(19) United States
(12) Patent Application Publication
(10) Pub. No.: US 2022/0021195 A1
(43) Pub. Date: Jan. 20, 2022

(54) FAULT DETECTION AND CIRCUIT INTERRUPTER DEVICES AND SYSTEMS

(71) Applicant: Brainwave Research Corporation, Woodbridge (CA)

(72) Inventors: Ghanshyam RATHI, Mississauga (CA); John ERIKSEN, Newmarket (CA); Benoit FORTIN, Richmond Hill (CA)

(21) Appl. No.: 17/290,245

(22) PCT Filed: Apr. 24, 2020
(86) PCT No.: PCT/CA2020/050545

§ 371 Date: Apr. 29, 2021

Related U.S. Application Data
(60) Provisional application No. 62/838,097, filed on Apr. 24, 2019.

(51) Int. Cl. H02H 1/00; H02H 3/16; G01R 31/52

(52) U.S. Cl. CPC H02H 1/0015; G01R 31/52; H02H 3/167

(57) ABSTRACT

Arc fault current interrupter electrical devices and systems. An example is an electrical device comprising: a contact configured for electrical connection to a power line; at least one sensor to detect at least voltage signals indicative of the power line; and a processor configured to determine from the detected voltage signals that a series arc fault has occurred.

### CROSS REFERENCE TO RELATED APPLICATIONS

This application claims the benefit of priority to U.S. Provisional patent application No. 62/838,097 filed Apr. 24, 2019, the contents of which are herein incorporated by reference into the Detailed Description of Example Embodiments, herein below.

### TECHNICAL FIELD

This disclosure is related to electrical receptacles, more particularly, to integrated power control, communication and monitoring of electrical receptacles and similar devices.

### BACKGROUND

Various conventional circuit interruption devices exist for arc fault protection, ground fault protection, overcurrent protection, and surge suppression. An arc fault is an unintentional electrical discharge in household wiring characterized by low and erratic voltage/current conditions that may ignite combustible materials. A parallel current fault results from direct contact of two wires of opposite polarity. A ground current fault occurs when there is a contact, which may be an arc, between a hot wire and ground. A series voltage fault occurs when there is an arc across a break in a single conductor. When a ground or arc fault is detected, power is conventionally terminated on the circuit by an AFCI or ground fault circuit interrupter (GFCI) disconnecting both receptacle outlets and any downstream receptacles.

It may be advantageous to improve the usability and safety of existing conventional receptacles. Existing conventional GFCI and AFCI receptacles do not provide detail about a fault. Currents are not being individually measured. Existing conventional GFCI and AFCI receptacles do not measure, monitor and control the delivery of current and voltage, and do not protect against overcurrent, under voltage or over voltage at the outlet. It may be advantageous to limit interruption of power to affected outlets, receptacles or devices only on the circuit, based on the type and location of the fault. Overcurrent protection at the outlet is preferable to the protection provided by the circuit breaker as it would avoid detection delay; as well as associated voltage losses associated with wire resistance along increasing wire length whereby such voltage losses impede the ability of existing circuit breakers to detect a short circuit at a remote location.

Additional difficulties with existing systems may be appreciated in view of the Detailed Description of Example Embodiments, herein below.

### SUMMARY OF DISCLOSURE

An example embodiment is an electrical device comprising: a contact configured for electrical connection to a power line; at least one sensor to detect at least voltage signals indicative of the power line; and a processor configured to determine from the detected voltage signals that a series arc fault has occurred.

An example embodiment is an arc fault circuit interrupter comprising: a power line conductor; a solid state switch for electrical connection to the power line conductor and configured to be activated or deactivated; an arc fault trip circuit cooperating with said solid state switch, said arc fault trip circuit being configured to deactivate said solid state switch responsive to detection of a series arc fault condition associated with voltage conditions of the power line conductor.

An example embodiment is electrical device comprising: a contact configured for electrical connection to a power line; at least one sensor configured to detect voltage signals indicative of the power line; and a processor configured to sample a plurality of the detected voltage signals within individual cycles of the detected voltage signals, and calculate mean square or root mean square values of the sampled voltage signals for the respective individual cycle of the detected voltage signals.

An example embodiment is an electrical circuit interruption device comprising: a contact configured for electrical connection to a power line; a solid state switch for in-series electrical connection with the power line; at least one sensor to detect voltage signals indicative of the power line and provide analog signals indicative of the detected voltage signals; an analog-to-digital convertor (ADC) configured to receive the analog signals from the at least one sensor and output digital signals to the processor; and a processor configured to determine from the digital signals that an arc fault has occurred, and in response deactivating the solid state switch.

An example embodiment is an arc fault circuit interrupter comprising: a hot conductor; a solid state switch for electrical connection to the hot conductor and configured to be activated or deactivated; an arc fault trip circuit cooperating with said operating mechanism, said arc fault trip circuit being configured to deactivate said solid state switch responsive to detection of an arc fault condition between the hot conductor and a neutral power line associated with detected current variation of the hot conductor and neutral power line.

An example embodiment is an electrical device comprising: a contact configured for electrical connection to a hot power line; at least one sensor to detect at least current signals indicative of the hot power line; and a processor configured to determine from the detected current signals that an arc fault has occurred between the hot power line and a neutral power line or between hot power line and ground power line.

An example embodiment is an electrical device comprising: a sensor to detect voltage signals indicative of a hot power line; and a processor configured to determine from the detected voltage signals that an arc fault has occurred, and differentiate the arc fault as being a series arc fault versus a parallel arc fault.

An example embodiment is an electrical device comprising: a contact configured for electrical connection to a power line; a solid state switch for in-series electrical connection with the power line; a sensor to detect voltage signals indicative of the power line; a processor configured to determine from the detected voltage signals that an arc fault has occurred, and in response deactivating the solid state switch without false tripping of the solid state switch.

An example embodiment is an electrical circuit interruption device comprising: a contact configured for electrical connection to a power line; a solid state switch for in-series electrical connection with the power line; a sensor to detect current signals indicative of the power line; a processor configured to: set a settable current threshold value, and deactivate the solid state switch in response to the detect current signals of the power line exceeding the settable current threshold value.

An example embodiment is an electrical device comprising: a contact configured for electrical connection to a power line; a voltage sensor for in-series connection to the power line to detect voltage signals indicative of the power line and provide analog signals indicative of the detected voltage signals; an analog-to-digital convertor (ADC) configured to receive the analog signals from the voltage sensor and output digital signals; and a processor configured to sample the digital signals in real time.

An example embodiment is an oscilloscope electrical device comprising: a contact configured for electrical connection to a power line; a sensor for in circuit electrical connection to the power line to detect signals indicative of the power line; a processor configured to sample the detected signals in real time, and provide oscilloscope information indicative of the sampled signals.

An example embodiment is an electrical device comprising: a contact configured for electrical connection to a power line; at least one sensor to detect signals indicative of the power line and provide analog signals indicative of the detected signals; an analog-to-digital convertor (ADC) configured to receive the analog signals from the at least one sensor and output digital signals to the processor; and a processor configured to calibrate the electrical device by: applying a first known electrical signal to the sensor and receiving a first digital signal value, applying a second known electrical signal to the sensor and receiving a second digital signal value, performing linear interpolation or extrapolation using the first digital signal value and the second digital signal value for the calibrating of the electrical device.

An example embodiment is an electrical device comprising: a first contact for configured for electrical connection to a hot power line; a first sensor configured to provide a first analog signal indicative of current of the hot power line; a second contact for configured for electrical connection to a neutral power line; a second sensor configured to provide a second analog signal indicative of current of the neutral power line; a solid state switch for electrical connection to the hot power line and configured to be activated or deactivated; an analog-to-digital convertor (ADC) configured to receive the analog and output a digital signal, and a processor configured to detect a ground fault condition of the hot power line by determining a current imbalance between the hot power line and the neutral power line based on the digital signal from the ADC, for the deactivation of the solid state switch.

An example embodiment is a ground fault circuit interrupter comprising: a power line conductor; a first sensor configured to provide a first analog signal indicative of current of the power line conductor; a neutral line conductor; a second sensor configured to provide a second analog signal indicative of current of the neutral line conductor; a solid state switch for electrical connection to the power line conductor and configured to be activated or deactivated; a ground fault trip circuit cooperating with said operating mechanism, said ground fault trip circuit being configured to deactivate said solid state switch responsive to detection of a ground fault condition associated with current imbalance between said hot conductor and said neutral conductor, wherein said ground fault trip circuit includes: an analog comparator circuit configured to receive the first analog signal and the second analog signal and output an analog signal indicative of a difference between the first analog signal and the second analog signal, an analog-to-digital convertor (ADC) configured to receive the analog signal from the analog comparator circuit and output a digital signal, and a processor configured to perform determining of the current imbalance for the detection of the ground fault condition based on the digital signal from the ADC, for the deactivation of the solid state switch.

An example embodiment is an electrical device comprising: a conductive housing defining a first channel for receiving a power line, and a second channel; a fastener through the second channel for tightening the power line to the first channel, a head of the fastener engaging the power line and the conductive housing when tightened.

An example embodiment is an electrical device comprising: a ground contact configured for electrical connection to ground; a first voltage sensor to detect voltage signals indicative of the ground contact; a first current sensor to detect current signals indicative of the ground contact; a neutral contact configured for electrical connection to a neutral power line; a second voltage sensor to detect voltage signals indicative of the neutral power line; a second current sensor to detect current signals indicative of the neutral power line; and a processor configured to determine from the detected voltage signals and/or the current signals that a ground imbalance has occurred between the neutral power line and the ground.

An example embodiment is an electrical device comprising: a ground contact configured for electrical connection to ground; a voltage sensor for in-series connection to the power line to detect voltage signals indicative of the ground contact line and provide analog signals indicative of the detected voltage signals; a current sensor for in-series connection to the power line to detect current signals indicative of the ground contact line and provide analog signals indicative of the detected current signals; an analog-to-digital convertor (ADC) configured to receive the analog signals from the voltage sensor and output digital signals; and a processor configured to sample the digital signals in real time.

An example embodiment is a method for detecting ground imbalance on an electrical device, comprising: receiving, from a senor assembly, current, voltage, or both current and voltage measurement results; determine whether a ground imbalance is above a predetermined safety threshold level; and sending an error message indicating the ground imbalance.

An example embodiment is an electrical device comprising: a dielectric body, a plurality of through holes formed on the dielectric body, each through hole for receiving a power line; and a housing at an end of the body for housing a current sensor for sensing a current of the power line, a voltage sensor for sensing the voltage of the power line, or both a current for sensing a current of the power line and a voltage sensor for sensing a voltage of the power line.

An example embodiment is an electrical device comprising: a dielectric body, a through holes formed on a first side of the dielectric body for receiving an end of a power line; and a housing at an end of the body for housing a current sensor for sensing a current of the power line, a voltage sensor for sensing the voltage of the power line, or both a current for sensing a current of the power line and a voltage sensor for sensing a voltage of the power line; and a conductive pin on a second side of the dielectric body for conducting current or voltage to or from the power line.

An example embodiment is an electrical device comprising: a plurality of power output terminals for supplying power; a plurality of power supply terminals for receiving power supply from a power source; a plurality of insulated power delivery modules, each module electrically connected to a respective power supply terminal and a power output terminal for conducting power; and a sensor unit for sensing current and voltage flowing through each of the power delivery module.

Additional features of the present disclosure will become readily apparent to those skilled in this art from the following detailed description of example embodiments, wherein only the preferred embodiments are shown and described, simply by way of illustration. As may be realized, there are other and different embodiments, and its several details are capable of modifications in various obvious respects, all without departing from the scope. Accordingly, the drawings and description are to be regarded as illustrative in nature, and not as restrictive.

### BRIEF DESCRIPTION OF DRAWINGS

Various exemplary embodiments are illustrated by way of example, and not by way of limitation, in the figures of the accompanying drawings in which like reference numerals may refer to similar elements and in which:

FIG. 1 is a block diagram illustrating two embodiments of the one circuit monitoring unit, plugged in and hardwired;

FIG. 2 illustrates a circuit module with its wired input and output;

FIGS. 3A and 3B is an example of an extension cord in accordance with an example embodiment;

FIGS. 4A, 4B, and 4C illustrates exemplary data and commands available for display on the monitoring screen, or for communication, in accordance with example embodiments;

FIGS. 5A, 5B, 5C and 5D are diagrams illustrating evolution history of breaker panels including example embodiments;

FIG. 6 is a front view and a rear view of a RS485 display screen;

FIG. 7 is a block diagram illustrating a number of RS 485 screens network;

FIGS. 8A and 8B illustrate exemplary embodiments of circuit boards shown in FIGS. 5A-D;

FIG. 9 illustrates exemplary embodiments of a building management monitoring and control system; and

FIGS. 10A and 10B illustrate exemplary embodiments of a cover and a box housing of a junction box; and

FIGS. 11A and 11B illustrate further exemplary embodiments of a cover and a box housing of a junction box;

FIGS. 12A-12G illustrate an exemplary embodiment of a duplex outlet receptacle for preventing glowing contacts;

FIGS. 13-1A and 13-1B represent a single cycle of sinusoidal waveforms (or sine wave) of voltage in an AC Circuit of a parallel arc fault, showing instantaneous voltage over time (“Vt”);

FIGS. 13-2A and 13-2B illustrate FFT values of normal (non-fault) sinusoidal waveform;

FIGS. 13-3A and 13-3B illustrate FFT values based on 64 samples of the sinusoidal waveforms of FIGS. 13-1A and 13-1B;

FIG. 14-1A is a photograph of normal operation of a power line prior to a series arc fault;

FIG. 14-1B illustrates example graphs of the occurrence illustrated in FIG. 14-1A;

FIG. 14-1C illustrate example data of the occurrence illustrated in FIG. 60-1A;

FIG. 15-1A is a photograph of a manual break in the power line and an arc starting to appear;

FIG. 15-1B illustrates example graphs of the occurrence illustrated in FIG. 15-1A;

FIG. 15-1C illustrate example data of the occurrence illustrated in FIG. 15-1A;

FIG. 16-1A is a photograph of the arc in full motion;

FIG. 16-1B illustrates example graphs of the occurrence illustrated in FIG. 16-1A;

FIG. 16-1C illustrate example data of the occurrence illustrated in FIG. 16-1A;

FIG. 17-1A is a photograph of the arc diminishing with glowing contacts;

FIG. 17-1B illustrates example graphs of the occurrence illustrated in FIG. 17-1A;

FIG. 17-1C illustrate example data of the occurrence illustrated in FIG. 17-1A;

FIG. 18-1A is a photograph of the arc finished, the conductors are back to normal.

FIG. 18-1B illustrates example graphs of the occurrence illustrated in FIG. 18-1A;

FIG. 18-1C illustrate example data of the occurrence illustrated in FIG. 18-1A;

FIG. 19A is a top view of a safety ground current monitoring sensor;

FIG. 19B is a side view of the safety ground current monitoring sensor;

FIG. 19C (1) is a rear view of the safety ground current monitoring sensor incorporated in an enclosure;

FIG. 19C (2) is a front view of the safety ground current monitoring sensor incorporated in an enclosure;

FIG. 19D illustrates a safety ground voltage sensor (“SGVS”); and

FIG. 19E is a flowchart of exemplary logic of GIDs; and

FIG. 20A illustrates a safety ground bus bar, according to an embodiment;

FIG. 20B illustrates an example of an intelligent sensing bus bar, according to an embodiment;

FIG. 20C illustrates an example of an intelligent sensing lug that has a protruding pin;

FIG. 20D illustrates an example of a joint three-phase module, according to an embodiment;

FIG. 21A illustrates a digital master breaker circuit interrupter electrical safety protection system, embodied in a two-phase environment; and

FIG. 21B illustrates an example of a breaker panel incorporating intelligent voltage and/or current sensing lugs, according to an embodiment.

### DETAILED DESCRIPTION OF EXAMPLE EMBODIMENTS

As understood in the art of electrical circuits and power lines, Black refers to hot or live power line, White refers to neutral power line, and Ground means earth ground. Last mile setups can be referred to as Black, White & Ground; or Live, Neutral and Ground. There is no potential difference (zero volts) between ground and white. The Neutral carries current back from the Black power line. Voltage Black to White potential will show the line voltage e.g., 110 V; and Ground to Black potential will show the line voltage, e.g. 110 V.

The Applicant has described electrical systems and methods in PCT/CA2017/051121, filed Sep. 22, 2017, PCT Patent Application No. PCT/CA2017/050893, filed Jul. 25, 2017, U.S. patent application Ser. No. 15/659,382, filed Jul. 25, 2017, U.S. patent application Ser. No. 15/274,469, filed Sep. 23, 2016, U.S. provisional application No. 62/490,527, filed Apr. 26, 2017, U.S. provisional application No. 62/505,434, filed May 12, 2017, provisional application No. 62/222,904 filed Sep. 24, 2015, U.S. provisional application No. 62/366,910 filed Jul. 26, 2016, U.S. provisional application No. 62/377,962 filed Aug. 22, 2016, U.S. provisional application No. 62/490,527 filed Apr. 26, 2017, U.S. provisional application No. 62/505,434 filed May 12, 2017, the contents of which are herein incorporated by reference.

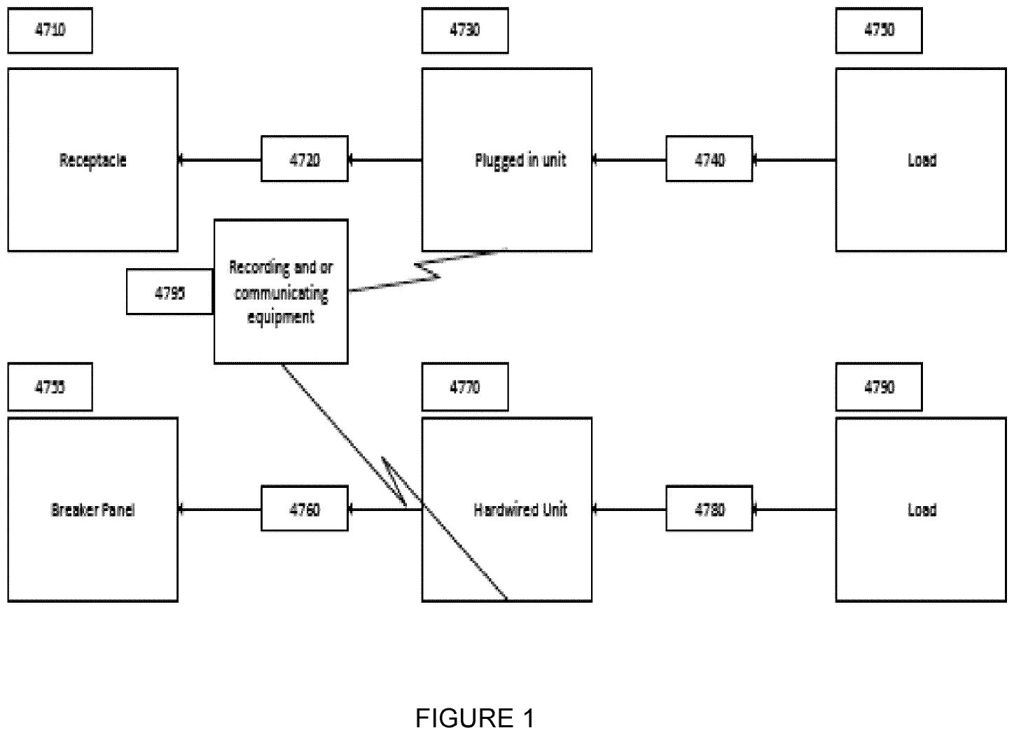

FIG. 1 illustrates two embodiments of a circuit monitoring unit, one is plugged in and one is hardwired.

In the first embodiment, a plugged-in unit 4730 is plugged in series with a receptacle 4710 by using a cord 4720. The load 4750 is plugged in the unit 4730 using a cord 4740. The unit 4730 through a communication link is connected to a data recording and communication unit 4795 for controlling the plugged in unit 4730 and/or monitoring/reporting the status of the plugged in unit 4730.

In the second embodiment, a unit 4770 is hard-wired in the circuit in series using electrical wires 4760 to the power source, such as a breaker panel 4755. The load 4750 is also hard wired and plugged in the hardwired unit 4770 using electrical wires 4780. The unit 4770 through a communication link is connected to the data recording and communication unit 4795 for controlling the hardwired unit 4770 and/or monitoring or reporting the status of the hardwired unit 4770. Each of the units 4730 and 4770 may also have a separate data recording and communication unit 4795. In some examples, the data recording and communication unit 4795 provides a control mechanism which allows for controlling the operation of unit 4730 and/or 4770. 4760 may be connected to an intermediary system rather than directly to a breaker panel.

In some examples, the data recording and communication unit 4795 has a communication port for both receiving data from the unit 4730 and/or 4770, and transmitting command to the unit 4730 and/or 4770 enabling 4795 to control the operation of the unit 4730 and/or 4770. 4795 may be a control device including but not limited to a PLC machine or a computer.

In some examples, the data recording and communication unit 4795 has two ports, one data port for receiving data from the unit 4730 and/or 4770, and one command port for transmitting commands to the unit 4730 and/or 4770 to control the operation of the unit 4730 and/or 4770.

In some examples, the data recording and communication unit 4795 includes a processor or a computer. Wires may be used to connect the processor with the communication port, or with the data port and command port. An API may be used to for the communication between the data recording and communication unit 4795 and the plugged-in unit 4730 or the between the data recording and communication unit 4795 and the hardwired unit 4770. For example, the API may be used, over the communication link, both to receive information, such as performance statistical data or acknowledgments, and to control the operation of the unit 4730 or unit 4770 by sending commands to the unit 4730 or 4770.

In some examples, the unit 4795 includes one or more transducers, rather than induction transformers, to convert AC current to DC current, to measure the DC voltage transmitted on the links 4720 and 4740, and to report the measured DC voltage.

In some examples, the unit 4795 includes one or more hall-effect sensors for measuring the current by transfusing the current into voltage. The ADC only measures voltage. As such, signals need to be first transfused into voltage signals, and the ADC then measure the voltage signals. The ADC may determine or calculate the measured voltage for example, based on the scale of the unit used. In some examples, the current, 10 amps, is first converted to a voltage, for example to 1.73 volts. The ADC may then measure the voltage and calculate RMS (average), and then can measure the current. Based on the scale of the unit used and the units measured, the ADC may determine the voltage value such as 1.73 V. The ADC uses the measured voltage, such as 1.73 V, to represent the current, such as 953 milliamps.

The signals may be voltage or current. When voltage of the incoming AC is measured directly through a resistor grid, the voltage of the hot line is directly measured by using the register divider dropped down to 3 volts for measurement in the ADC. The ADC only measures the signals. Therefore, a separate processor may be used to control the operation of the unit 4730 or 4770.

In the example of FIG. 1, the measurement and control of the signals are conducted by the unit 4795. Signals are transmitted to the unit 4730 and 4770 from the receptacle 4710 and the breaker panel 4755, respectively. With the communication links that connect the unit 4730 and 4770 with the unit 4795, the unit 4795 measures the signals and controls the operation of the unit 4730 and/or 4770. The units 4730 and/or 4770 may be measurement and building automation equipment from a number of manufacturers such as Mircom, Johnson Controls, or Siemens to name a few.

In an embodiment, a metering device may be used for a power distribution cabinet distributing power through a plurality of electrical wires. Each wire is driven by a line Voltage. A method of operating the metering device includes providing for a plurality of current transformers on aboard, each current transformer generating a current signal Voltage responsive to a current of an electrical wire through the current transformer, providing for a plurality of connections on the board for a plurality of different line voltages; and arranging said plurality of current transformers in physical correspondence to power outputs of said power distribution cabinet.

In a metering device for a power distribution cabinet distributing power through a plurality of electrical wires, each wire driven by a line Voltage, said metering device having a plurality of current transformers, each current transformer generating a current signal Voltage responsive to a current of an electrical wire through said current transformer, and a plurality of connections for a plurality of different line voltages, a method of calibrating said metering device.

Generating within said metering device a calibration number from an energy reading of a reference metering device and a metered energy reading of each current transformer and corresponding electrical wire mapped to be driven by one line voltage whereby said metered energy is rapidly calibrated.

In a metering device for a power distribution cabinet distributing power through a plurality of electrical wires, each wire driven by a line Voltage, said metering device having plurality of current transformers, each current transformer generating a current signal Voltage responsive to a current of an electrical wire through said current transformer, and a plurality of connections for a plurality of different line voltages, a method of calibrating said metering device comprising: generating within said metering device a calibration number from an energy reading of a reference metering device and a metered energy reading of each current transformer and a line Voltage.

A metering device for metering energy delivered on a plurality of electrical wires, said device comprising a plurality of current transformers, each current transformer arranged to generate a signal in response to current on one of said plurality of electrical wires; at least one Voltage connection for a line Voltage of said one of said plurality of electrical wires; and circuitry connected to each of said plurality of current transformers and said at least one Voltage connection, said circuitry sampling said current transformer signal and said line Voltage to measure instantaneous energy delivery over each one of said plurality of electrical wires, each one of said plurality of electrical wires and Voltage mapped by programming to one of a plurality of meter accounts monitored by said metering device; whereby said metering device is capable of monitoring energy delivery to a plurality of customers.

In a metering device for a power distribution cabinet distributing power through a plurality of electrical wires, each wire driven by a line Voltage, said metering device having a plurality of current transformers, each current transformer generating a current signal Voltage responsive to a current of an electrical wire through said current transformer, and a plurality of connections for a plurality of different line voltages, a method of operating said metering device comprising: mapping a current signal Voltage of at least one of said plurality of said current transformers in said metering device to a line Voltage driving an electrical wire associated with said at least one current transformer; and metering energy by product of said current signal Voltage and said line Voltage according to said mapping.

The method of the above storing said mapping into nonvolatile memory.

In a metering device for a power distribution cabinet distributing power through a plurality of electrical wires, each wire driven by a line Voltage, said metering device having a plurality of current transformers, each current transformer generating a current signal Voltage responsive to a current of an electrical wire through said current transformer, and a plurality of connections for a plurality of different line voltages, a method of operating said metering device comprising: programmably mapping a current signal Voltage of at least one of said plurality of said current transformers in said metering device to a line Voltage driving an electrical wire associated with said at least one current transformer; metering energy by product of said current signal Voltage and said line Voltage according to said mapping for one of a plurality of meter accounts monitored by said metering device.

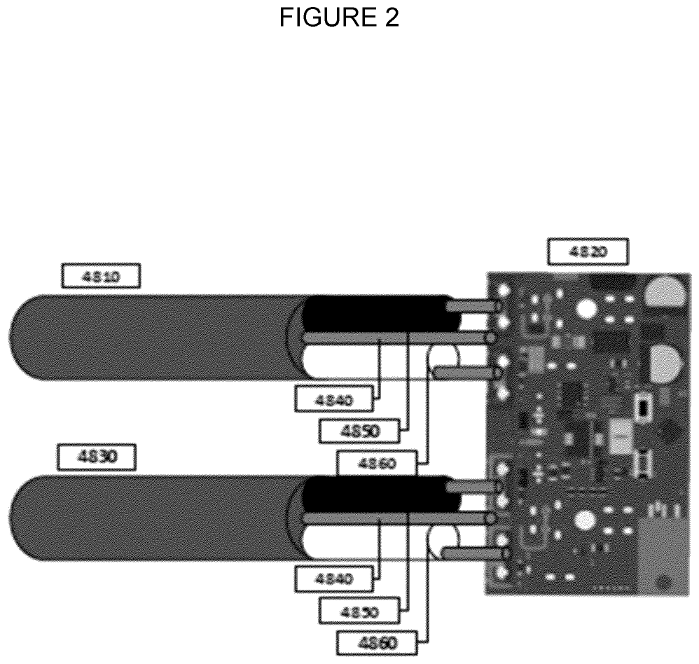

In the examples of FIG. 2, separate ground connections are used to connect with each of the module 4820 or a circuit. In FIG. 2, the wires 4840, 4850, and 4860 connect to respective terminals that are connected to separate the buses of the module 4820 internally. The module 4820 may include filters. As illustrated in FIG. 2, the two neutral wires 4860 and the two ground wires 4840 are separately connected to two different isolated connectors of the module 4820. The connectors may be bus bars. With this arrangement, the module 4820 or a circuit reduces wires by wiring internally between the connectors and other circuits within the module 4820.

The module 4820 may also connect to one or more breaker panels, for example, from the opposition side of the connectors. In some examples, the module 4820 may also be included in a breaker panel.

The module 4820 may also be used in test circuits to generate the current leakage by connecting the live power wire to the connector connected to the neutral wire.

The industry uses the two wires (live power and neutral) into the transformer, and determines whether there is a magnetic imbalance between the live power and neutral widings. With module 4820, only the live power wire is connected to one sensor and the neutral is connected to a different sensor. Therefore, the live power and neutral wires are connected to two separate sensors, rather than connect to one transformer. In the industry case, once the power lines leave the transformer, they are merely used to source downstream loads and are not individually sensed.

The breaker panel may be used in the Breaker companion module 4820, inside the breaker panel and/or in power and communication switching device.

The ground wires 4840 has dual purposes: In the input 4810 of the module 4820, the ground wire 4840 acts both as an earthing return and a communication conductor; In the output 4830 of the Module 4820, the ground wire 4840 is for the earthing return. At the output 4830, all grounds are common and attached to the master earthing ground return. The master earthing ground return is a circuit that provides for power control within the module 4820. The output 4830 may be on a bus and common to the master earthing ground. At output 4830, ground is common in order for the ground not be a floating ground.

The input 4810 of the module 4820 includes incoming insulated wires, in the example of FIG. 2, the input 4810 contains three wires: wire 4850 as the insulated live wire, wire 4840 as ground wire that may be connected to the module 4820 individually and has a dual purpose of earthing the return and acting as a communication conductor as described above, and wire 4860 as the insulated neutral wire.

In some examples, the electrical noise associated with the electrical current may be filtered when the current is input from the input 4810. The wires 4840, 4850, and 4860 each may be connected to a filter before connecting to their respective bus bars. By filtering the electrical current, the noise of the electrical current is eliminated before the current is transmitted over the different bus bars so that cross noise between different wires 4840, 4850, and 4860 may be prevented; as well, filtering out the noise allows cleaner spectrum and faster data transmission.

The output 4830 in the example of FIG. 2 comprising insulated wires, the live wire 4850, ground wire 4840, and the neutral wire 4860.

The ground wire 4840 of the output 4830 provides earthing return. The ground wire 4840, similar to other common ground systems, is electrically connected to a master ground, for example, the ground of a building, including a residential, commercial building.

In some examples, the input 4830 may be connected to a breaker panel. if the module 4820 is used to form a breaker panel, the ground wire 4840 is connected to the master grounding bus of the breaker panel.

If the module 4820 is used to form a switch, the ground wire 4840 is also connected to a master ground bus that is connected to the master ground, so that the module 4820 is connected to the master ground. By connecting to the master ground bus, messages may be extracted without having a floating ground.

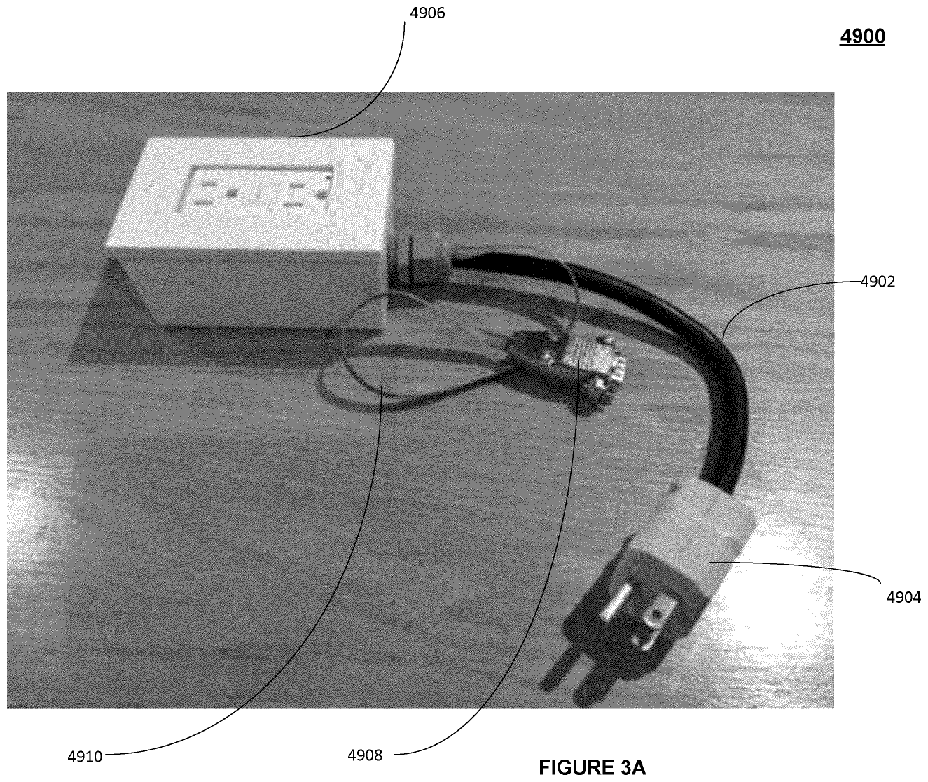

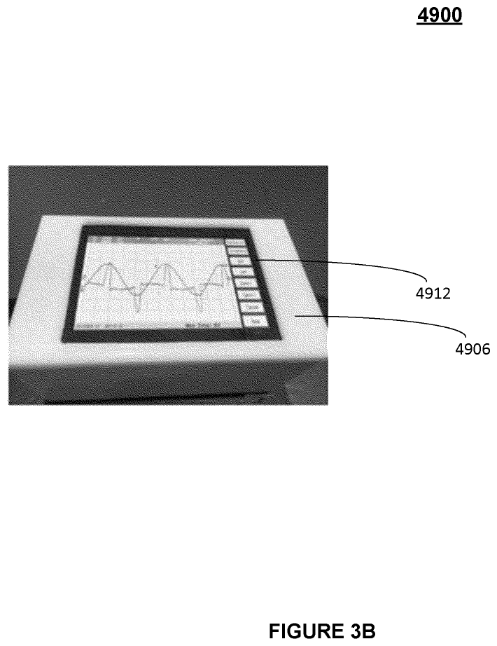

FIGS. 3A and 3B illustrate an exemplary extension cord. In FIG. 3A, an extension cord 4900 comprises: a cable 4902 having a first end portion and a second end portion; a power input end 4904 terminating the first end portion of the cable 4902; a power output end 4906 terminating the second end portion of the cable 4902; at least one sensor (not shown) positioned at the second end portion for detecting signals indicative of the cable 4902; a solid state switch (not shown) in series relationship with the cable 4902 at the second end portion of the cable 4902; a processor (not shown) configured to determine, based on the detected current, that there is a ground fault, arc fault or over-current condition, and in response cause the solid state switch to deactivate. The processor may be connected with the power output end 4906 via a connector 4908 and a cable 4910. The processor may control the operation of the power output end 4906 via the connector 4908 and the cable 4910. FIG. 3B illustrates an example of a display screen 4912 that is integrated with a casing of the power output end 4906 of the extension cord 4900.

In some examples, the processor is configured to cause the solid state switch to activate when there is no ground fault, arc fault or over-current condition. The processor may also be configured to cause the solid state switch to deactivate in response to receiving a manual command.

In some examples, the solid state switch and the at least one sensor are in a same packaging or a same circuit board. The solid state switch and the at least one sensor may also be in the same packaging or the same circuit board as the power output end. The at least one sensor may be in series relationship with the cable at the second end portion of the cable 4902. The at least one sensor may comprise a current sensor for detecting current and/or a voltage sensor for detecting voltage. The at least one sensor may detect signals of a hot power line of the cable 4902. The at least one sensor may detect signals of a neutral power line of the cable 4902.

In some examples, as illustrated in FIG. 3A, the power input end 4904 comprises a male end, and the power output end 4906 comprises a female end. In the example of FIG. 3A, the power output end 4906 may also comprise at least one or a plurality of plug outlets. Each of the plurality of plug outlets may individually controllable by the processor.

Traditionally, in the example of a breaker panel, the live power wire is connected to the breaker panel, the neutral wire is connected to a bus bar at the bottom of the panel, and the ground wire is connected to a separate bus bar, such as on a side inside the panel. The industry generally does not separate out distinct inputs for ground, and connects all of the ground of a circuit to one common bus bar.

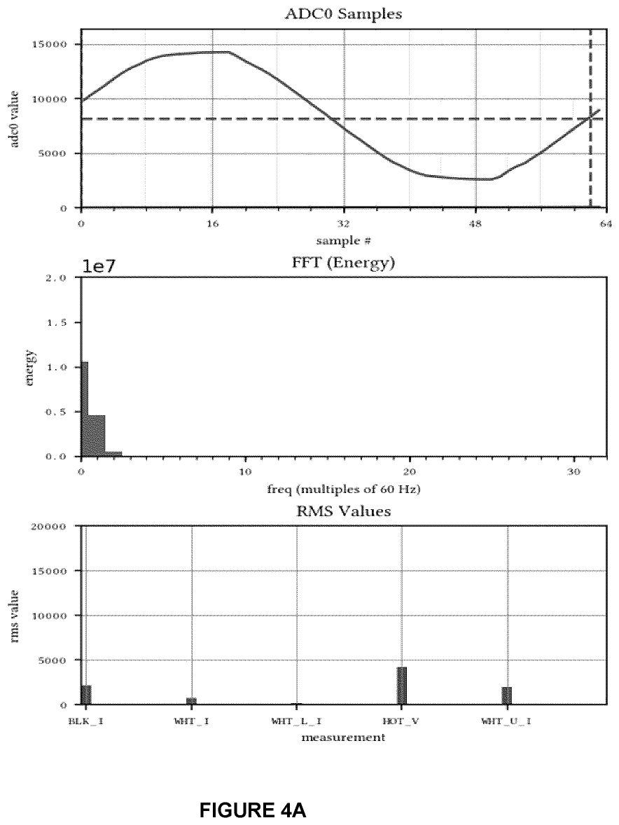

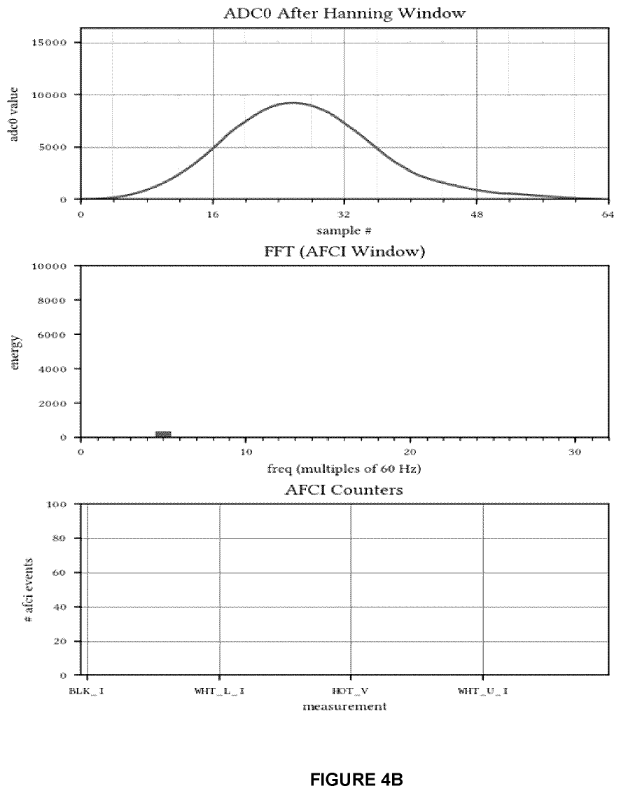

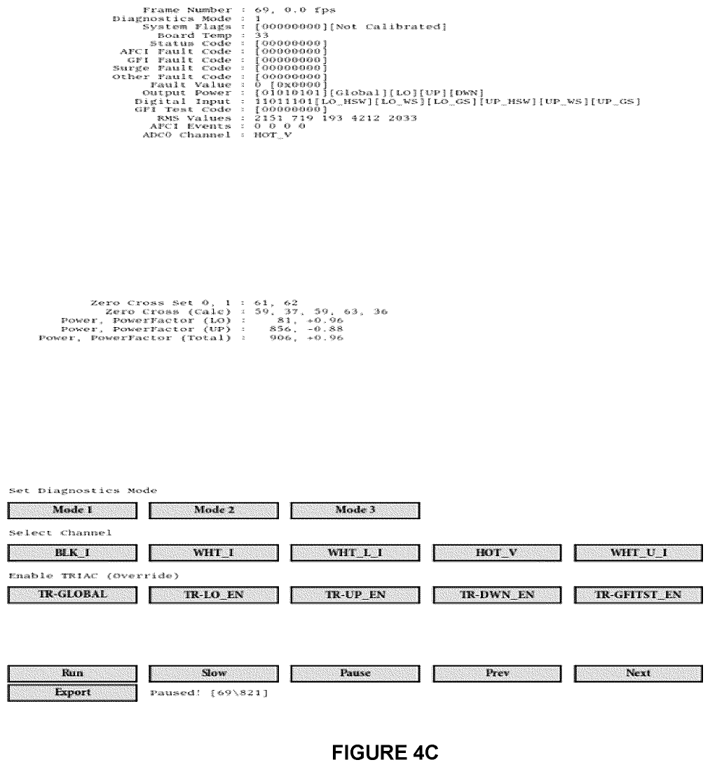

FIGS. 4A, B and C illustrate examples of the parameter settings and data which are detected or calculated by the device, which can be displayed on the monitoring screen 5204 of applicable electrical products, including but not limited to receptacle devices (with or without outlets, corded, portable and/or direct-wired), extension cords, branch circuit feeders in a breaker panel, an electrical junction box that is adjacent to the circuit breaker panel, an in-line power receptacle, a metering device, or an intelligent junction box. Parameters and controls may be used to diagnose applicable electrical products. FIG. 4C illustrates a first set of exemplary parameters and controls, and FIGS. 4A and 4B display measurements or analysis results according to the first set of parameters and controls. FIG. 4A illustrates the sampling values generated by ADC, the FFT analysis results, and RMS values of different channels associated with the different electrical lines, such as the white line, black line, and the hot power line. Similarly, the parameter settings and data can also be displayed onto the display screen 4912 of the extension cord 4900 (FIG. 3B), in an example. Note, the actual content shown in FIGS. 4A, 4B and 4C is not intended to depict scientific accuracy, but rather represents an illustration of what kind of data can be displayed in an embodiment. In another embodiment, Information could be displayed, collecting data over an extended period of time showing multiple AC cycles.

As illustrated in the example of FIG. 4C, parameter settings may be displayed. Frame number denotes the frame rate of the recording, for example, frame number 69 at some frame per second recording speed. Diagnostic Mode indicates the mode of operation such as mode 1. The modes will be described in greater detail below. System flag to show whether the system is calibrated, for example not calibrated. Board temperature indicates the temperature of the electrical board, such as 33 degrees. Status code is used to indicate the operation status: for example, all zero's means that there is no fault. AFCI fault code, GFCI fault code, surge fault code, other fault codes and fault value collectively indicate the current value that caused the trip. Output power indicates the powers that are turned on; e.g. global power and downstream are the only ones illustrated as turned on in the example of FIG. 4C. Digital input indicates the pins that have been plugged in. RMS values indicates values of black current, return current, upper receptacle current, and lower receptacle current. AFCI event indicates number of times that the arc has been detected while it was turned on or powered on. ADCO channel indicates the power line pursuant to which the information is provided, for example, HOT-V indicates hot voltage line. Zero cross set 0, 1 and Zero cross (Calc) are the voltage zero cross, then black current and white and their zero cross. Based on Zero cross set 0, 1 and Zero cross (Calc), the Power Factors may be determined. Power factor (UP), Power Factor (LO) are calculated based on zero cross values.

Under a specific mode; Select Channel allows to control different subjects, such as including but not limited to black, white, upper receptacle, lower receptacle, and hot volts. The commands can be issued using Modbus to make the selection, for example by setting the mode, and channel number etc.

As illustrated in the examples of FIG. 4C, there may be three or more diagnostic modes, such as, mode 1, mode 2, and mode 3. Different modes are associated with different data. API may be used to switch the mode of the diagnostic information. For example, in mode 1, voltage data and Fast Fourier transformation (FFT), frequency analysis and related information may be collected and displayed. In mode 2, information related to time domain signals for voltage, current, white currents may be collected and displayed. In mode 3, voltage information is not available, but other power analysis information, such as zero crossing, power factor measurements etc., may be collected and displayed. By switching to different modes, different information may be collected and displayed.

With the different modes, information may be multiplexed depending on the requirements of the master. Different modes may be used to display information of different subjects of interest. In some examples, in mode 1, voltage and its frequency analysis of related information are produced. If the black current, or total current is of interest, mode 1 may be switch to black current to show time domain black current data and along with it the FFT, the frequency analysis and related information.

The API can be used to manually or automatically set the current threshold, which can be a standard or non-standard current threshold value.

An example embodiment is an electrical circuit interruption device including: a contact configured for electrical connection to a power line; a solid state switch for in-series electrical connection with the power line; a sensor to detect current signals indicative of the power line; a processor configured to: set a settable current threshold value, and deactivate the solid state switch in response to the detect current signals of the power line exceeding the settable current threshold value.

In an example of the electrical circuit interruption device, the settable current threshold level is a standard current threshold value. In an example of the electrical circuit interruption device, the standard current threshold value is 15 A/20 A or 16 A/32 A, 50 A, 100 A, 200 A or more. The standard current threshold value may also be values in the international standards, or a customized value, a predetermined value, or a controlled value or input. In an example of the electrical circuit interruption device, the settable current threshold level is non-standard current threshold value. In an example of the electrical circuit interruption device, the setting is performed by the processor based on the detected current signals. In an example of the electrical circuit interruption device, the setting is performed by the processor based on a database stored in a memory accessible by the processor. In an example of the electrical circuit interruption device, the settable current threshold level for the setting is received by the processor by way of received input. In an example of the electrical circuit interruption device, the received input is received from an Application Program Interface, a user input device, a second electrical receptacle device, or a computer device.

Reference to breakers, circuit breakers, and circuit breaker panels may be interchangeable used or interchangeable as to their functionality as described herein, as applicable. An in-inline electrical receptacle may be synonymous with an intelligent junction box, in example embodiments. The disclosed concepts are applicable to in-wall electrical receptacles, power strips, power bars, extension cords, receptacle adaptors, circuit breakers, circuit breaker panels, in-line electrical receptacles, junction boxes, and other devices to facilitate provision, safety, and control of electrical power from power lines to downstream loads. Such receptacles may or may not include plug outlets for a matching plug, or other output connectors such as fixed electrical wiring, terminal screws, sockets or pins. Reference to neutral-to-ground can be used interchangeably with ground-to-neutral, depending on the perspective of the particular device. While a North American 110V 60 Hz receptacle is exemplified herein, the disclosed concepts are applicable to other international receptacles or devices. Similarly, the disclosure is not limited to plug blades as the mating means for the receptacle outlet but is applicable interchangeably to other plug configurations such as found in other international standards. Moreover, although the present disclosure has been exemplified in a single phase alternating current context, the disclosure is operable in the contexts of direct current and multiple-phase systems.

Examples of solid state switches or controlled state switches include insulated-gate bipolar transistors (IGBT), MOSFETs, and TRIACs they would be included in a module similar as the one shown in FIG. 2.

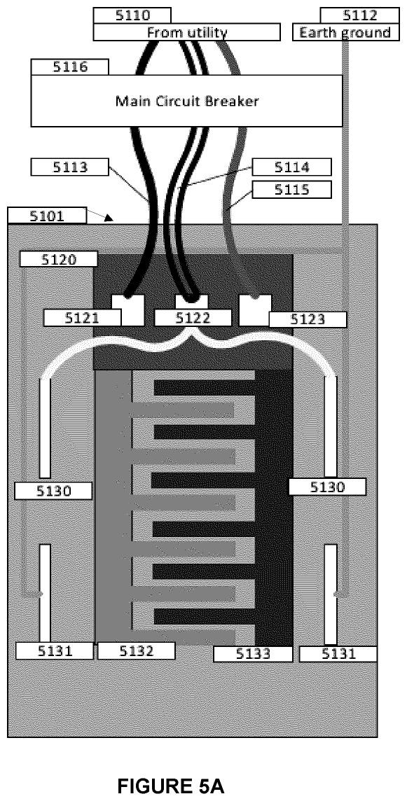

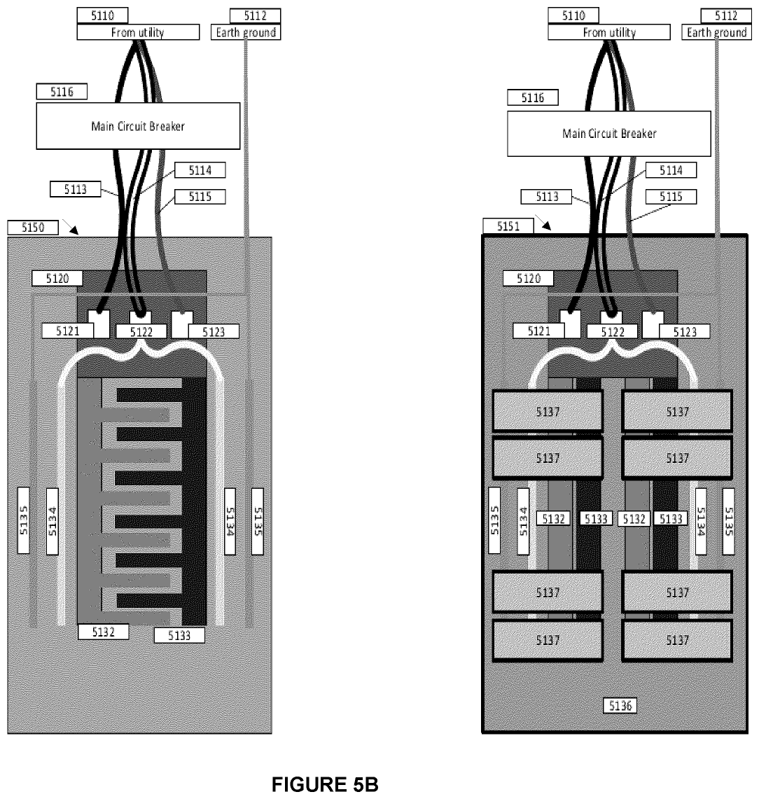

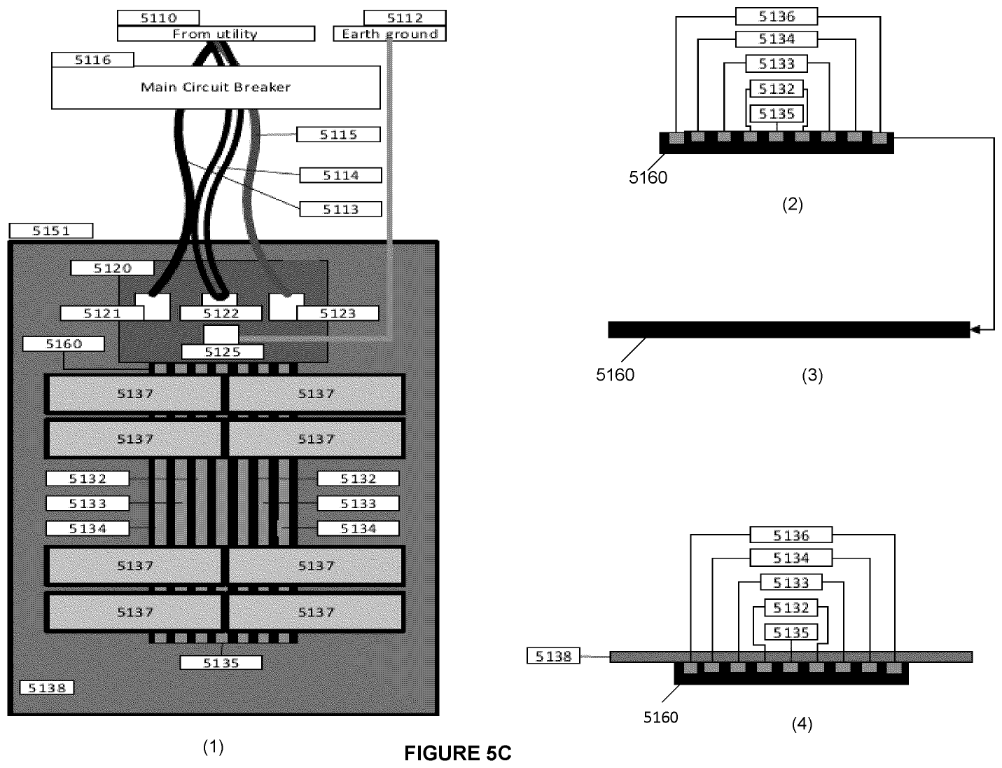

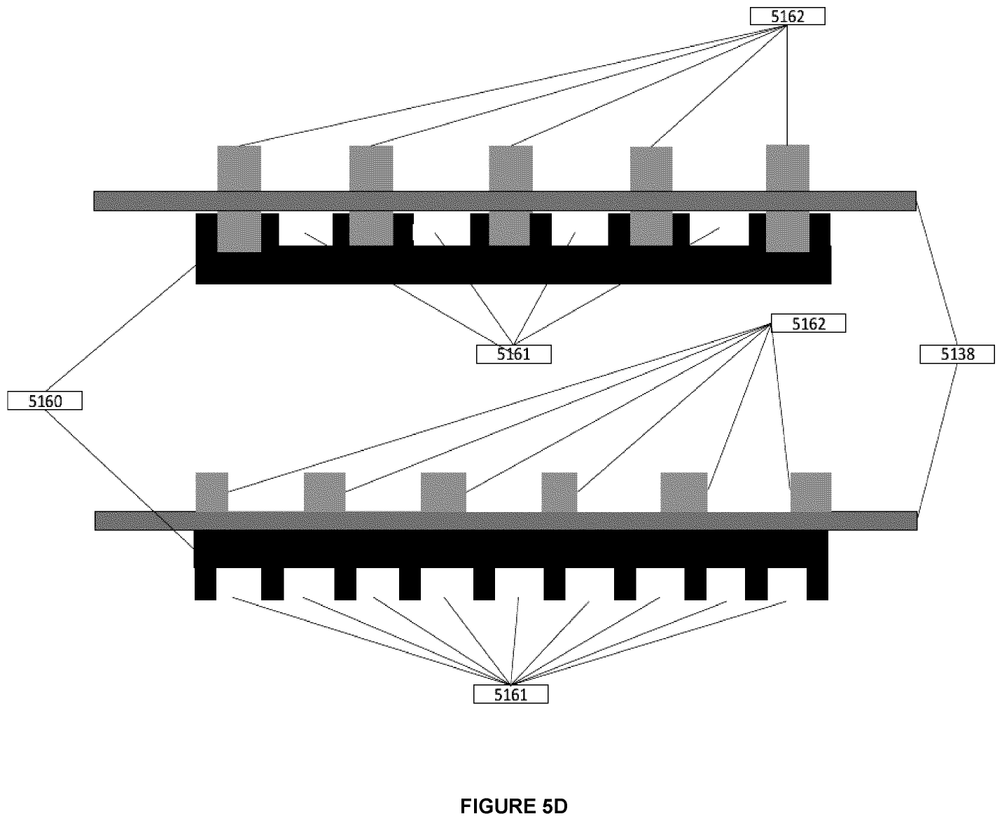

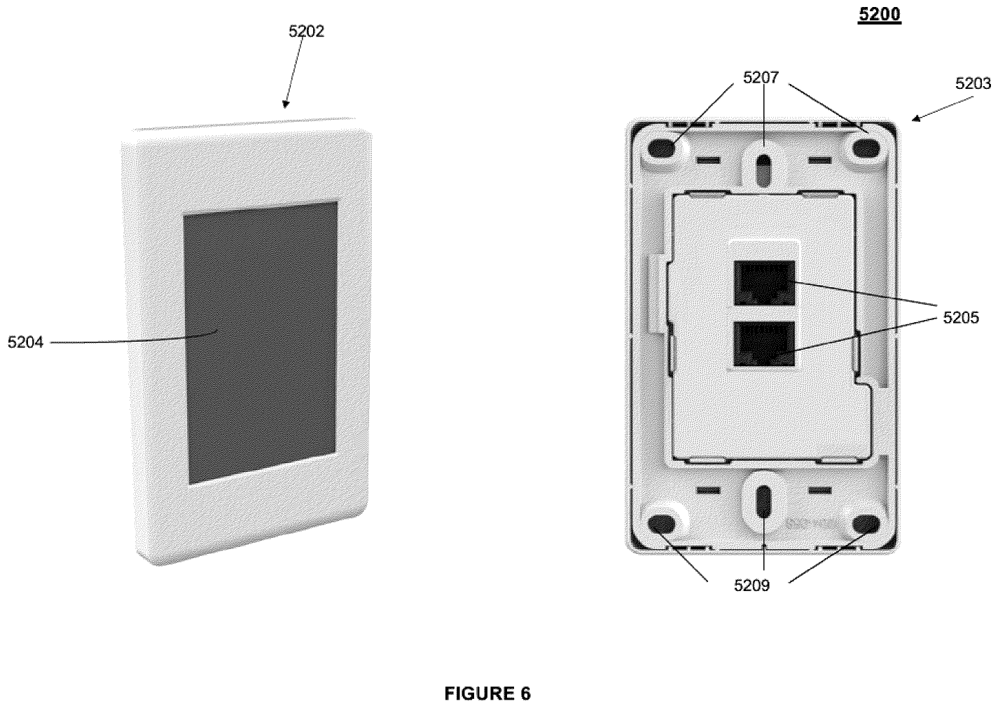

As illustrated in the example of FIGS. 5A-5D, an electrical device 5101 for separated power lines. The utility 5110 provide electrical power to the electrical device and the Earth ground 5112 provides an earth ground. The utility 5110 may include a power line 5113, a neutral power line 5114, and a ground line 5115. In some examples, the utility 5110 may first connected to a main circuit breaker 5116 for protecting the electrical device 5150.

In the example of FIG. 5A, the electrical device 5101 may be a circuit breaker panel, an electrical junction box that is adjacent to the circuit break panel, an in-line power receptacle, a metering device, or an intelligent junction box.

In the example of FIG. 5B, the electrical device 5150 may have a circuit breaker connected to the neutral and to ground. In some examples, the electrical device 5151 may have a circuit breaker connected to the neutral and to ground using a PCB connected to a socket. In the example of FIG. 5C(1), the PCB may connect to the socket via a plastic encased rail, and the PCB may connect to the socket via a plastic encased rail. The casing of the panel may be a standard casing with the attachments for securing the wires coming from the field. The wires from the field may be directly connected to the sockets 5137 to the PCB modules hosted in the sockets 5137. The sockets may include a module 4820 as illustrated in FIG. 2. The electrical device 5150 may include a rail or bus bars block 5135, for example, to provide a common ground to the electrical device 5150.

The casing of the panel may be a standard casing with the attachments for securing the wires coming from the field. The wires from the field may be directly connected to the sockets 5137 to the PCB modules hosted in the sockets 5137.

In the examples of FIGS. 51A-51C, the isolation connecting block 5120 is an example of a two phase arrangement. The isolation connecting block 5120 may also have one phase or three phases. The isolation connecting block 5120 may include but not limited to a plurality connectors or contacts 5121, 5122, 5123 and 5125. In the example of FIGS. 51A-51C, the connector 5121 is connected to the live power line 5113, the connector 5122 is connected to the neutral line, and the connector 5123 is connected to the ground line. And the connector 5125 is connected to the earth ground.

The railing system 5160 of the electrical device 5151 may include 5-9 connectors. In the example of FIG. 5C (2), the railing system 5160 includes 9 connectors for a three phase arrangement. The rails 5136 may be removed in a two phase arrangement. In a one phase arrangement, both the rails 5136 and 5134 may be removed. In some examples, one of 5132, 5133, 5134, 5135 and 5136 rails may be in first and second railing systems 5160, one rail may be used per row of the sockets 5137. The rails 5132-5136 may be bus bars.

FIG. 5C (3) is a side view of the boarder of the railing system 5160 showing the side encasement of the railing system. The bottom end of the railing system 5160 may be capped, and the top end of the railing system 5160 may be connected to the connecting block 5120.

In the example of FIG. 5C(4), a main motherboard 5138 may be included and placed on top of the railing system 5160 with a socket system or a Breaker clip top of the PCB placed on the mother board 5138.

FIG. 5D illustrates an example of the rail system 5160, which includes a plurality of air gaps 5161 for dissipating heat generated by the rail system 5160 or the mother board 5138. For example, the hot air heated by the rail system 5160 or the mother board 5138 may be dissipated through the air gap.

In some examples, the electrical device 5101, 5150, or 5151 comprises: a plurality of electrical devices 5137, each electrical device 5137 comprising a first contact 5121 for electrical connection to a respective upstream hot power line 5113, a second contact 5122 for electrical connection to a respective neutral power line 5114, and a third contact 5123 for electrical connection to a respective upstream ground line 5115; each electrical device 5137 comprising a fourth contact 5132 for electrical connection to a respective downstream hot power line, a fifth contact 5133 for electrical connection to a respective downstream neutral power line, and a sixth contact 5134 for electrical connection to a respective downstream ground line; a bus 5135 for electrically connecting all of the downstream ground lines.

The electrical device 5101, 5150, or 5151 may further comprise at least one sensor in series relationship between one of the upstream power lines 5113 and one of the downstream power lines for detecting signals. The at least one sensor may include at least one current transducer.

Each electrical device 5137 may include a switch in series relationship between the first contact 5121 and the fourth contact 5132, for controlling conductive connectivity between the respective upstream hot power line 5113 and the respective downstream hot power line, responsive to the signals detected by at least one of the sensors.

The at least one sensor may include a respective sensor for each electrical device 5137 in series relationship between the first contact 5121 and the fourth contact 5132 for detecting signals indicative of one of the respective hot power lines, for controlling at least one of the switches.

The at least one sensor may include a respective sensor for each electrical device 5137 in series relationship between the second contact and the fifth contact for detecting signals indicative of one of the respective neutral power lines, for controlling at least one of the switches.

Each electrical receptacle may include a respective filter or diode in series relationship between the third contact 5123 and the sixth contact 5134, for filtering or one-way conductive connectivity from the respective upstream ground line to the respective downstream ground line.

The electrical device 5101, 5150, or 5151 may further comprise at least one communication subsystem configured for wired communication over at least one of the downstream power lines with reference to the downstream ground line. The one of the respective downstream power lines for the wired communication may be the respective downstream neutral power line, or the respective downstream hot power line.

The electrical device 5101, 5150, or 5151 may further comprise at least one communication subsystem configured for wired communication over at least one of the upstream power lines with reference to the upstream ground line.

The electrical device 5101, 5150, or 5151 may further comprise a circuit board that contains the plurality of electrical devices, the circuit board include the bus for the electrically connecting of all of the downstream ground lines.

In some examples, the bus comprises a rail 5132, 5133, 5134, 5135, or 5136. In some examples, the bus the bus is for connecting to earth ground.

The electrical device 5101, 5150, or 5151 may further comprise a second bus 5131 for electrically connecting all of the downstream neutral lines without connecting to the upstream neutral lines 5114.

The electrical device 5101, 5150, or 5151 may further comprise a plurality of circuit boards, wherein a first circuit board includes the bus and a second circuit board includes the second bus 5131.

The electrical device 5101, 5150, or 5151 may further a plurality of circuit boards, wherein a first circuit board includes the bus and a second circuit board includes the first contact 5121 for electrical connection to the respective upstream hot power line 5113.

A RS485 connected display screen 5200 may include a cover 5202 and a base 5203. FIG. 6 illustrates a front view of cover 5202 and a rear view of a base 5203 of a RS485 display screen 5200.

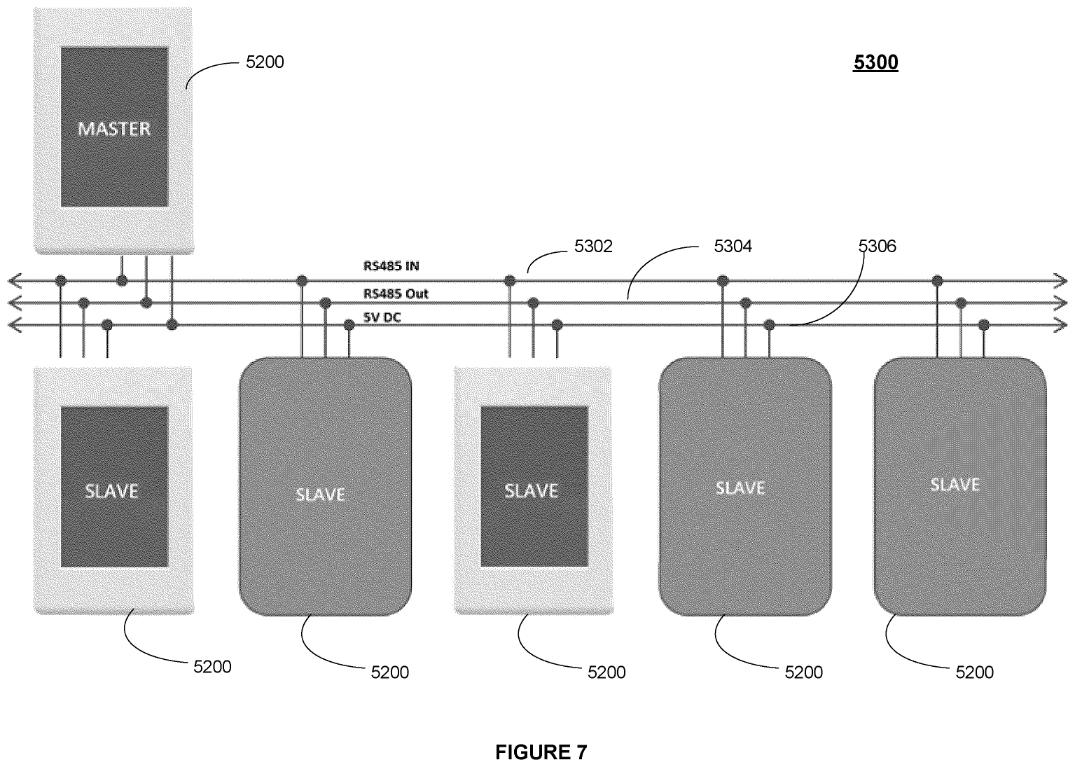

As illustrated in FIG. 7, a number of display screens 5200 may be connected via serial communications ports (or interfaces) such as RS485 or USB, to form a display screen network 5300. In the example of FIG. 7, the display screen network 5300 includes a master RS 485 display screen 5200, and five slave RS 485 display screens 5200. Each RS 485 display screens 5200 is connected to a RS485 in signal line 5302 for slave RS 485 display screens 5200 to receive input signal from the master RS 485 display screen 5200, a RS485 out signal line 5304 for slave RS 485 display screens 5200 to transmit signals to the master RS 485 display screen 5200. The 5V DC line 5306 supplies 5V DC to the master and slave RS 485 display screens 5200.

The RS485 display screen 5200 may be mounted on the wall and the RS485 display screen 5200 may be Display-Control Mod Breakers. The RS485 display screen 5200 may have a Display/Control Module (DCM) 5204.

As illustrated on the rear view of the RS485 display screen 5200, the Display-Control Module (DCM) 5204 is configured to be mounted in to a standard light switch metal electoral box (single gang), which enables quick and easy installation in to a wall. The Display-Control Module (DCM) 5204 may be mounted into an enclosure or panel, and may have a wide range of uses for different applications. The DCM 5204 may be mounted without an electrical box. In some examples, DCM 5204 has two holes for the RJ35 cables 5205 and at least two fasteners, such as two mounting screws for in one of the upper three mounting holes 5207 and in one of the lower three mounting holes 5209 to fix the DCM 5204, such as on a wall. In use, the cover 5202 may be clipped on or removed from the base portion 5203.

The DCM 5204 may include a 3.5″ 320×480 TFT LCD Display, a processor, a Resistive Touch, micro-SD memory storage, a Real Time Clock, 4 wire RS485 serial Interface which can act as either Master or Slave RS 485 display screens 5200. The display, Resistive Touch, micro-SD memory storage, Real Time Clock, and 4 wire RS485 serial Interface are electrically connected with the processor. The processor may contain a Crypto Authentication security engine for securing the data transmissions, and support an Optional Wi-Fi module for wirelessly communicating the data with a wireless receiver, such as a computer, a tablet, or a smart phone.

The DCM 5204 is typically connected, by a single RJ-45 cable, to the other devices, such as a circuit breaker panel, an electrical junction box that is adjacent to the circuit break panel, an in-line power receptacle, a metering device, or an intelligent junction box. The cable uses 2 of the 4 pairs of conductors to carry a full-duplex RS485 serial data stream. For example, one pair of conductors receive data and the other pair of conductor transmit data. The other 2 pairs of conductors may supply 5V DC to power the DCM device 5204.

Other communication ports and interfaces may be used. As well, converters may be incorporated, such as RS485 to USB or Ethernet; and cabling such as CAD5 or CAD6 may be used. The application may use wireless communication to and/or from the display(s).

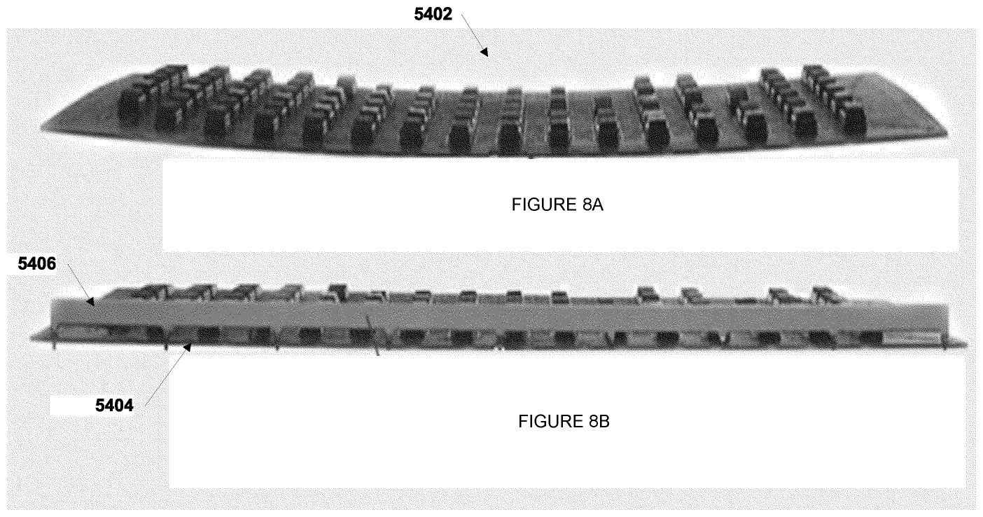

FIGS. 8A and 8B illustrate two exemplary power breakers or distributed panel modules. FIG. 8A illustrates a first power breaker or distributed panel module 5402. The circuit board of the module does not include a stiffener. FIG. 8B illustrates a second power breaker or distributed panel module 5404 on which a powder coated busbar 5406 covers some of the electronic components placed on the circuit board. In some examples, the busbar 5406 provide wide traces to enable the busbar 5406 serve as a high voltage power rail on the circuit board to provide the high amperage. The circuit board may be a PCB.

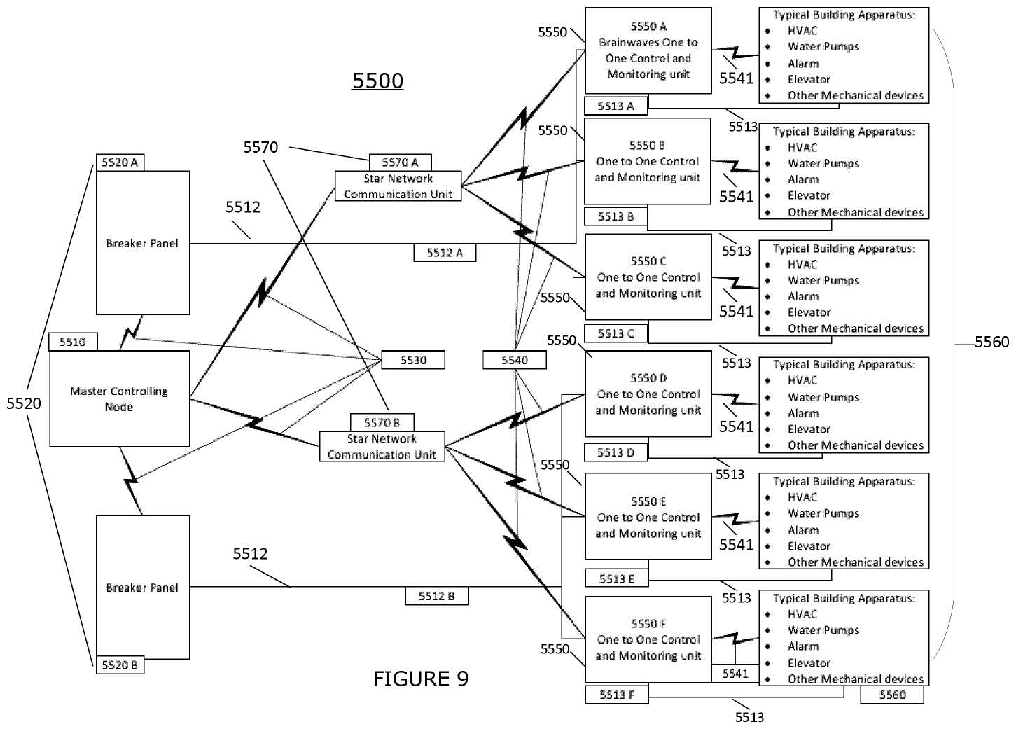

FIG. 9 illustrates an example of a power supply monitoring and controlling system 5500. The system 5500 may be used, for example, for monitoring and controlling power supply of a building. The system 5500 may be a PLC application system. The system 5500 may include one or more master controlling node 5510, one or more breaker panels 5520, one or more star network communication units 5570, one or more control and monitoring units 5550, one or more electrical devices 5560. The master controlling node 5510 may selectively control power supply to the electrical devices 5560 connected therewith, for example, by switching on or off the power supply from the breaker panels 5520 to one or all of the electrical devices 5560.

The Master Controlling Node 5510 monitors and controls the building management monitoring and control system 5500. In the example of FIG. 9, the Master Controlling Node 5510 communicates with two breaker panels 5520A and 5520B and two Star Networks Communication Units 5570A and 5570B. In some examples, the Master Controlling Node 5510 may communicate with one or more breaker panels 5520, and/or with one or more star network Communication Units 5570. In some examples, system 5500 may only include the master controlling node 5510 and control and monitoring units 5550, and the master controlling node 5510 may directly communicate with one or more Control and Monitoring units 5550 with the breaker panels 5520 or star network communication unit 5570 via the communication links.

The Master Controlling Node 5510 receives information from one or more breaker panels 5520, such as from 5520A and 5520B. In some examples, each of the Master Controlling Node 5510 may connect to up to 16 breaker panels and/or star network communication units 5570. The breaker panels 5520 may receive power input from the utility company. In some examples, the Master Controlling Node 5510 may operate as a power switching device. If the breaker panels 5520 are appropriately configured, the Master Controlling Node 5510 may be managed by a database, and an entry in the priority table that manages the order of the priority may control the power switching. The Master Controlling node 5510 may communicate with the breaker panels 5520, for example, by receiving information from the breaker panels 5520, and/or sending commands to controls the delivery of the power to one or more of the breaker panels 5520. For example, the Master Controlling node 5510 may control the breaker panels 5520A and 5520B to supply electricity to different electrical devices 5560 with different amperages.

In some examples, the master controlling node 5510 may include a processor for controlling the system 5500. The master controlling node 5510 may use Linux operating system.

In some example, the system 5500 may include more than one master controlling node 5510. Each Master Controlling Node 5510 may be connected with and control multiple star network Communication Units 5570, and/or breaker panels 5520. Each of the star network Communication Unit 5570 may have various network configurations. Each Star Network Communication Unit 5570 may connect or control one or more control and monitoring units 5550. In some examples, the control and communication unit 5550 may include a processor configured to send, through the star network communication unit 5570, a communication that one of the circuit breakers 5520 has opened or tripped to the master controlling node 5510. In some examples, a star network communication Unit may connect up to thirty-two or more units of control and monitoring units, depending on hardware limitations. The limitations are hardware driven and may be modified to handle up to 255 devices.

Various communication links may be used in system 5500. In the examples of FIG. 9, links 5540 may provide communication links between 5570 and 5550 using for example RS485 communications. In the examples of FIG. 9, the Star Network Communication unit 5570A is connected to each of three control and monitoring units 5550 A-C by a communication link 5540; the Star Network Communication unit 5570B is connected to each of three control and monitoring units 5550 D-F by a communication link 5540. Each of the Star Network Communication units 5570A and 5570B may connected to fewer than three control and monitoring units 5550. The Star Network Communication unit 5570A and 5570B may control the respective control and monitoring units 5550 connected thereto. 5540 is the communication Link using Power line communication.

System 5500 may also include communication links 5530 each for connecting the Master Controlling Node Block 5510 to the Breaker Panel(s) 5520A and 5520B, or to the Star Network Communication Unit(s) 5570 A and 5570B. The communication links 5530 provides communications between the Master Controlling Node Block 5510 and the Breaker Panel(s) 5520A and 5520B, or to the Star Network Communication Unit(s) 5570 A and 5570B. The communication links 5530 may use TCP/IP communication protocols. The communication links 5530 may be power lines In some examples, the measurement data from the start network communication units 5570A and 5570B and the breaker panels 5520A and B, are transmitted to the master controlling node 5510 and the control data from the master controlling node 5510 to the the start network communication units 5570A and 5570B and the breaker panels 5520A and 5520B may be transmitted via the links 5530.

The system 5500 may also include links 5541 each for connecting a control and monitoring units 5550 to one or more electrical devices 5560. The links 5541 may be used to transmit data between the control and monitoring units 5550 and the electrical device 5560. The data may include control data from the control and monitoring units 5550, and measurement data from the electrical device 5560. The control and monitoring units 5550 may process the received data form the electrical devices 5560, and then transmit the processed data to the star network communication unit 5570 connected with the control and monitoring units 5550. The control and monitoring units 5550 may transmit data received from the electrical devices 5560 to the star network communication unit 5570 connected with the control and monitoring units 5550. In the example of FIG. 9, the system 5500 includes six communication links, each connecting the electrical devices 5560, such as the sensor(s) of the electrical devices 5560 to the Control and Monitoring Unit(s) 5550, such as 5550A-F. The sensors may include, but is not limited to, temperature sensors, monitoring friction sensors, vibration sensors, motor/engine noise sensors, smoke detection sensors, CO detection sensors, water flood detection sensors, and other sensors, which may directly or indirectly related to the electrical devices 5560 or the environment.

Power supply links 5513, such as 5513A-F, provides the electrical connections, between the Control and Monitoring Units 5550A-F and the electrical devices 5560. Power supply links 5513 may be electricity cables. Each of the power supply links 5513 may deliver electricity from a control and monitoring unit 5550 to one or more electrical devices 5560. The electricity provided by the control and monitoring unit 5550 are received by the control and monitoring unit 5550 from the breaker panel 5520 via the link 5512.

In some examples, the electrical devices 5560 may be configured in a star network topology by connecting to the star network communication units 5570. The system 5500 may monitor and control the electrical devices 5560 and report information regarding the operations of each of the electrical devices 5560. In the example of FIG. 9, electrical devices 5560 are examples of, but are not limited to, typical devices that may be connected to other electrical equipment, alarm systems, or devices that may be monitored such as HVAC, water pumps, elevators, escalators, alarms, electrically driven mechanical devices, etc. In some examples, each electrical device 5560 may include sensors, such as sensors for use in a building, for monitoring the status of the devices 5560. The system 5500 may operate with one or more of the electrical devices 5560. The electrical devices 5560 may be distributed in different units of a building or in different places of a facility.

For illustration purposes three Control and Monitoring Units Blocks 5550A-C are connected to one breaker panel Block 5520A and three other Control and Monitoring Units Blocks 5550D-E are connected to another breaker panel Block 5520B. Alternatively, the system 5500 may be designed to operate with fewer or more electrical devices 5560, fewer or more Control and Monitoring Units 5550, and/or fewer or more breaker panels.

One or more breaker panel connections 5512 each may be used to connect the breaker panel 5520A or 5520B to one or more control and monitoring units 5550. In the example of FIG. 9, 2 breaker panel connections blocks 5512A and 5512B each may be connected to one or more control and monitoring units 5550. For example, breaker panel connections 5512A is connected with control and monitoring units 5550 A-C, and breaker panel connections 5512B is connected with control and monitoring units 5550 D-F.

Breaker panel connections 5512 A and 5512B provides electrical connections from the breaker panels 5520A and 5520B to the electrical devices 5560 via the Control and Monitoring Units 5550 A-F. Breaker panel connections 5512A and 5512B connected with the breaker panels 5520A and 5520B, respectively, may be configured as one, two or three phases. The Control and Monitoring units 5550 may use Triacs or IGBTs, or relays of the Control and Monitoring units 5550 for controlling the delivery of power to the devices 5560.

The control and monitoring unit 5550 may be connected to one or more breaker panels 5520 for receiving power supply from the breaker panels 5520. In the example of FIG. 9, control and monitoring units 5550A-C are electrically connected to the breaker panel 5520A via block 5512A and control and monitoring units 5550D-F are electrically connected to the breaker panel 5520B via block 5512B. Each of the control and monitoring units 5550 A-F may connected to one or more electrical devices 5560.

In an example embodiment, there is provided an electrical device 5500 comprising: at least one circuit breaker 5520 for connection to at least one hot power line, and each circuit breaker 5520 configured for a downstream electrical connection to a respective downstream power line 5512; a communication subsystem 5570; and a processor configured to send, through the communication subsystem 5570, a communication that one of the circuit breakers 5520 has opened or tripped. The communication may include identifying which particular circuit breaker 5520 has opened or tripped.

In another example embodiment, the communication subsystem 5570 is configured for wired communications over the hot power line. The wired communications continue when the one circuit breaker 5520 opens one of the power lines. The at least one circuit breaker 5520 may comprise a switch. The switch may comprise a solid state switch.

In another example embodiment, the at least one circuit breaker 5520 may comprise a mechanical breaker.

In another example embodiment, an electrical receptacle device comprises a contact configured for electrical connection to a power line. The contact may be configured for downstream electrical connection to a downstream power line. The contact may be configured for connection to an electrical outlet. At least one sensor is used to detect at least voltage signals indicative of the power line. A processor is configured to determine from the detected voltage signals that a series arc fault has occurred on the power line. In some examples, in response to said determining, the processor is configured to send a communication that the series arc fault has occurred. The electrical receptacle device may comprise a switch in series connection with the power line, where the processor is configured to, further in response the said determining, opening the switch. The at least one sensor may further include at least one current sensor to detect at least current signals indicative of the power line, wherein the determining is further based on the detected current signals.

Current may or may not be affected during a series arc fault depending on the particular load of the system. For a smaller load such as a light bulb, the current may not show much of a variance, if at all, because the value of the current itself is so small. In a larger load, the current variance will be detectable during a series arc fault. A threshold current value can be used to differentiate between a small load and a large load,

In another example embodiment, the power line comprises a hot power line or a neutral power line or a ground power line.

FIGS. 56A and 56B illustrate a junction box 5800. The junction box 5800 includes a cover BLOCK 5810 and a box housing BLOCK 5820. In use, the cover BLOCK 5810 is configured to cover the box housing 5820. The cover BLOCK 5810 may incorporate LEDs for indicating the status of various conditions of the junction box 5800, such as active, not active, occurrence of a fault (series or parallel arc fault, ground fault, and more). The box housing BLOCK 5820 houses a power control and analysis module 5850. The line power input, including line and neutral wiring, and optionally ground wiring, may connect to the power control and analysis module 5850 at conductors, such as metal clips 5860. Line power may be output at least one of the output channels 5840, 5841 and 5842. More or fewer output channels may be included in the power control and analysis module 5850. The cover BLOCK 5810 may also include controllers or actuators, such as test and reset buttons for each output channels.

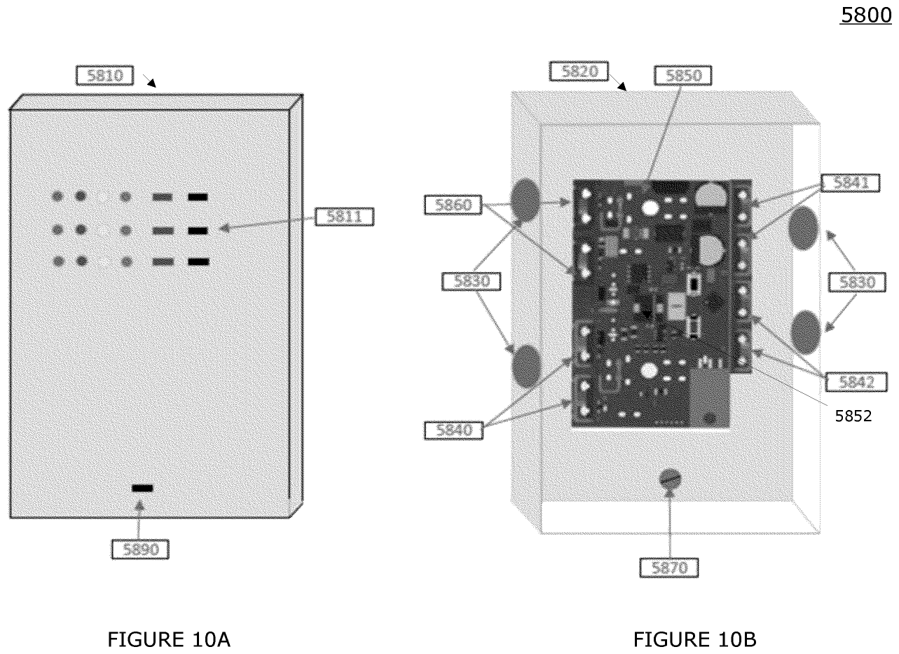

The block 5810 may include a plurality of indictors to show the status of the junction box 5800, such as the output channels of the power control and analysis module 5850. In the example of FIG. 10A, three rows of LEDs indicate the 3 output channels 5840, 5841 and 5842. The block 5810 may also include test and reset buttons for each of the channels 5840, 5841 and 5842.

The block 5810 may also include a communications port BLOCK 5890 for the junction box 5800 to communicate with an external device. A communications channel may also be incorporated directly at box housing BLOCK 5820.

BLOCK 5830 represents a single line voltage input channel, including black, neutral and ground wires. Blocks 5840, 5841 and 5842 represent 3 different output channels 5840, 5841 and 5842.

The amperage output from output channels 5840, 5841 and 5842 for this embodiment may be 15 amps or 20 amps.

BLOCK 5830 may be pass-through holes that include strain reliefs. The input and/or output wires may pass through the holes as input power for connecting to the input terminal 5860 inside the box 5820, or wires with power output from the power module 5850, such as wires forming output channels 5840, 5841 and 5842, may pass through the holes to output the power from the junction box 5800. Conductors 5860 represents wiring clips in which black (live) and white (neutral) wires are inserted of the line wire from the breaker panel or any other feeder.

On the output side, each of the 3 output channels 5840, 5841 and 5842 is monitored independently by a microprocessor 5852 on the power control and analysis module 5850 and the microprocessor may indicate the status of the output channels 5840, 5841 and 5842 on the outer surface of the cover block 5810.

The example in FIG. 10B is configured for one line voltage input, and three outputs (line voltage, neutral return and ground). However, there may be only one line input and one output channel; the microprocessor 5852 may be configured to monitor one or more input channels and output channels 5840, 5841 and 5842. The output channels 5840, 5841 and 5842 may supply power to electrical devices or components, such as lights, plug outlets, and switches.

In a star network, each circuit or load (or multiple downstream loads) may be connected to any one of the output channels 5840, 5841 and 5842. Multiple junction boxes 5800 or modules 5850 may interact with each other, and one output channel of one junction box or one module 5850, rather than supplies power to the its own output load(s) or circuit, may become the input channel to another junction box or module 5850, and a master-slave relationship between the junction boxes or modules 5850 may be formed in other configurations and embodiments.

For example, one junction box 5800 or a first module 5850 of junction box 5800 may have two output channels and a third output channel may lead to an input channel of a second junction box 5800 or a second module 5850. As such, two junction boxes 5800 or modules 5850 may result in 5 output channels to expand the output capacity of the junction boxes. Alternatively, 2 separate modules 5850 of a junction box 5800 may provide multiple channel outputs, such as, but not limited to, 4 output channels, 2 per module 5850.

The amperage of the output channels 5840, 5841 and 5842 may be 15 and/or 20 amps. The amperage of each output channel 5840, 5841 or 5842 may also be pre-set locally or remotely by the factory, the user, or a computer. In some examples, the upper limit of the current output from the output channels 5840, 5841 and 5842 may be a lower amperage such as 2 or 3 amps, for example, to protect certain equipment for example, or an amperage higher than 15 or 20 amps (e.g. 50, 100, 200), for example, to enable the box 5800 to act as a power switch for controlling the power to loads and/or circuits. In some examples, box 5800 may be a power switch for controlling power supply for other module(s) in a star network embodied in other boxes 5800 or transmitting to other modules 5850, for independent power definition and control.

Three output channels 5840, 5841 and 5842 are illustrated in the examples of FIGS. 56A and 56B. One or more output channels 5840, 5841 and 5842 may be monitored, such as delivery of power from each channel, optionally displayed and/or communicated, and controlled, through one or more communication interfaces, such as a communications port 5890, including RS485, Ethernet, USB etc.

The junction box 5800 may also include a ground mechanism 5870 in the box housing 5820, such as a ground screw to provide ground to the box 5800.

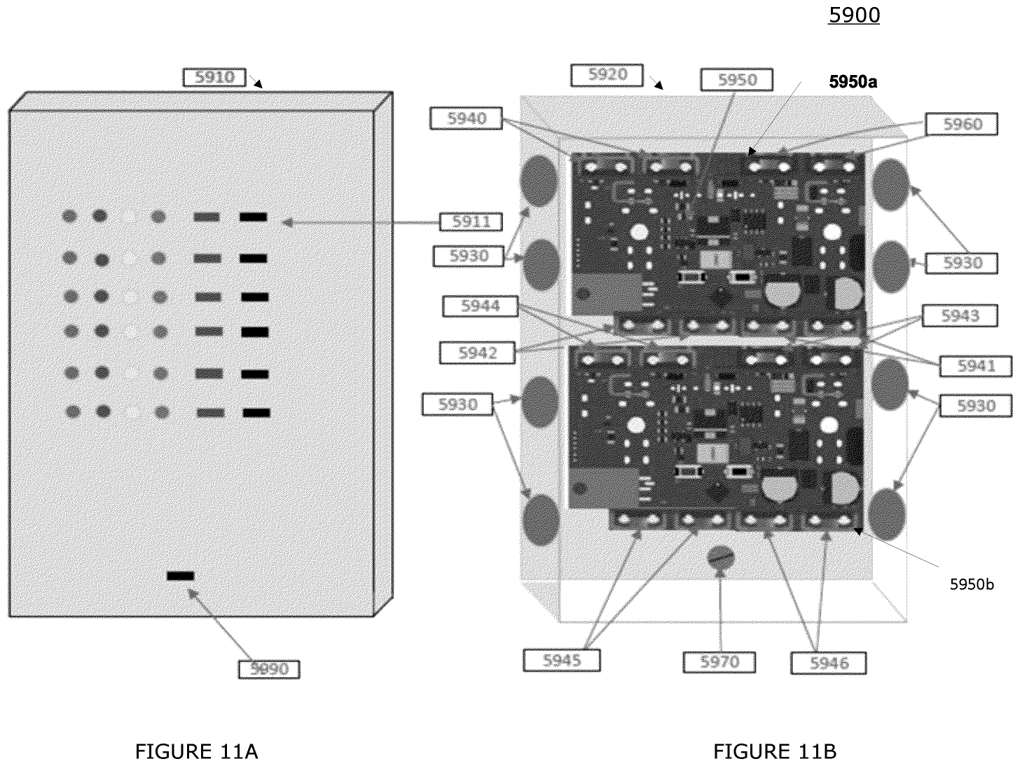

FIGS. 11A and 11B illustrate another example of a junction box 5900. The junction box 5900 includes a cover BLOCK 5910 and a box housing BLOCK 5920. The cover BLOCK 5810 may incorporate LEDs for indicating the status of various conditions of the junction box 5800, such as active, not active, occurrence of a fault (series or parallel arc fault, ground fault, and more). The cover BLOCK 5810 may include a communication channel 5990. The cover BLOCK 5910 may also include controllers or actuators, such as test and reset buttons for each output channels.

The box housing BLOCK 5920 houses a power control and analysis module 5950. The line power input, including line and neutral wiring, and optionally ground wiring, may connect to the power control and analysis module 5950 at conductors, such as metal clips 5960. Line power may be output at least one of the output channels 5941, 5942, 5943 and 5944. More or fewer output channels may be included in the power control and analysis module 5950. The box housing BLOCK 5920 may also include a ground mechanism 5970 such as a ground screw to provide ground to the box housing block 5920.

In the example of FIGS. 11A and 11B, the power control and analysis module 5950 is the 2-board assembly 5950a and 5950b that work similarly as 5850 in FIG. 10B. The combination of both boards 5950a and 5950b may provide either up to 5 output channels 5940, 5941, 5944, 5945 and 5946. The output channel 5942 serves as the power fee for inputting power to the input channel 5943 on the second module 5950b. In this case, channel 5942 may control the input of the second module 5950b. In some examples, each of these two power modules 5950a and 5950b may act as a 2-circuit assembly with each having a maximum of 3 output channels, for example, output channels 5940, 5941 and 5942 on the first module 5950a and output channels 5944, 5945 and 5946 on the second module 5950b.

The input power line would be connected to block 5960 on the module 5950a. The block 5960 also supplies power to the second module 5950b. In some example, input power line may separately connect to BLOCKS 5960 and 5943 to respectively supply power to both modules 5950a and 5950b.

The block 5930 represents a single line voltage input channel, including black, neutral and ground wires. BLOCK 5930 may be pass-through holes that include strain reliefs and has the same function as Block 5830 described above.

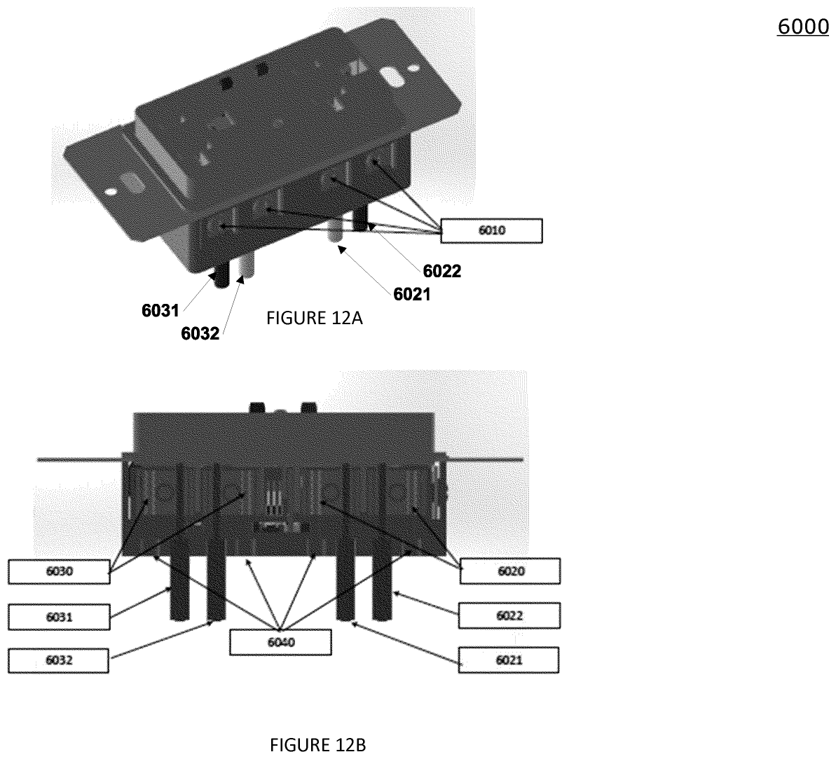

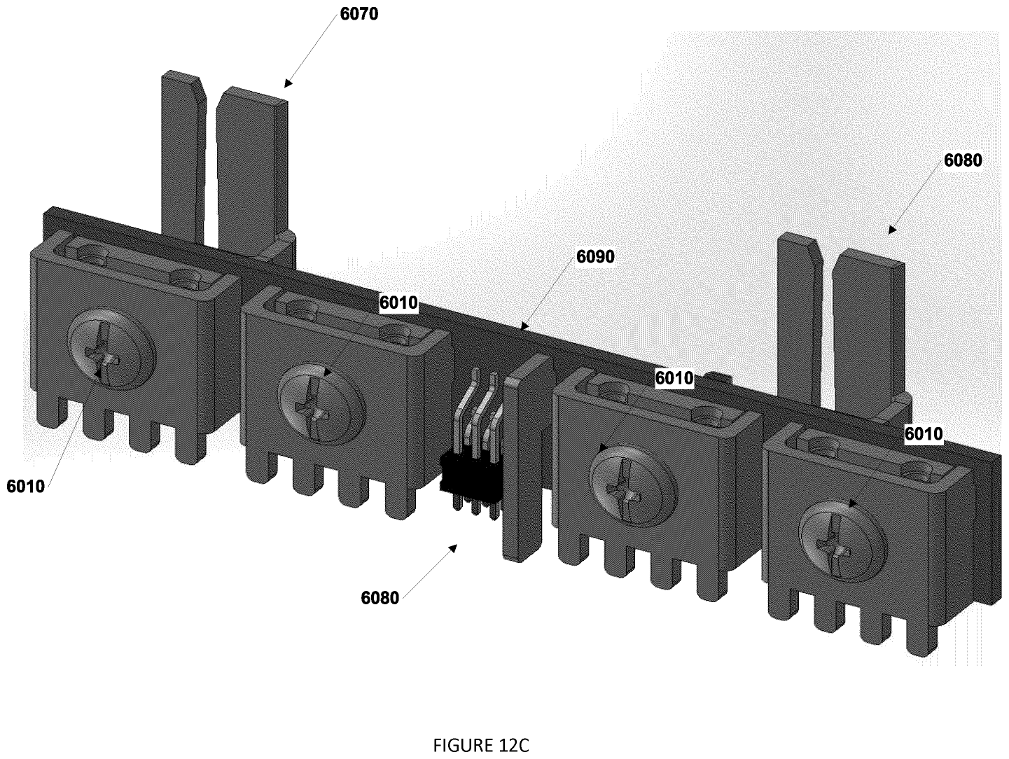

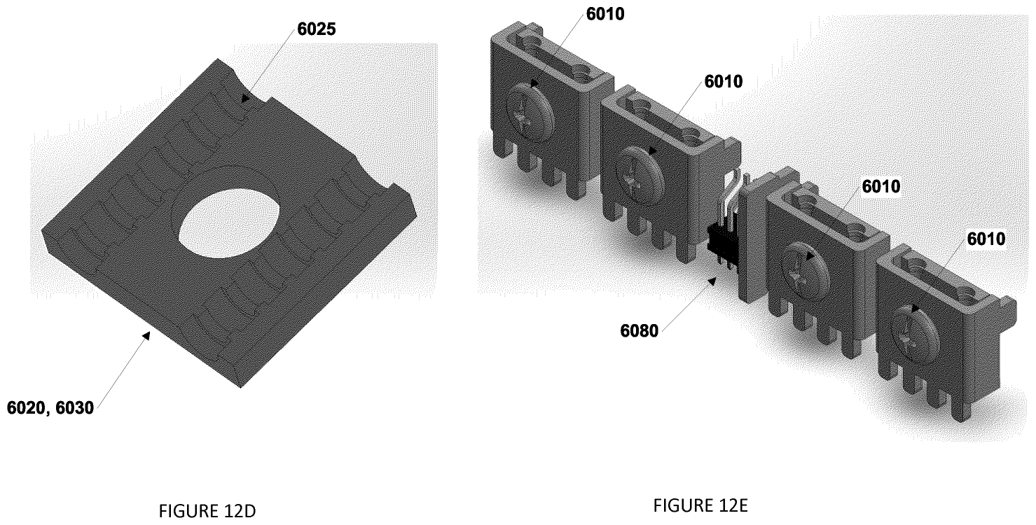

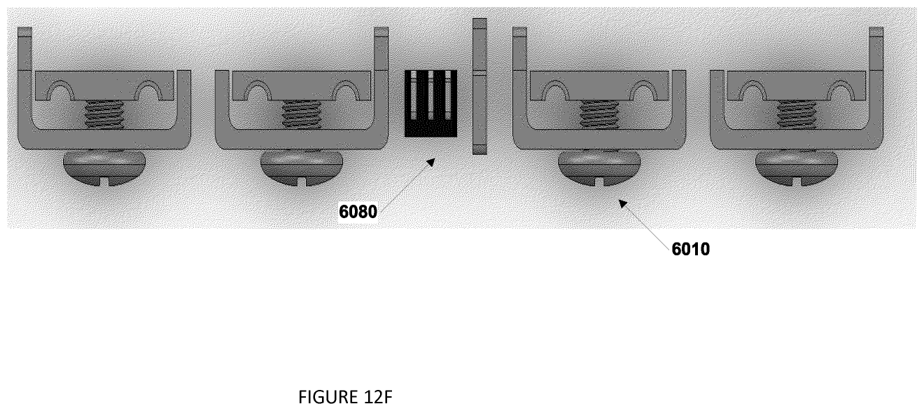

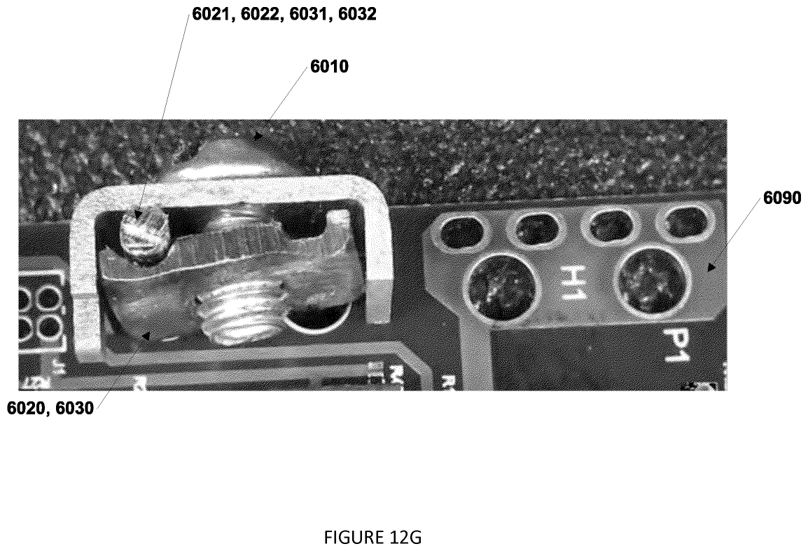

FIGS. 12A-12G illustrate an exemplary duplex outlet receptacle for preventing glowing contacts, which are known to be a cause of fires. When glowing contacts takes place, there is no arc as the conductors are touching each other, there is no spark as the mechanical connection is solid, and there is no overload or leakage, as would otherwise be present in 5 mA ground leakage present with ground fault detection. Optional downstream connections are illustrated to improve on the safety of wiring connections, for downstream use, which for example are relevant to AFCI and GFCI electrical fault detection.

Glowing contacts occur at the receptacle when the wires are insecurely looped around screws or the looped connections become loose. When the contact pressure has not been properly completely secured, a glowing contact takes place through the hairline surface touching between the screw terminal and the metal backing—the contact pressure being small and the conductor surface also being a small cross-section. The glowing takes place because the conductor's resistance is too high, as the current flows through that very small area.

Glowing contacts inside of an electrical box hosting a receptacle are not visible and thus are more important than at the end of a cord of an appliance or device such as a light bulb, hair dryer, electric drill, toaster, vacuum cleaner, etc.

In an electrical receptacle, traditional industry typically wraps the wiring loops around a screw and the screw provides conductivity. Whether wire is inserted through holes in the back, or the wiring is looped around the screw, the wiring contact can become loose, potentially causing a dangerous glowing contact electrical fire risk.

A need exists for an improved means of connecting wires, providing a larger surface of conductivity and improved strain relief to minimize possibility of a contact becoming loose.

The need exists to provide discontinuance of power should there be “glowing contacts”. These may take place at many levels whereby connections may be loose, at the wiring connections in receptacle devices or at the end of cords connected to appliances on the load (e.g. light bulb, hair dryer, electric drill, toaster, vacuum cleaner, etc.).

It is desired to detect glowing contacts, to reduce the risk of fires caused by glowing contacts, and even to eliminate glowing contacts at a receptacle outlet, through mechanical design embodiments herein illustrated in FIGS. 12A-12G. The mechanical designs may prevent looping of the wires at the contact point(s) and attachment of wires externally to the receptacle, eliminating bad connections. As well, without the glowing contacts, the plastic will not melt as device discontinues the delivery of power if temperature increases, thereby reducing another potential fire risk caused by glowing contacts.

The mechanical design in the examples of FIGS. 12A-12G illustrate a mechanical separation of the black and white wiring, such that looping of wiring is not permitted during installation, thereby eliminating the majority of the causes of loose connections at the receptacle outlet level. Without looping of wiring, the occurrence of glowing contacts are significantly reduced.

The disclosed connector assembly comprises a front clip, back clip and a screw that applies a force, whereby the design ensures that the screw cannot be in contact with the inserted wire, is not used for conductivity but rather as a pressure means. In another embodiment, another pressure means could be used. Other fasteners can be used instead of the screw in other examples.

Illustrated is embodied in an electrical receptacle but can be applied to other devices, including but not limited to adaptors, junction boxes, cables, power plugs and breakers. The gripping means integral to the structure, is a significant improvement over traditional means whereby wires are inserted and held in place with minimal strain relief and security, and are easy to pull out.

Disclosed is an insertion method/means through a channel, whereby the wire itself has a larger contact surface area, contact is made with a larger surface area of a metal screw terminal, comprising of two components screwed tightly, and one part of the screw terminal being attached on a circuit board, the second part being connected to the first part, and it being attached to a second circuit board.

In the particular embodiment FIGS. 12A-F, the screw terminal is attached to a power sensor board 6090, which itself is attached to a mother board (having a CPU) and part of the screw terminal incorporates four pins which are inserted into the mother board providing connectivity and further rigidity. The sensor board 6090 is a printed circuit board (PCB). The hole of the PCB is offset from the side of the front clip, therefore when pressure is applied from the screw to bring in the back clip, the conductor is slightly bent while being pushed to the front clip providing additional physical resistance preventing the wire to be pulled out without unscrewing the assembly.

Other embodiments are possible with our without downstream means, variations in location of black and white wiring in and out of the electrical device (which need not be an in-wall electrical receptacle, including but not limited to adaptors, junction boxes, circuit breakers, corded devices, load centers, switches and more), and the attachment means of the terminal assembly which need not be attached to any particular circuit board.

The concave channels in at least a first portion of a wiring screw terminal assembly (screw means being one example of a pressure means) provide conductivity contacting the wiring, rather than the screw—and the ridges (teeth) provide additional conductivity and strain relief.

The wires passing through the screw terminal neither touch the screw, nor depend on contact with the screw for conductivity; and accordingly do not touch the screw itself. The wire is not in direct contact with the screw itself, and rather derives its conductivity from the metal screw terminal—the round concave portion of the channel providing the conductivity and squeezing the wire to the front clip.

In addition, and optionally, conductive, metal teeth provide a better contact reducing the resistance and providing additional conductivity (e.g. and breaking up oxidization which may have built up on the surface of the wire) and additional strain relief.

FIGS. 12A-12G illustrate exemplary connectivity of a receptacle FIG. 12A Block 6000. FIG. 12G, Block 6010 points to the terminal screws of the receptacle 6000, the screws are indented inside the casing, as also illustrated in FIGS. 12C and 58G. This arrangement has two major advantages: First, the screw cannot create a short with the electrical housing customary used by code to house any receptacle. Second, the screws do not come out, therefore it is impossible to connect any wires outside the receptacle 6000. This may prevent glowing contacts from faulty connections, a major source of electrical fire.

In FIG. 12B the Block 6040 shows the housing and wire guides for the insulated conductor connecting to the receptacle 6000 (FIG. 12A) and enabling the wires to be installed inside the outlet. This arrangement prevents shorts between conductors, another source of electrical fire. Block 6040 also incorporates mechanical strain relief, as a portion of the insulation enters the body of the receptacle 6000 and provides integral strain relief to the wires entering the receptacle 6000. In FIG. 12F the four screw terminal assemblies illustrated from left to right are for black wire (line), white wire return (neutral), white wire return (neutral) and black wire (line) with each terminal incorporating a second channel for optionally enabling parallel connections. For example, power for lighting might to a switch and then to a light(s), the second hole being used for wiring for another downstream circuit. A ground fault circuit interrupter receptacle device might want to be used whereby wiring goes both to downstream and to lighting. The use of this screw terminal assembly system can be an alternative to, and advantageous over the use of traditional twist-on wire connectors, and provide superior connection with less possibility of loose connections.

In another embodiment, one of the two holes in any of the screw terminals could be covered preventing and limiting entry to only one wire accessing the particular screw terminal.

FIG. 12C also illustrates the embodiment within an electrical receptacle device having two outlets—pins 6070 and 6080 providing white wire returns for each, respectively. Block 6060 is a power bus transmitting energy through the sensor board 6090 to the main board. In this particular embodiment, the back clip FIG. 12D would be attached to the sensor board 6090 and the companion front clip would be attached (seventeen teeth shown) and soldered to a main processor sensor board 6090 (horizontally positioned) providing further rigidity. Blocks 6031 and 6032 jointly are the power feed to the receptacle 6000. Block 6031 shows that the hot feed conductor is connected to the terminal, and Block 6032 shows that the neutral feed conductor is connected to the terminal. Block 6030 shows a space for a parallel connection for both the Hot and Neutral lines, and this is a possible unmonitored connection to one or multiple downstream equipment.

The terminal in the examples in FIGS. 12A-12G allows both the feed and parallel connections. Both feed and parallel connections provide a safe connection as well as maximizing the connection surface with the conductor. In conjunction with the terminal and block 6040, a tunnel is created limiting the possibility for any short from either the feed or the downstream connections.

Blocks 6020, 6021 and 6022 are jointly the downstream monitored connection to one or multiple downstream electrical devices. The receptacle 6000 may in this case control and/or monitor the entire circuit. Block 6022 shows the hot feed conductor connected to the terminal, and Block 6021 shows the neutral feed conductor connected to the terminal. Block 6020 shows the connection point for a second monitored connection point for more electrical devices.

FIG. 12D Blocks 6020 and 6030 shows the rear portion of the wire retainer contacts. The rear portion (back clip) defines a channel/recess that is formed with ribbed recesses (teeth) 6025, and this increases the contact area of the retainers to the wire. The formed rear retainer shape wraps around the wire so it is not just a round wire pressed between two flat pieces of metal; as well, the recess is ribbed so it bites into the wire to increase the effective pressure holding the wire. The recess also reduces inherent contact resistance, thereby increasing the contact-to-wire surface area.

As loose connections at connection points in receptacle outlets are eliminated, physical mechanical design in FIGS. 12A-12G prevents the looping of wires and therefore prevents glowing contacts from occurring. This protect the body of the receptacle 6000 from melting as a result of glowing contacts.

When a glowing arc occurs in an electrical receptacles, analysis performed by the processor can be used to detect changes in the root mean square (RMS) over one or more cycles of the power signal. Mean square is first calculated to determine RMS, and mean square can be used instead of RMS in example embodiments as applicable. In some examples, the processor may determine from the detected voltage signals that the series arc fault has occurred by calculating a mean square or root mean square of individual cycles of the detected voltage signals and determines that there are at least two consecutive cycles of decreases in the mean square or the root mean square of the detected voltage signals. This analysis is described in greater detail herein in relation to series arc faults.

The mechanical design illustrated in FIGS. 12A-12G discloses a mechanical separation of the black and white wiring, such that looping of wiring is not feasible during installation, therefore eliminating the majority of the causes of loose connections at the receptacle outlet level. Without looping of wiring, the occurrence of glowing contacts are significantly reduced.

An example embodiment is an electrical device including: a conductive housing defining a first channel for receiving a power line, and a second channel; a fastener between the first the second channels for tightening the power line to the first channel, a head of the fastener engaging the power line and the conductive housing when tightened, the head being nested within an exterior of the conductive housing when tightened.

Another example embodiment is an electrical device including: a conductive housing defining a first channel for receiving a power line, a fastener for tightening the power line to the first channel, a head of the fastener engaging the power line and the conductive housing when tightened, the head being nested within an exterior of the conductive housing when tightened.

In an example of the electrical device, the fastener contacts the conductive housing without contacting the power line.

In an example of the electrical device, the conductive housing includes a first conductive part and a second conductive part that collectively define the first channel.

In an example of the electrical device, the first channel includes one or more ribs for crimping contact with the power line. In an example of the electrical device, the fastener is a screw and the head is a screw head. In an example of the electrical device, the power line does not wrap around the screw. In an example, the electrical device further comprises a conductive element conductively connected to the conductive housing for electrical connection to an electrical outlet or for downstream connection.

In an example, the electrical device further comprises a circuit board that comprises the conductive element. In an example, the circuit board includes an opening for receiving direct connection to the power line.

In an example of the electrical device, the power line does not wrap around the fastener. In an example, the electrical device is for preventing of glowing contact between the power line and the conductive housing. In an example of the electrical device, the fastener and the head are conductive. In an example of the electrical device, the first channel is generally perpendicular to the second channel.

Example embodiments of the electrical device are used to detect glowing contacts. In example embodiments, the electrical device captures all the signal data of the power line. Glowing contacts can be detected and tripping can take place—by analyzing the electro characteristics of parameters captured, the voltage, current, the differential current. The glowing contact is detected by looking at differentials and amount of load.

In example embodiments, the electrical device also includes a ground fault detector built in. In example embodiments, temperature sensors are used as well for detecting glowing contacts. A glowing contact that raises the temperature would cause the electrical device to trip; i.e., delivery of power is discontinued.

In an example embodiment, an electrical device, which may be an electrical receptacle, includes a first contact and a second contact configured for electrical connection to a hot power line and a neutral power line, respectively, the first contact and the second contact for downstream electrical connection to a downstream hot power line and downstream neutral power line, respectively; a switch connected in series relationship to the hot power line; at least one sensor configured to detect signals of the hot power line and/or the neutral power line; a memory; a communication interface; and at least one processor configured to execute instructions stored in the memory for: i) automated control of an activation or a deactivation of the switch in response to the signals detected by at least one of the sensors, ii) control of the switch in response to receiving a communication over the communication interface, iii) processing raw information of the signals detected by the at least one sensor to arrive at processed information, and storing the raw information and the processed information to the memory, and iv) sending at least the processed information through the communication interface. The processing raw information of the signals includes calculating power factor. The processing raw information of the signals may include performing frequency analysis, such as Fast Fourier Transform (FFT). The processing raw information of the signals may include calculating output power. The automated control may be for power distribution control and/or safety control.

The at least one processor may include a programmable logic controller (PLC) configured to have preprogramming to perform the automated control; the communication interface comprises a serial communication interface for wired communication to the at least one processor; and the at least one processor executes a MODBUS protocol over the serial communication interface to: receive command through the serial communication interface for the preprogramming of the PLC, receive command through the serial communication interface for the control of the switch, and send at least the processed information through the serial communication interface. The at least one processor may execute the MODBUS protocol over the serial communication interface to send the raw information of the signals from the memory through the serial communication interface. The at least one processor may be configured to determine a condition of the hot power line or the neutral power line from the signals detected by the at least one sensor, and perform any one of i)-iii) set out above in response to the determined condition. The at least processor comprises a universal asynchronous receiver-transmitter (UART) for communication over the communication interface

The switch may be controlled to achieve a specified power factor to the downstream hot power line by comparing the calculated power factor to the specified power factor. The specified power factor may be achieved by cycle stealing and the partial power output may be achieved by cycle stealing.

The at least one sensor may comprise a current sensor; the processor is configured to control deactivation of the switch in response to the detected current of the current sensor output indicative of ground fault, arc fault or over-current conditions. Each of the at least one sensor is in series relationship to one of the power lines. The switch may be controlled to achieve a partial power output.

The downstream electrical connection may be to a plug outlet of the electrical device. The downstream electrical connection may be to a second electrical device.

The electrical device may further include a second switch connected in series relationship to the neutral power line.

The memory may include a first buffer and a second buffer, and the at least one processor is configured to store the raw information to the first buffer and store the processed information to the second buffer.

An example embodiment is an electrical device, for example a metering device, configured for distributing power, which includes: a first contact, a second contact, and a third configured for electrical connection to a hot power line, a neutral power line, and a ground line, respectively, the first contact, the second contact, and the third contact for downstream electrical connection to a downstream hot power line, downstream neutral power line, and downstream ground line, respectively; a switch connected in series relationship to the hot power line; at least one sensor configured to detect signals of the hot power line and/or the neutral power line; a memory; a communication interface; and at least one processor configured to execute instructions stored in the memory for i) automated control of an activation or a deactivation of the switch in response to the signals detected by at least one of the sensors, ii) control of the switch in response to receiving a communication over the communication interface, and iii) storing raw information of the signals and/or processed information of the signals to the memory.

The at least one processor may be configured to send the raw information and/or the processed information through the communication interface. The power distribution device may be a power distribution cabinet. The communication interface may be a wired communication interface.

There can be 3 categories of arc faults: Parallel Arcing: between black wire (live) and ground; Parallel Arcing: between black wire (live) and white wire (neutral); Series Arcing: within a black wire, or within a white wire. Industry AFCI's will trip on shorts (results in overload), overload (overcurrent) and leakage rather than actual arcs. They measure the residual energy of the difference, and detect arcs on that basis. As the industry does not detect series arcs directly, the existing fault detection mechanisms respond once there has been sufficient electrical damage to create a ground fault before tripping.

As the AFCI technology traditionally used in the industry looks at current differentials, AFCI breakers, for example do not trip until detecting current overload, they have limitations in being able to detect, e.g.: i) one type of parallel arc; namely, between the black and white; and ii) two types of series arcs; namely those that occur between the black and black, and between the white and white. The industry presently detects indirectly that a series arc fault has occurred.

As the current can stay the same on the black (phase line) or the white (neutral line—return path) wire experiencing a series arc, despite a series arc taking place, traditional means and methods based on identifying current imbalances will not recognize that an arc in series took place (until it is too late that a flame may have already ignited).

Traditionally, the industry use analog only, measuring current differential using magnetic circuits, affected by magnetic fields. Detection of arc faults or ground faults is based on examining differences in the magnetic field. Traditional industry leaves the signals in analog only, amplifying the differential and using it to activate the switch.

Ground fault (GFCI) testing involves differential between the black and the white; e.g. leakage to the ground.

When discussing Arc Faults, the industry often refers to there being a differential in currents; namely between the black and the white there being a 70 milliamp differential current. They are referring to the RMS (averaged) value difference.

The problem with this approach is that if you are looking for a difference between the averages of the black and the white, you won't find any; e.g. RMS value difference will be zero.

Industry electromechanical devices work on thermal effects of the currents. They don't look at the waveform, rather averaged net effects of the current. They basically respond to the “effective” value, not how it is varying. They are measuring the magnetic effect of the leakage current. Traditional industry does not look at the wave form.

In example embodiments, an electrical device digitizes the analog input. Furthermore, the electrical device uses analog for the differential data. RMS (root mean squared) averaging has an equivalence to an equivalent DC. As the current is varying the electrical device finds out what equivalent effect would be if there were a DC circuit there. The RMS value measures the effectiveness of the current, irrespective of its variation.

Parallel Arcs may take place between: i) black wiring (live) to ground, or ii) black (live) to white (neutral). Traditional industry may only consider arcing between the black and the ground. But if arcing is happening between the black and the white, the differential current will be zero because the same current going through the black comes back through the white. The industry may not be capturing parallel arcs taking place from black to white because it will not have a differential current. Rather than having a differential current, it will have a signature in the current. There will be irregularities in the current. But if you measure only RMS values, this will not be detected. Without examining the wave form of the current, this parallel arc between the black and the white won't be detected. Similarly, a certification body measuring the difference in the current between black to the white, will not see any differential current. However, a differential current will be detected only if the arc is between the black and the ground which is a parallel arc, in which case there will be a leakage (differential) current between the black and the white because the current leakage is to the ground.

Series arcs can occur as well. Example embodiments include electrical devices, including receptacles and circuit breakers, for detecting a series arc fault and providing circuit interruption in response.

Series arc fault occurs when the arc occurs within the black or within the white wires; e.g. it is in series to the load. The traditional industry cannot determine by examining magnetic fields using traditional electro-mechanical means that there is a series arc, as there is no leakage current in a series arc. If an arc takes place in the black wire going into a load, the load will draw appropriate current and there won't be any differential between the black and the white. Similarly for a series arc within the white. Example embodiments can detect these by analyzing the waveforms on the applicable power line.

Traditional arc fault interrupters are really detecting leakage current, and they create the leakage current by melting the insulation waiting for a different fault condition to occur before tripping. Whether at the breaker level (e.g. breaker feeder, Combo) or at the AFCI receptacle level (e.g. outlet circuit AFCI, Portable AFCI, Cord AFCI and Leakage Current Detection and Interruption (LCDi)), the industry is doing an inadequate job as they are not properly measuring and detecting arc faults in series. Primarily this is because they are measuring current when an arc jumps across a single wire (“series”). As the current has not leaked to the ground, they don't detect the occurrence of a series arc. Detecting series arcs on the basis of insulation first being melted can be dangerous as it could start a fire in a hazardous environment.

If there is a leakage the present industry technologies will detect the arc; but if there is no leakage, they will not. As leakage is always between the black and the ground, you can measure the difference between the black and the white and this difference between them will be the “leakage” that flows to the ground. Leakage can happen through a short circuit as well as parallel arcing. Leakage is not relevant for series arcs as series arcs occur as a break within the same wire or at a loose connection. Overload current is not leakage current, as there is no leakage where there is no current imbalance.

Example embodiments of the electrical device do not require there to be leakage for detection of the series arc fault. In contrast, in traditional industry devices leakage is the only way existing AFCI breakers and receptacles detect a parallel arc fault (leakage is not relevant for detection of series arcs in example embodiments).

To detect series arcs and/or parallel arcs between line and neutral, AFCI breakers and receptacles, may rely on the breakdown of the insulation creating a leakage or surge. The arc on the black wire causes the insulation to melt exposing its metal. Then it melts the neutral wire next to it. When the current flows between black and white, there is no limit for it until the AFCI breaker, or MCB trips because of overload. It becomes a parallel arc, but there is no current differential. It will not be tripped by traditional receptacle(s).

Parallel arc between black and neutral is not detected by industry devices. In traditional industry devices, the AFCI devices can detect the parallel arc between live and ground, which is in effect a ground fault, e.g., 70 milliamp if no load, 5 milliamp if load. Traditional industry device detect a leakage current which is the same as AFCI, and trip in response.

For live and neutral, when there is arcing, the current just keeps on building as there is no limit as to how much the current can keep building up. At some point, there is effectively creating a short between live and neutral (fire could have started). The traditional industry devices may detect this extra surge of current that goes beyond the 15 Amp limit (“overload”) and hence the traditional AFCI will trip. The traditional AFCI does not know why it is being tripped (namely merely because current is going beyond 15 amp limit). Really, the traditional AFCI is sensing the short circuit, also evidenced by the metal guillotine test where the metal creates a short between the line and neutral—which gets captured as the flow exceeding 15 amps. AFCI devices are tripping due to over-current for the black-neutral, rather than directly detecting a parallel arc. The certification testing is really checking the shorting.

The danger is that if there are conditions of arcing between live and neutral whereby the current does not reach 15 amps (to cause tripping), then the arcing will continue and won't be detected by the present devices on the market. Traditional industry does not trip based on one wire having an arc, rather they wait for the arcing to cause enough damage to melt the insulation on both wires so that the arcing can properly form between the live and the neutral causing a short—then they trip it.

Traditional industry MCB's (Micro Circuit Breakers) trip for over current. When there is a short, current builds up and when it exceeds 15 Amps, the breaker trips. MCB's protect against shorts, but they don't catch leakage. Arcing can cause extensive damage without exceeding the current rating of a breaker. A less than 15 amp arc between live and neutral can cause a fire. Depending on detecting the melting of wiring and/or enclosures, is not a reliable means for fault tripping. Traditional industry MCB's will not trip if there is arcing (between live and neutral) without an extra surge of current over 15 Amps or overload. The actual current rating of the MCB may not be exceeded.

Traditional arc fault breakers and receptacles would not necessarily have been an improvement over the MCB's. In traditional industry devices, series arcs are not detected as there is no current imbalance, differential on the single black or white wire. In traditional industry devices, parallel arc faults between black and white trip by detecting overcurrent—which may not take place as there may not always be arcs that are so high that they will exceed the current limit. Parallel arcs between black and white are not being detected by traditional industry arc fault breakers because there is no leakage there during this type of arc and as there is no overcurrent. The only way they could “detect” it, is if the current exceeding 15 amps is being caused by arcing. What all this shows is that it may not always be true that a parallel arc will result in the tripping of traditional breaker (MCB or AFCI) due to overcurrent.

Further, traditional industry GFCI devices would not have detected these faults either. Traditional GFCI and AFCI rely on detecting known current differentials (e.g. imbalances), but they do not quantify it as there is no actual measurement (the whole thing is analog, so there is no digital conversion of the voltage or current). Although existing AFCI devices detect leakage, they are inadequate in detecting parallel arcs occurring between the black and the white where there won't be current imbalance. As an example, a light bulb plugged into a receptacle may not be arcing—it is drawing a constant current which is coming in through the black phase wire, going through a receptacle, going to the bulb and returning via the white wire (neutral). If a series arc occurs in the black or white wire, the current isn't leaking to ground and it is not shorting.

Although series arcs can occur anywhere, in the black or white wire it usually occurs at the terminals due to a loose contact. In this instance of arcing due to loose connections, voltage changes, causing the current to get modulated, which would not be exhibited/result as a difference between the white and the black currents (e.g. no differential change) and therefore arcing would not be detected by traditional industry devices—which, had there been a current imbalance, such arcing could otherwise have been detected by the traditional comparative means and methods used to detect arcs.

Situations may arise whereby a wire from a breaker panel to a receptacle, or via a junction box, has a splice in the wire somewhere along the line, or the screw on the breaker (or on a receptacle as wires are being connected on the back side) hasn't been tightened down adequately in which case that contact is not making a good contact. Accordingly, if the contact isn't making a good contact, in the case of a nominal load like a light bulb, there may not be significant current drawn and the traditional arc fault means of examining current will not detect the arc fault. With example embodiments of the electrical device, there will be less chance of a loose contact due to mechanical structures.

Traditional industry AFCI's look at the differences between black and white, not at RMS variation. For example, for a hair dryer, there is a variable speed motor, the current will vary and there is no arc indicated. If the industry looks at absolute RMS values, they won't be able to do much. The load will be varying load so they will trip falsely.

Example embodiments of the electrical device have arc fault detection. Using voltage change as the indicator the electrical device both detect arc faults and do so earlier than the traditional devices. Traditional industry devices depend on current as the marker for tripping, and will trip as they really depend on secondary events such as grounds, shorts which can be too late.

Regarding traditional industry AFCI breakers, if current changes, the current changes equally on both black and white and not one versus the other. Even in case of a parallel arc fault on the black and the white, the AFCI will not trip because there is no differential or imbalance.

Traditional industry looked at GFI type imbalances. The traditional GFI may perceive that there is balance current going into and out of it. This is because the current differential that it is measuring are both staying the same. There's not a difference between the white and the black.

The traditional industry only looks at current for series arc faults, and believes that there are always two arc fault voltage spikes within each cycle, representing the fault.

In example embodiments of the electrical device, when the series arc fault occurs, it is not the waveform that particularly has an arc and the spike, but rather the whole waveform gets squished. The value of the voltage itself goes down, and there is no spike. There is no change in the signature in FFT. This is evidenced in FIGS. 14-1A to 18-1C which show that when the arc occurs there is not much variation in FFT. This means that there are no spikes in the voltage. As evidenced in FIGS. 14-1A to 18-1C, the whole RMS of the voltage value goes down and lasts for seconds. The whole waveform shrinks and there is no spike in it.

As shown in FIGS. 14-1A to 18-1C (actual arcing and corresponding signatures) that when the arcing happens, the arcing lasts for seconds or tens of seconds, and the voltage signature that you see there, you don't see the Batman ears and those kinds of spikes, because if there were any spikes in the voltage, they would have shown on the FFT. Nothing appears on the FFT because what is happening is that the whole RMS value is going down (from 4,000 it goes to 1,600 counts) which means that the RMS value goes down without causing the Batman ears. This means that if a device is only doing FFT analysis, it won't catch the series arc. The device needs to look at the erratic voltage changing over time.

Traditional industry shows voltage changing over every cycle (“Batman ears”)—which does not work.

For traditional industry devices, when a series fault occurs, the device does not detect the series fault. Rather they wait for the series fault to melt the insulation thereby creating the parallel fault, leakage fault, or short circuit and then they detect the leakage fault and they trip it. They also won't detect an arc on a 2-conductor wire (white and black) as there is no leakage. In that case, the device will wait for the overload because if it is pure shorting, they are hoping that it will be sufficiently bad to indirectly cause tripping.

Example embodiments include arc fault test and measurement equipment. The API enables the device to observe what is happening with both current and voltage, and voltage varies significantly and erratically with series fault when there is a series arc.

Example embodiments include equipment for testing arc faults in series, by measuring voltage and taking action (creating circuit interruption) when there is a significant and erratic voltage change resulting from the series fault, and wherein the voltage change occurs over a number of the waveform cycles. The arc fault test and measurement equipment incorporates real time measurement of voltage over a number of cycles. In some examples, the processor may determine from the detected voltage signals that the series arc fault has occurred by determining that the mean square or the root mean square deviation has occurred for more than or less than a threshold number of cycles of the detected voltage signals within a certain time window.

Example embodiments are directed to an apparatus, system and method for monitoring, collecting and processing current and voltage information in real time in order to provide superior detection, identification, differentiation and response to series arc faults, as well as controlling the delivery of power. Advanced devices and processes enabling control of current and voltage, as well as enabling both user or computer-controlled variation of current and/or voltage limits as markers of fault limits (including but not limited to overcurrent/overload parameters) upon which to trip, or determine alternative power activity, is described.

The circuitry and/or processes can be embodied in branch feeder breakers (“breakers”) and receptacles including but not limited to: outlet circuits (with or without loads); in-wall receptacles or external receptacle devices (including but not limited to wall adaptors; extension cords, corded devices, portable receptacles, corded or hardwired devices, junction boxes, Corded AFCI devices and devices offering Leakage Current Detection and Interruption (LCDI) Protection (e.g. a device provided in a power supply cord or cord set that senses leakage current flowing between or from the cord conductors and interrupts the circuit at a predetermined level of leakage current), companion products for breaker panels and more).

Example embodiments include devices and processes for identifying and accordingly reducing false tripping.

An example embodiment is a monitoring, display and controlling device and process, which can be integrated in the devices described above, under the direction of a software API incorporating a communications interface.

Example embodiments relate to a circuit board that incorporates a computer processor with on board current and voltage sensing, which measures, monitors and controls current and voltage in real time on an individual receptacle outlet, plug load basis.

Example embodiments include comprehensive real time current and voltage sensing and power delivery system which uses a computer processor to recognize valid fault conditions was developed for individual loads, eliminating the weaknesses of current electrical fault detection technology, and providing superior measurement, detection & control of over current, both over & under voltage, surges, ground faults, and arc faults.

Example embodiments include devices and methods for detection of series arc faults by identifying erratic voltage drop (signature analysis) and optional performing frequency analysis such as FFT, in either or both the voltage and current domains.

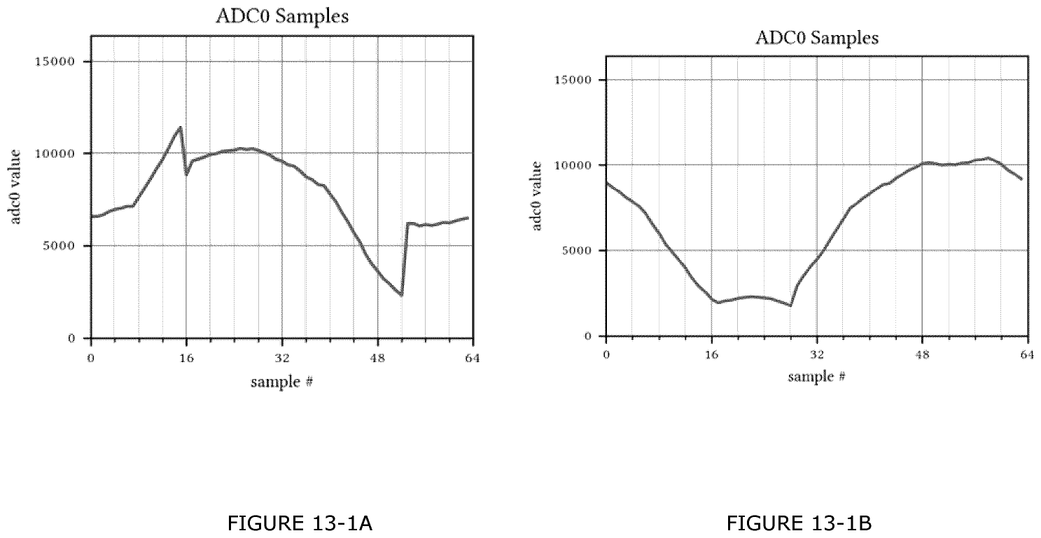

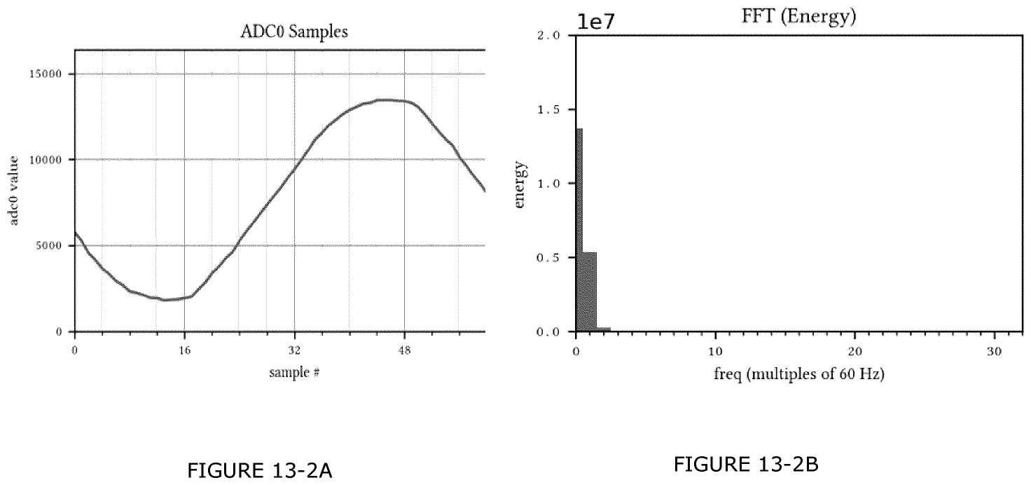

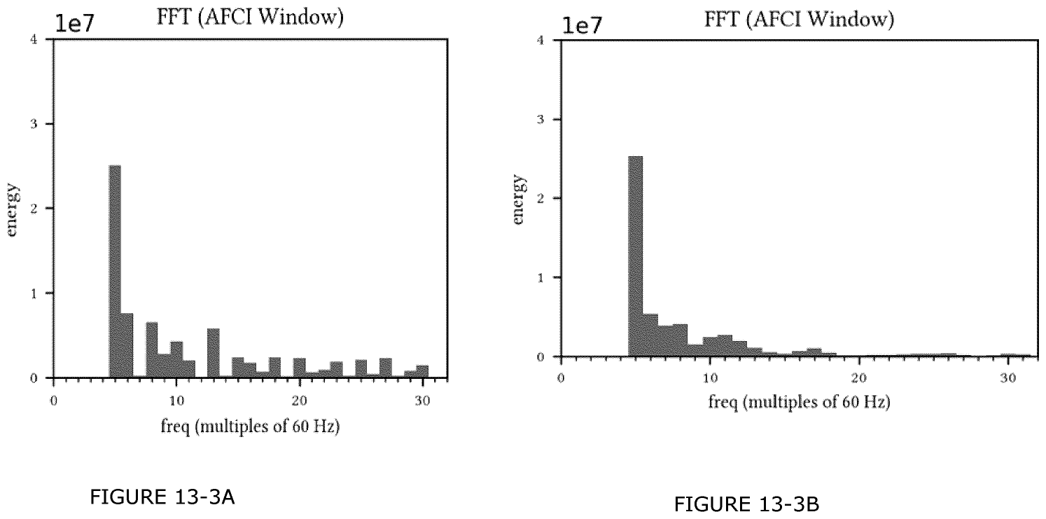

FIGS. 13-1A and 13-1B represent one cycle of sinusoidal waveforms (or sine wave) of voltage in an AC Circuit, illustrating a parallel arc fault. 60 such cycles occur in one second (60 Hz). A similar sine wave or sinusoidal mathematical curve may describe current.

FIGS. 13-2A and 13-2B illustrate FFT values of a normal (non-fault) power line signal, for example 60 Hz. The FFT value of voltage which does not change much.

FIGS. 13-3A and 13-3B illustrate FFT charts showing different frequencies: 60 Hz, 120 Hz, 180 Hz and so on up to 1,920 Hz (based on an example of taking 64 samples per cycle). FFT is within one individual cycle and when a parallel arc related spike occurs, its voltage and current FFT will show a huge line/bar. The first one will be very strong as the first one represents the fundamental frequency component of 60 Hz. The other two to the right are artifacts of the windowing function (they are not really present there). They are 120 Hz and 180 Hz.

These “side lobes” are an artifact of doing the FFT. Anything higher has been removed, e.g., using the hamming window whereby the artifact does not show up at higher frequency than 180 Hz or 240 Hz. We have selected these parameters for the purposes of this illustration, so that anything over 240 Hz has to be related to arcing. And that's why we eliminate the first 4 or 5 frequency components in terms of the fundamental frequency; the first 5 bars we ignore, and we take everything from there onwards, to the end of the graph (higher frequencies over the fundamental frequency of 60 Hz).

FIGS. 14-1A, 15-1A, 16-1A, 17-1A, and 18-1A are photographs of the progression of a series arc. When the voltage dropped, it did not drop for only part of the cycle, rather for 1 or 1.5 seconds, meaning that the whole voltage line went down. The progression of the arc continued for tens of seconds.

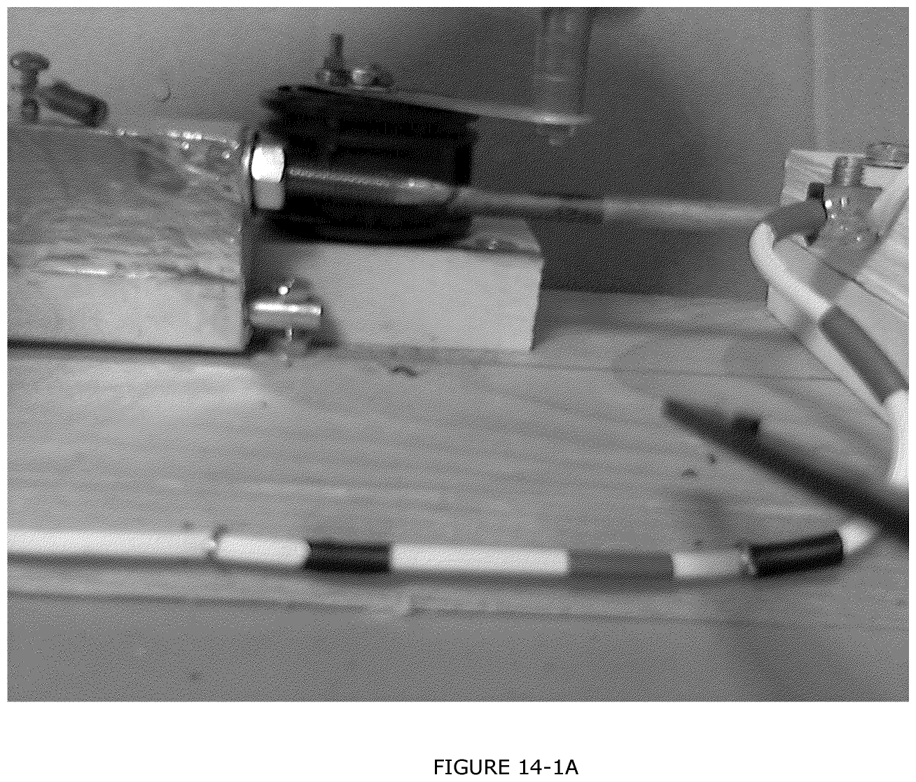

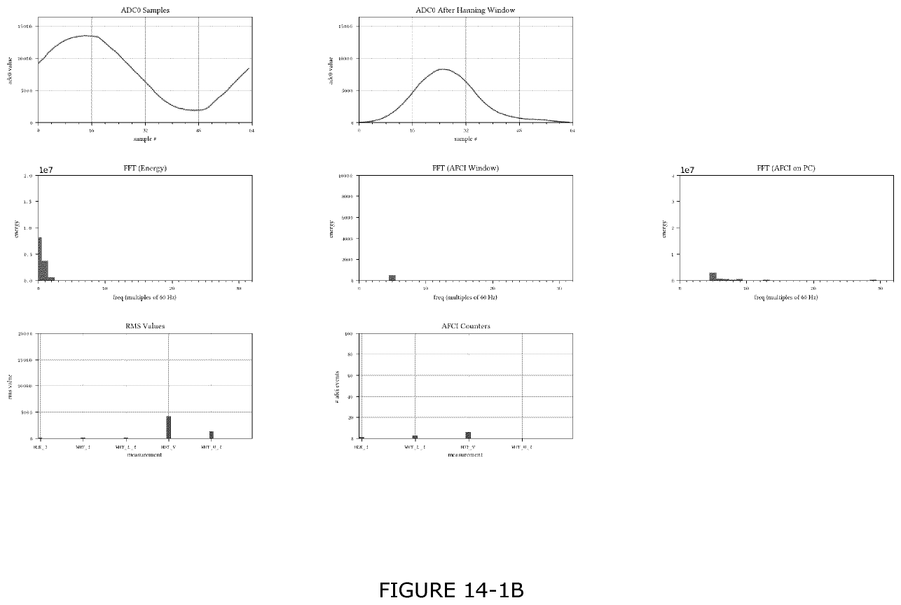

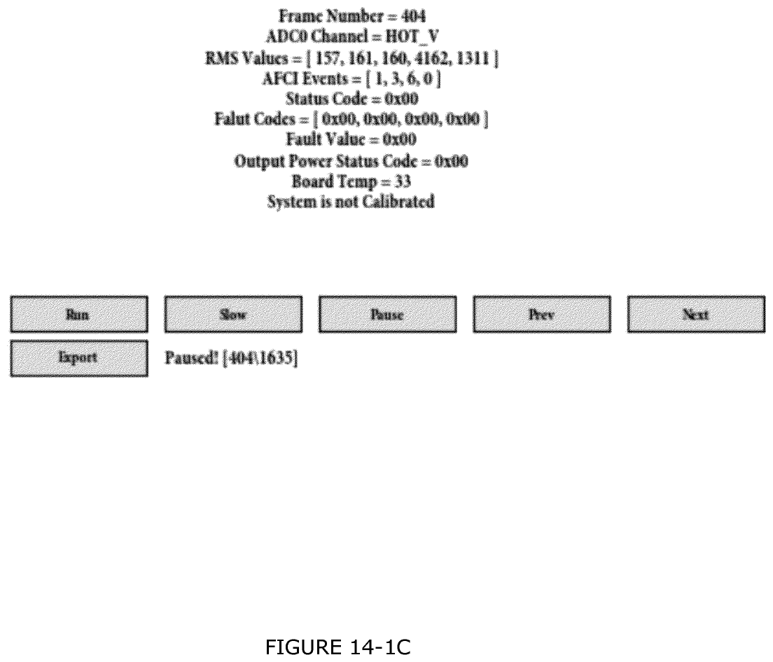

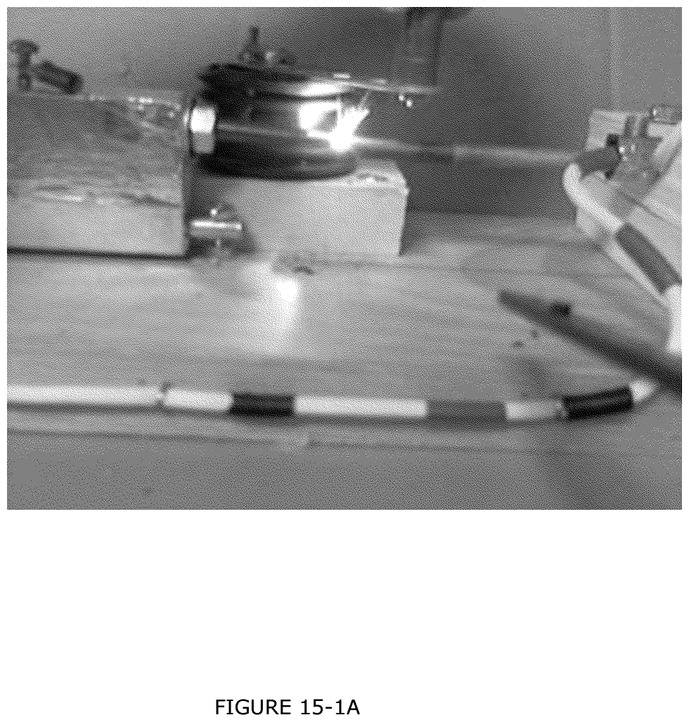

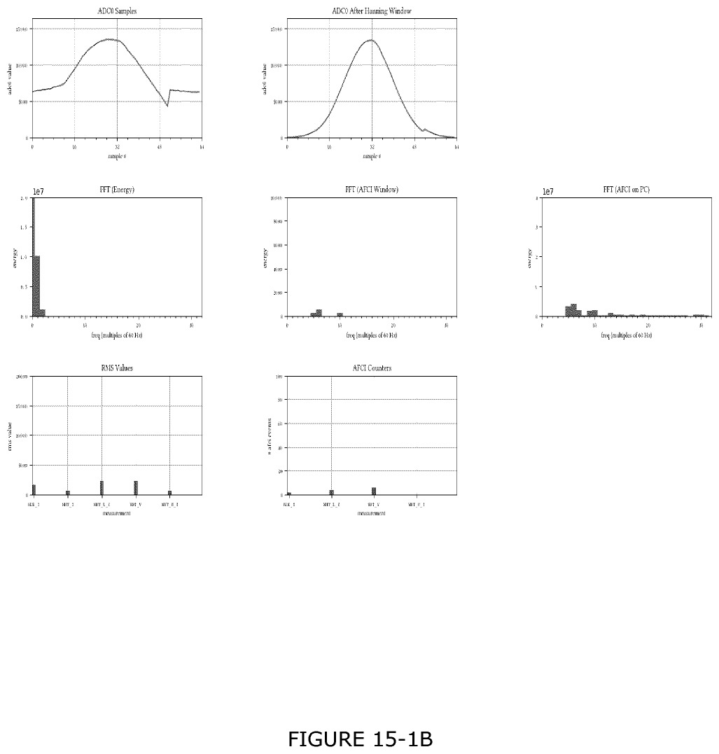

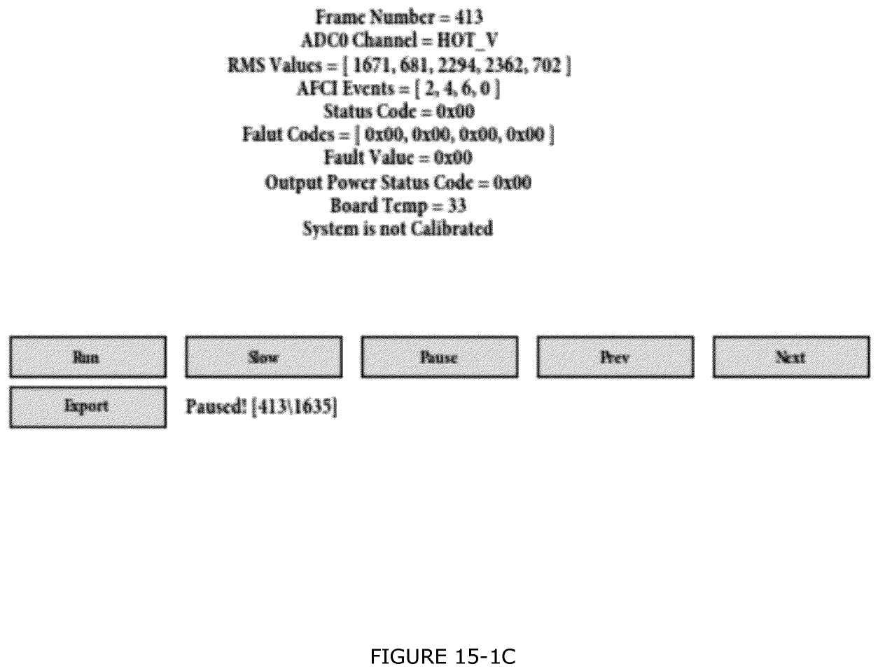

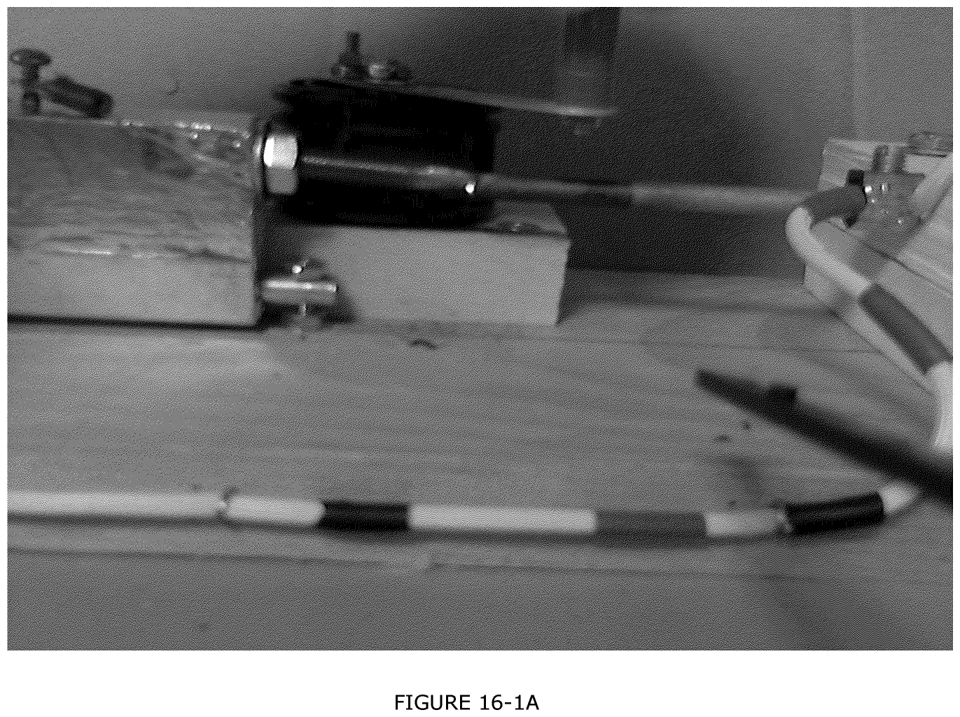

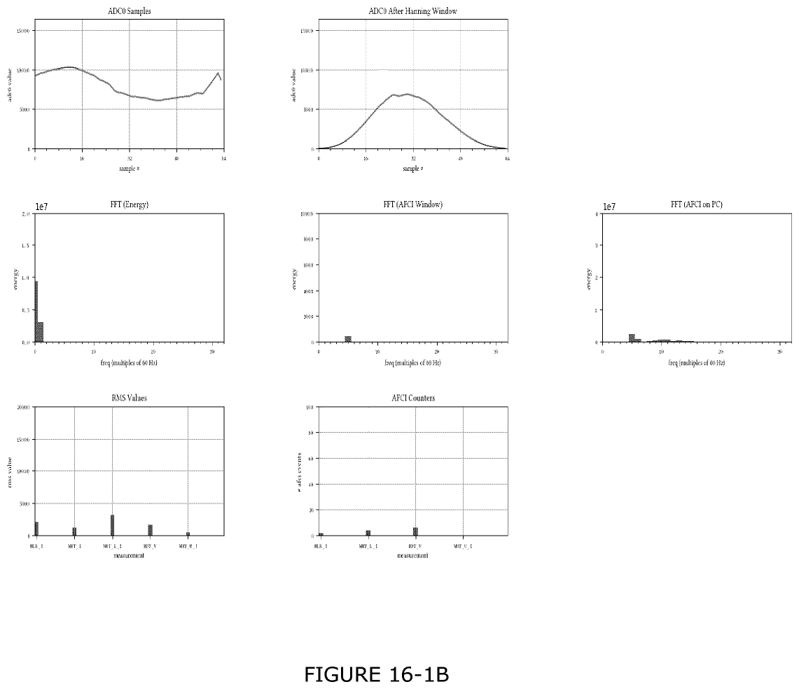

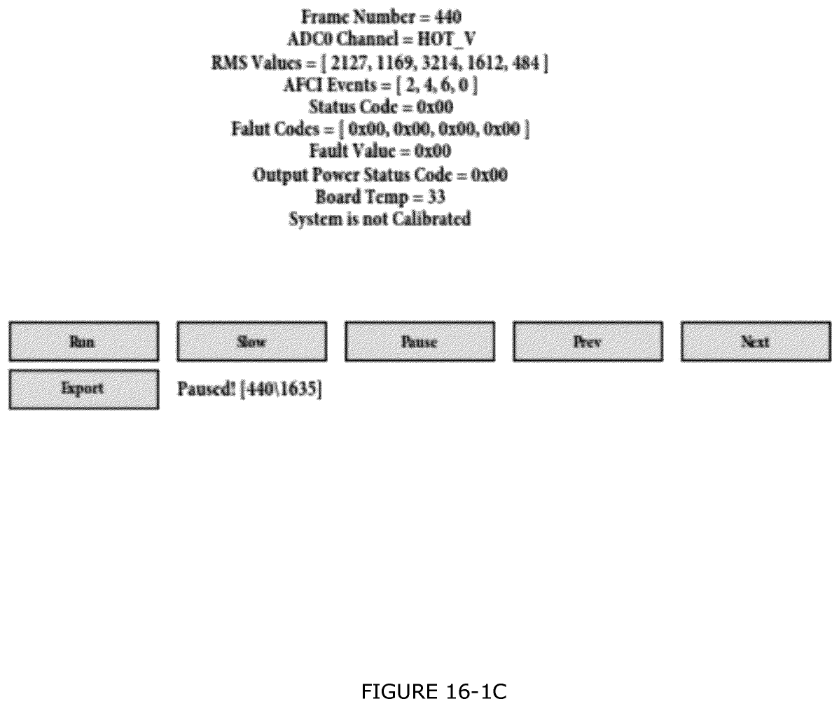

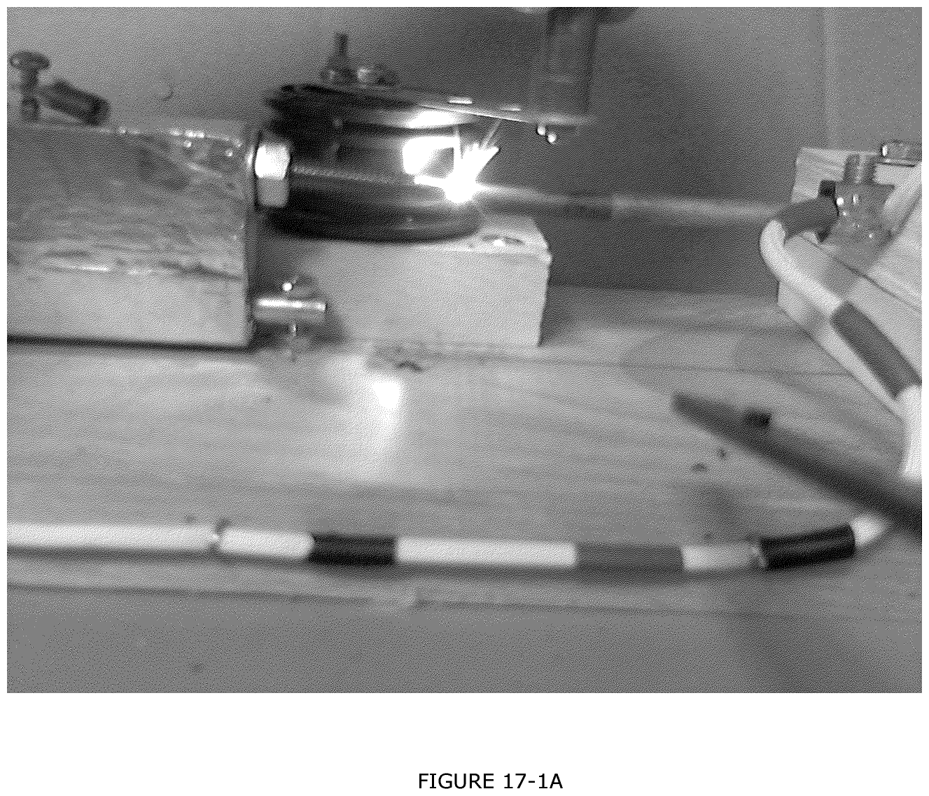

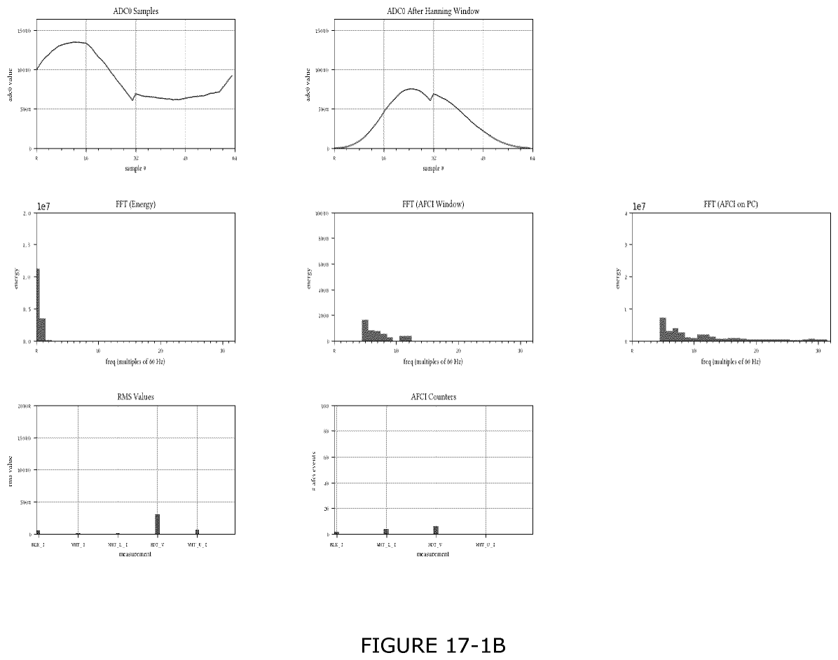

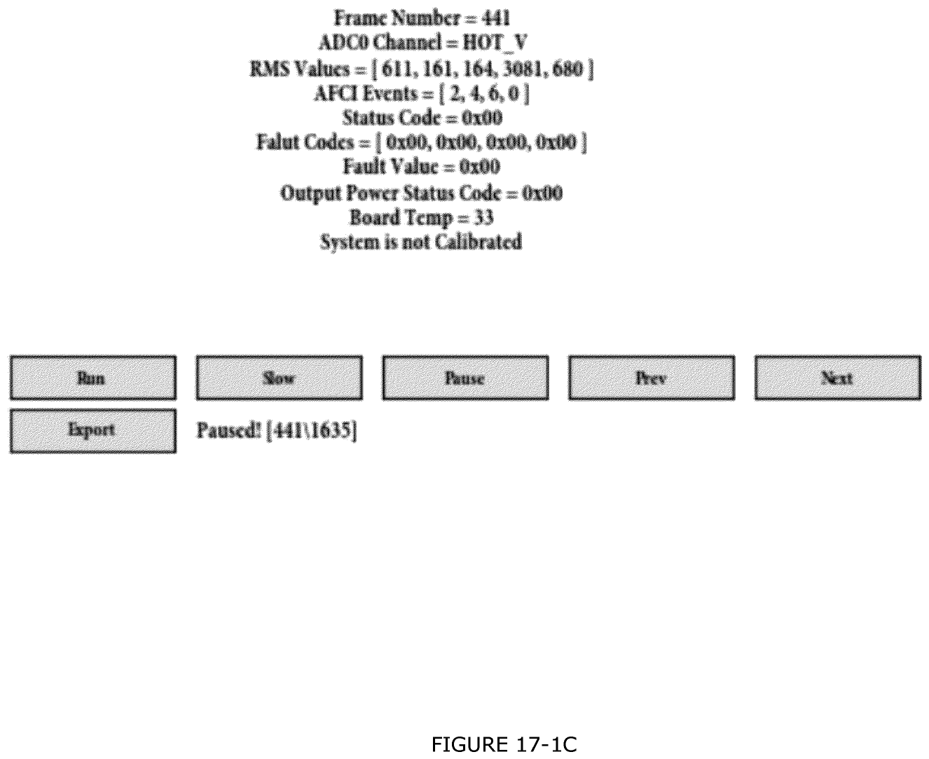

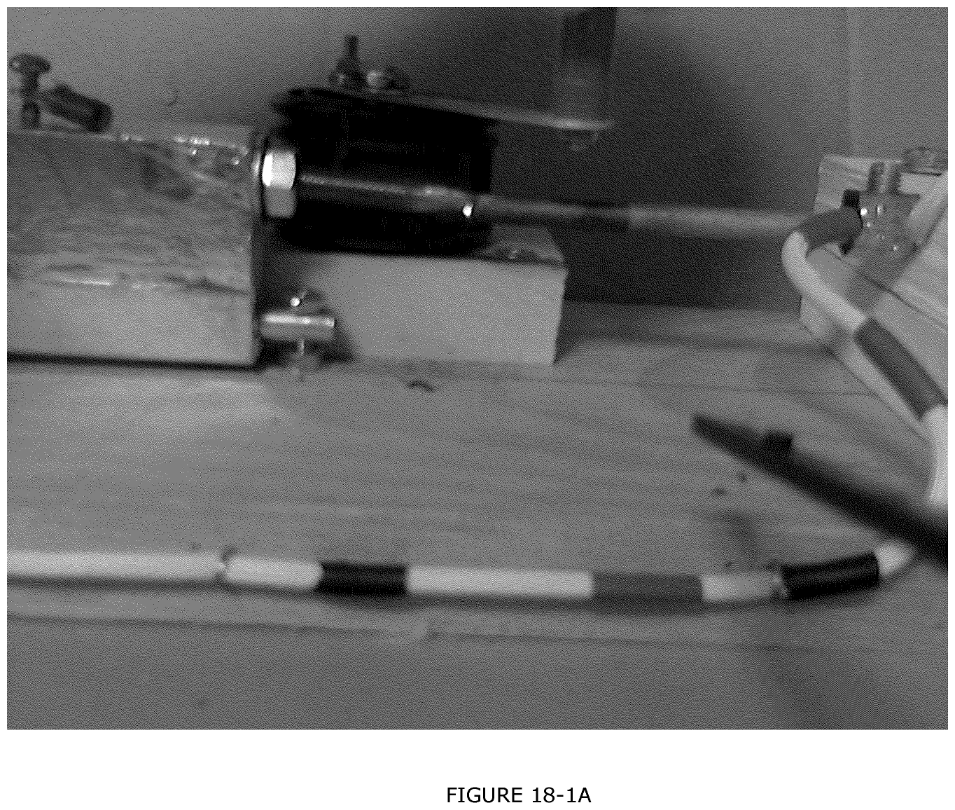

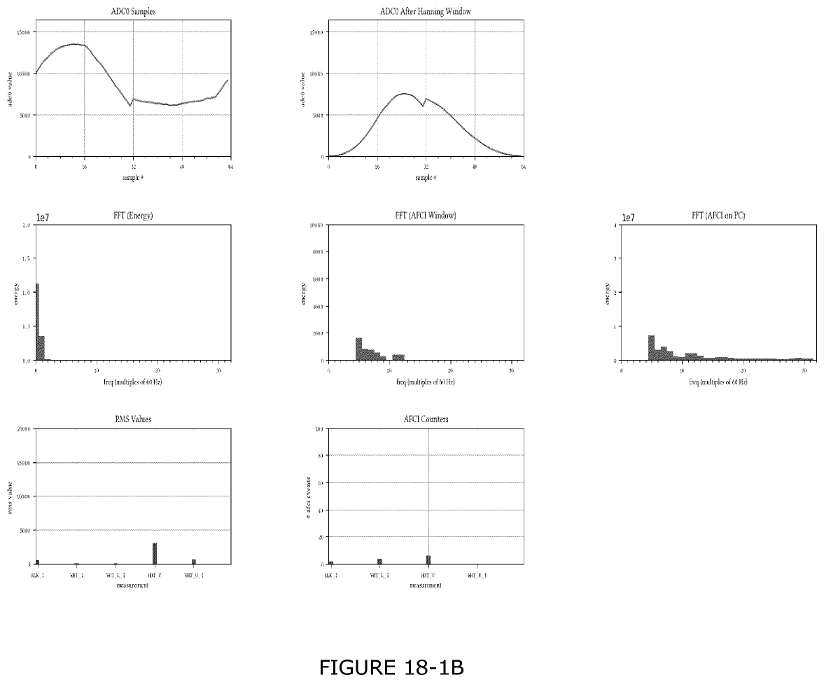

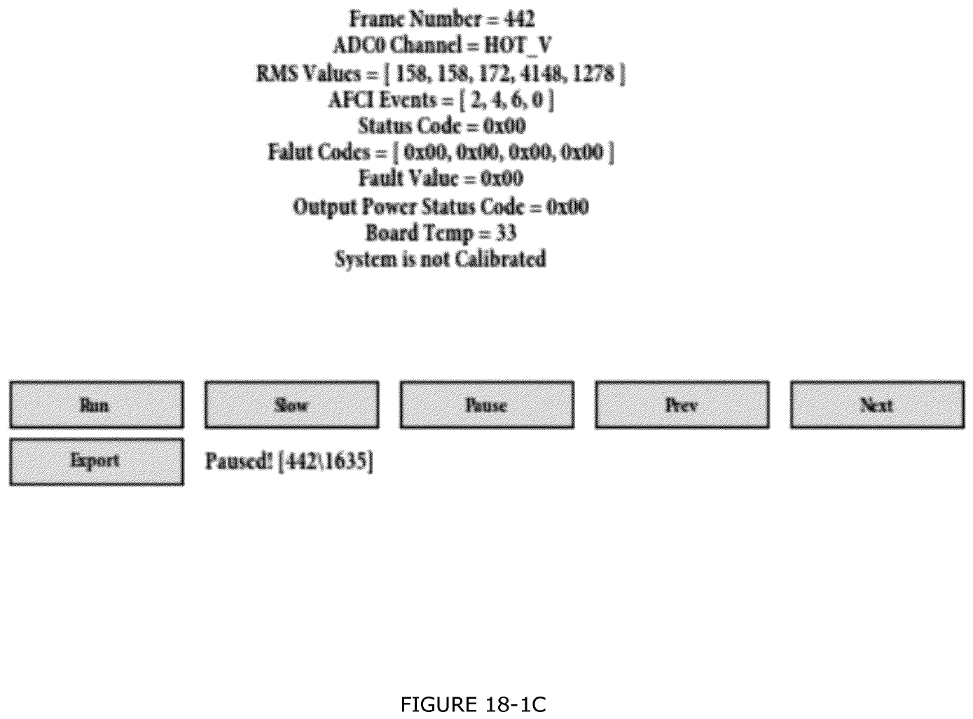

FIG. 14-1A is a photograph of an Arc has not started yet. Everything is normal, where the contact is made. FIG. 15-1A is a photograph of an arc starting to appear. FIGS. 16-1A is a photograph of the arc in full motion. FIG. 17-1A is a photograph of the arc diminishing with glowing contacts. FIG. 18-1A is a photograph of the arc finished, the conductors are back to normal.

FIGS. 14-1B, 15-1B, 16-1B, 17-1B and 18-1B are sinusoidal waveforms of RMS voltage values sampled, FFT bar graphs, and fault related counters. FIG. 14-1B shows that at first, the voltage is in its full AC wave form. The corresponding Voltage RMS value is 4,162. FIG. 15-1B shows that as the arc starts to appear, the AC waveform starts to break, indicating a voltage drop from an RMS value of 4,162 to 2,362. There is not much activity in the FFT window/chart. FIG. 16-1B shows that when the arc is in full bloom, the whole waveform is smaller, indicating a further voltage drop from 2,362 to 1,612. Nothing appears in the FFT domain as there is no frequency change. FIG. 17-1B shows that at the ending stage of the arc, the waveform increases back from its previous low of 1,612 back up to 3,061. There is little activity in the FFT domain. FIG. 18-1B shows that when there is no more arc, the waveform has returned to normal with a corresponding voltage RMS value of 4,148. There is no activity in the FFT domain.

FIGS. 14-1C, 15-1C, 16-1C, 17-1C, 18-1C are data values received for various functions, results from processing of data and mode and channel controls.

Example embodiments of the electrical device can calculate both RMS and FFT for both voltage and current.

Example embodiments of the electrical device can calculate Fourier Transforms, for example FFT. Normally any equipment or load is connected to line voltage, e.g., hair dryer, washing machine. If voltage drops a little bit, in order to maintain speed of motor, the current goes up because it needs more energy (current) to operate. In the case of arcing, the current is not steady. As the air creates resistance, the current is jumping across the air gap, the draw is low.

The FFT of voltage signals does not show a significant change for series arc. Therefore, detecting series arcing only based on FFT of voltage signals is not feasible under series arc. If current drawn is very high, it is not true that it will be sufficient to detect a series arc. The FFT will show some effect, but it isn't enough to distinguish from normal conditions.

Voltage drops for a series arc, because of the air gap is in series with the load. Voltage is shared between the load and the air gap. For a series arc, FFT will vary, but not significantly enough to be detected. FFT showing erratic behaviour definitely is an indication of an arc, which must be a parallel arc. If voltage drops erratically across cycles, then it must be due to an arc fault. If doesn't show up significantly in the FFT domain, it is a series arc.

In a series arc, RMS voltage value changes erratically. So sometimes the voltage goes down to 90 v, 70 v, then come back to 110 v, then go down depending on how strong the arc is. If not stable at 110 v for one cycle, then it counts as an arc (e.g., FIG. 14-1B, 1 count on the AFCI Counters graph, see row 3 column 2, “HOT V”).

In a period of ½ second to 1 second, if the RMS value of the voltage changes, going down, up, down, up, then the electrical device of example embodiments knows the voltage is changing “erratically” and a result of a series arc.

Usually, each height of the bar is the amplitude or calculation of that particular frequency; e.g. 60 Hz or 120 Hz or 180 Hz. So each bar represents the amplitude corresponding to that wave that is contributing to that actual waveform.

There are no frequency indicators under the series arc. The frequency components don't change. There are not any variations in the frequency analysis of voltage under those conditions.

The voltage being “erratic” means deviation from the RMS from one cycle to another. For example, 110 volt varies without any discernible pattern, rather than it goes slowly down, then slowly up. There is no pattern. 110 v to 70 v, then to 90 v, then to 65 v, then back to 110 v. Because of the arc, there is no pattern to the variation.

In series arc, the air resistance in between the break is very high (resistance is high) so the voltage drops. As the resistance is not constant, the voltage drop varies when the arcing is happening. And that's when we see the voltage changing erratically because of the high resistance nature of the gap. The voltage doesn't change, it remains stable. The voltage develops some kinds of spikes depending on how the arcing is happening. Those spikes are typically captured in the frequency domain because the spike implies that there are more sine waves present of higher frequency. In academia they call this typical arcing, the spikes are present in the waveforms of voltage and current.

On the other hand, for a parallel arc, it is not expected that the voltage will go down and change erratically. For a parallel arc, the electrical device will see spikes and capture those in the FFT.

If the electrical device sees voltage drop without FFT, then it is evidence of a series arc.

If the electrical device does not see voltage drop and sees FFT activity, then there are spikes in the voltage; and if these happen for long (e.g. over 5 cycles) it's a real arc fault, but if less than 5 cycles then it probably is not a harmful arc and it is a safe situation; accordingly, the electrical device will not trip.

Voltage dropping and frequency showing anomalous FFT behavior (response) is indication of an arc. Example embodiments of the electrical device can distinguish between a parallel arc versus a series arc.

When there is normal current flowing, the electrical device of example embodiments detects the voltage sine waves responding to the AC current. When see more than one frequency present with significant contribution, the electrical device of example embodiments detects that the waveform is not regular (e.g. is irregular) and therefore harmonics are present which is abnormal by itself, and it is most likely the result of arcing.

Whenever there is an erratic voltage drop across cycles, it is a series arc. When such voltage behavior is taking place and the FFT response is observed, it is most likely a parallel arc.

For parallel arcs, voltage is connected to the load using the same conductors. So a parallel arc will not be associated with a drop in voltage assuming the supply is “stiff” (the power coming in from the utility company is staying steady) which it usually is. There is a parallel load forming which is same as air gap. Depending on the stiffness, the voltage most likely will not drop across different cycles. The FFT might show irregularities in the voltage domain. When the voltage regardless of dropping or not, shows an anomalous FFT response indicative of a parallel arc. In the case of a parallel arc, the FFT will be much stronger because there is no limiting factor. It is just creating a short between black and white, or black and ground. For parallel arcs between black and white, the voltage will be the same, but the current will vary erratically, and the FFT of the current will also show some variations; e.g. change, erratic variation.

For series arc, the FFT will not show a significant deviation simply because the amount of current that is involved in the arc will be low, whereas in the case of parallel arc, there is no limit as to the amount of current it can take.

A parallel arc can occur from Black to Ground. An arc from Black to Ground is called leakage (black current goes to ground but not sufficient to trip traditional industry MCB (unless overload). Shorting means that the black is physically connected to the ground. Current will build up significantly and cause the breaker to trip because of the overload. When there is a short connecting the black to white, the traditional industry MCB will trip because of the overload. Shorting can also occur connecting black to ground, but the current does not return through neutral. A short because an overcurrent at the breaker; leakage may or may not, depending on strength; for example leakage of 6 or 7 milliamps will not show as an overload.

In a parallel arc, the Batman—ear type spikes in the voltage domain may or may not show. Will show up in the current domain as there will be high frequency components.

Regarding parallel arcs, when the frequency domain shows variation, this is a known phenomenon. But not for a black to neutral parallel arc, as they won't see a current differential and therefore won't detect the arc. So the invention is overcoming that they cannot detect black to neutral parallel arcs; e.g. by using FFT (which existing art does not do at all because they don't measure actual values), we can detect parallel arcs between black and neutral.

The differential is the difference between the current and it is measured in RMS rather than the waveforms or amplitude and frequency. The spikes are indicated through FFT and therefore we would expect the RMS to stay the same as there is no change in the current between them.

In case of parallel arc, the arc between black and neutral won't exhibit a differential, but the waveform will in fact show the spikes. And this case in not caught by the industry because they look only at the differential. However, the academic world describes this arcing as the spikes in the voltage waveforms. Nobody is using that description, but they are looking at the differential current in their products.

For real devices or loads that will be connected to the electrical receptacle (e.g. hair dryer, brush motors where there's arcing, etc.), these kinds of spikes are going to be present for almost every kind of load that is connected. The solution is to identify different types of arcs to establish the harmless variation in the spike.

Therefore, there is a need to define the actual nature of the arc, understanding which spikes are relevant and which do represent actual arcs and which do not.

Based on looking at the spikes and then corresponding variations in the RMS values of the voltage and of the current, the electrical device can determine are and are not an arc, as well as the type of arc. The combination of the spikes and variation in RMS value indicates that it is a harmful arc.

In example embodiments, the electrical device includes the processor, and frequency calculations (e.g. FFT, wavelets), and determining random variations in the RMS value of the voltage by statistical means (the latter combination, indicating to us that it is a harmful arc, as opposed to the normal starting and harmless arcs that happen to the operation of the equipment).

The electrical waveforms, spikes, and variations may be observed. These may be used to draw a reliable conclusion regarding the presence of an arc. Upon drawing a conclusion, the electrical device then causes a “trip”, energizing or de-energizing based on what has been explained herein. Example embodiments use a microprocessor to control hardware to energize and de-energize based on the decision process flow.

Series arcs will occur when a conductor is broken. A partially broken wire simply means that resistance will be increased and the temperature will rise; but depending on how much heat there is, and current flowing, the whole thing will just get hot or get complete meltdown. In the case of an LED bulb, there won't be much current draw, so the wire won't necessarily get that hot and break. A series arc can occur when a conductor has broken, e.g., either screw terminal at breaker is loose, or connection gets corroded; e.g. anytime there is a poor connection, or another connection is not proper, or wire breaks.

FIGS. 13-1A and 13-1B represent a single cycle of sinusoidal waveforms (or sine wave) of voltage in an AC Circuit, showing instantaneous voltage over time (“Vt”). 60 such cycles occur in one second (60 Hz). A similar sine wave or sinusoidal mathematical curve may represent current. RMS provides the average of the voltage (or current as the case may be) variation for each cycle.

Current and voltage spikes are shown, represented. In the cycle as what the industry often refers to during arcing as having the appearance of “Batman-like” ears. The spike shows as a higher frequency. This has been the characteristic signature of arcing in the voltage and current domains and continuous in each cycle.

Although 5 channels are illustrated as being recorded: voltage, BLK current, WHT current, upper receptacle, and lower receptacle—and additional channels may be added, such as a sixth channel for recording GFCI leakage signal(s).

In one embodiment, 64 data points are sampled per channel, within each cycle, across the 60 cycles during each second. Voltage varied continuously within each cycle. From the instantaneous voltage values that varied during 1/60th of a second, one RMS voltage value is generated per cycle.

FIGS. 13-2A and 13-2B illustrate FFT values of a normal (non-fault) power line signal, for example 60 Hz. The FFT value of voltage which does not change.

FIGS. 13-3A and 13-3B illustrate FFT values for different frequencies of voltage; e.g. 60 Hz, 120 Hz, 180 Hz, and so on, up to 1920 Hz based on having 64 samples. FFT will show only if there is an inconsistency within a waveform. FFT may could also be illustrated for different frequencies of current.

In example embodiments, voltage and current fluctuations are captured in the frequency domain, computed and processed during frequency analysis (such as FFT and/or wavelet). A parallel arc is accompanied by a drop in RMS voltage and current. Accompanied by fluctuation in FFT establishes that a parallel arc is taking place.

Traditional AFCI analog based technology depending on detecting current differentials. Traditional AFCI analog can capture parallel arc faults between black (live) and ground, based on leakage. Traditional AFCI analog will not capture parallel arc faults between black (live) and white (neutral) based on detecting current differentials, as although the current may be varying, the current remains the same during a parallel arc occurring between the black and the white wires.

Example embodiments of the electrical device can use at least voltage (and sometimes with current) RMS value drop, and voltage and current fluctuations in the frequency domain, enables detections, affirmation and identification of a parallel arc.

FIGS. 13-3A and 13-3B display FFT. When a parallel arc related spike occurs, its voltage and current FFT will show a huge line as illustrated. However, for series related spikes, in FIG. 14-1B the RMS voltage value drop does not show up in the corresponding FFT.

Applicable to both parallel and series arc faults, the accumulation of a count of the number of fault conditions as illustrated in FIGS. 14-1B, 15-1B, 16-1B, 17-1B and 18-1B enables the determination of whether an arc is normal (as for hair dryers, brush motors, etc.) or should be acted upon to de-energize the power to the load.

For example, the presence of less than 5 instances of an arc within one cycle, would indicate that no action should be taken, power should not be turned off—which otherwise could have resulted in a false trip. Over 5 fault instances within a cycle, might indicate that the frequency of the arc is sufficient to trip, de-energize the load, or circuit.

The triggering fault number can be pre-set, predetermined or controlled by input optionally even in real time using a power monitoring, measurement, control means/process such as the API disclosed herein. Similar to voltage and current instantaneous values, RMS values and frequency analysis, the recording of occurrences of fault counts (spikes) takes place within a second, for 6 channels: voltage, BLK current, WHT current, upper receptacle, lower receptacle, and (soon to be added, GFCI leakage signal).

The number of channels can be less or greater, depending on the desired product and/or process application embodiment.

For series arcs, the photographs show the progression of series arcing in FIGS. 14-1A, 15-1A, 16-1A, 17-1A, and 18-1A with the corresponding Voltage RMS values and associated Frequency Analysis. In this embodiment a frequency analysis using Fast Fourier Transform (FFT) illustrates that for during the particular Series Arc, the RMS Voltage values vary erratically in series fault, dropping from 4,162 to 1,612 as the arc went into full bloom, then back to 3,061 as it diminished, and to 4,148 when the arc was gone (FIG. 18-1A the arc had terminated, and the “broken” carbonized rod (graphite) 2 conductors had been brought back together). (The arc could have stop and the 2 pieces of metal become welded).

However, no activity appeared in the FFT domain. This unique characteristic unpublished in the industry is the basis for the detection, identification and differentiation process and means herein described which affirms that a series arc has occurred. Series arcs are not detected by AFCI technologies which are based on identifying current differentials, and which do not measure actual values of current or voltage, nor have the processing means to establish that arcs have not exhibited their spikes in the frequency domain—whether voltage or current. The progression of the arc continued for tens of seconds.

When the series arc occurs, the actual RMS voltage value drops and the drop continues for several seconds. The drop is not within the waveform but rather the whole waveform itself shrinks. This is very peculiar to series arc. RMS value drop can take place in ½ or 1 second, but can continue for tens of seconds. Undetected, the arc will continue until wire melts.

FIGS. 14-1B, 15-1B, 16-1B, 17-1B AND 18-1B illustrate that for series arcs, RMS voltage value drops occurs across multiple cycles, e.g. over a period of time; e.g. the AC waveform itself is dropping. The whole RMS value goes down, and it takes place over ½ second to one second—but continues over multiple seconds, across multiple waveforms. Even though the voltage drop is accompanied by a small distortion in the frequency domain, it is not sufficient to be captured by the frequency analysis alone.

The AFCI Signature comprises of multiple conditions including: voltage, current, frequency changes (for example FFT detects frequencies present, wavelets detect how these frequencies are changing),

A series arc can occur in ½ to 1 second; e.g. within one cycle. However, the duration of the series arc can be 10, 20 even 30 seconds, with voltage (and sometimes current) (as exhibited in its RMS value) fluctuating erratically in series fault across multiple cycles.

Determining that a series arc has occurred by only measuring voltage or current fluctuation within a single cycle rather than across more than one cycle or multiple cycles will improperly establish that a series arc has occurred, resulting in false tripping. Moreover, attempting to determine that a series arc is taking place, by monitoring and measuring fluctuations of currents in the frequency domain, will fail at detecting series arcs.

Both measuring current differentials and monitoring spikes in the current domain fail to detect series arcs as there won't be current differentials in a cut black or white wire; and significant current fluctuations won't appear in the FFT, or frequency domain.

The specific unique characteristic of a series arc to vary erratically in series fault in its RMS value, across wave forms is sufficient to determine that a series arc is occurring. Accordingly, it is inadequate to establish a series arc fault condition based on fluctuation occurring only within a single 1/60^{th} of a second waveform cycle.

Erratic voltage RMS voltage (or current) RMS values, with no significant presence of FFT values (for either current or voltage) is sufficient to trigger further examination to confirm the presence of a series fault. The continuation of an erratic voltage RMS value drop across more than one cycle is sufficient to indicate the presence of a series arc, upon which to trip the breaker, or de-energize the respective load or circuit (accessed by the receptacle type device).

The electrical device in example embodiments can include an API a “soft oscilloscope” (i.e. soft oscilloscope being a built-in oscilloscope function). FIG. 3B illustrates an integrated display of real time data and processed calculations providing a real time representation as to what is taking place in the processor. Ideal for testing, validation, and monitoring current and voltage activity in real time, and/or recording for future use. An API provides a means of getting the information out of the controller. API is important for diagnosing, analysing and presenting the information.

The process of using an API can be used with a communications interface (including but not limited to a communications port or channel); for example a Uart and an RS485 interface are serial communication ports. I²C (“inter integrated communication”), SPI (“serial peripheral interface”) could also be used.

For example, one may want to create a high level device in the same instrument. One controller could request information from another controller through the API without the presence of a communication port to go out; e.g. to transmit information externally (e.g. outside to the data base).

In another specific example embodiment, a star controller can have a power module built-in to the same unit. The power module would talk to the star module using the UART serial communications port directly. There would be an API used by the star controller to talk directly to the power module through a communications interface (e.g. Uart serial communication port in this case—could be Uart, I²C (“inter integrated communication”), SPI (“serial peripheral interface”). A communication channel may or may not have a port; e.g. physical communications interface. In this embodiment, the API is there with a communication interface, but no communication channel, as such, as it is built into the same unit; e.g. a Uart is not needed when integrated in one device. When communicating externally for example, to a database (or for analysis and/or control) then the communication port is required

Optionally, in some example embodiments, a communications means such as a communication interface (such as but not limited to an RS485 serial communications port) can be incorporated to transmit that information to an external device. Protocol standards such as Modbus can be included.

Oscilloscope readings can be provided by the electrical device in example embodiments. The API is a “low speed” oscilloscope function that is into the electrical device to look at the sampled array but developed from the voltage and current sensors, versus traditional oscilloscopes. Memory buffers are used/incorporated to enable oscilloscope type readings. E.g. the electrical device example embodiments has diagnostic buffers (data is continuously coming in, and data being analyzed, and so the data needs to be retained somewhere so it can be sent out).

The electrical device in example embodiments includes memory buffers to generate the oscilloscope functions-corded product with display.

Because of the diagnostic bus, the data is continuously streaming out after every two cycles. So the electrical device is doing the full RMS measurement and all of the related processing.

The electrical device is still recording all electrical signals measured (e.g. electrically derived signals such as current and voltage including but not limited to safety ground sensed voltage and current data) and sending the information out; RMS values and instantaneous wave forms—they come out slowly after 2 cycles. The frame rate is slightly lower, but we get all the data. This can be considered a “low speed” oscilloscope.

An example embodiment is a built in oscilloscope device; e.g. embedding oscilloscope function in a device itself by examining and displaying sample arrays developed from sensors in circuitry. The product embodiment of a measurement device with a display (FIG. 3B), is effectively an oscilloscope.

In example embodiments, the electrical device is an oscilloscope because an oscilloscope is built in to our devices (receptacle and derivative devices) which can capture, measure, display and present the waveforms in real time. The electrical device is configured to do both time-domain waveforms & RMS. The electrical device provides oscilloscope type information, but based on being integrated in device and based on time domain tracking built into the device.

An example embodiment is an oscilloscope electrical device, including a contact configured for electrical connection to a power line; a sensor for in-series electrical connection to the power line to detect signals indicative of the power line; a processor configured to sample the detected signals in real time, and provide oscilloscope information indicative of the sampled signals.

In an example embodiment, oscilloscope information is indicative of the sampled signals. The signals are detected by an oscilloscopes which may have a probe that measures current. The oscilloscopes may be the clamp type whereby the clamp electrically connects to the wire (parallel) and the clamp measures the current. The oscilloscopes may not provide current measurements in series; and electrical connection to the power line is not in series. In an example, the electrical connection for current measurement is in series in that a sensor may be an integral part of the circuit the voltage and current is flowing through the sensor or right under the sensor, depending on whether a direct connect or induction connection method is used.

In an example of the oscilloscope electrical device, wherein the oscilloscope information includes a waveform of the detected signals, further comprising a display screen for the providing of the waveform in real time. In an example of the oscilloscope electrical device, the processor is configured to analyze the sampled signals in real time. In an example of the oscilloscope electrical device, the analyzing includes calculating a mean square or a root mean square of the sampled signals.

In an example of the oscilloscope electrical device, the analyzing includes performing frequency analysis of the detected voltage signals. In an example, the frequency analysis is a Fourier transform or a Fast Fourier Transform (FFT) of the detected voltage signals.

In an example of the oscilloscope electrical device, the oscilloscope information includes information of the analyzed sampled signals.

In an example of the oscilloscope electrical device, the oscilloscope electrical device further comprises a communication subsystem for the providing of the oscilloscope information by transmitting to another device. In an example of the oscilloscope electrical device, the oscilloscope electrical device further comprises at least one analog-to-digital convertor (ADC) configured to receive a respective analog signal from the at least one sensor and output a respective digital signal for processing by the processor for the providing of the oscilloscope information.

In an example of the oscilloscope electrical device, the processor is configured to execute an application program interface (API). In an example, the API includes commands for instructing what mode of the oscilloscope information is to be provided by the processor.

In an example of the oscilloscope electrical device, the oscilloscope electrical device further comprises a solid state switch for in-series electrical connection with the power line, wherein the API includes control commands for manual or automatic power distribution or safety of the power line by activating or deactivating the solid state switch.

In an example of the oscilloscope electrical device, sixty four samples are sampled from the respective individual cycle of the detected signals.

The electrical device in example embodiments is looking at voltage as well as current, if the voltage varies erratically, but current variation is not much, (because the actual value of the current itself is small; e.g. if drawing a few milliamps, would not see much variation—but the voltage will be varying). The electrical device in example embodiments will trip assuming an arc even if the current is not varying much, but the voltage is erratic. This especially true when the load is light (below a current or power threshold). In one embodiment, the disclosed means and processes of examining voltage determine that if voltage starts being erratic, then an arc is taking place, even without the presence of any significant current variance. If an arc takes place only during one cycle rather than more than one cycle, then this would be an indication of a non-hazardous series arc and tripping of the breaker or the circuit should not take place, as it would otherwise result in a “false” trip.

In example embodiments, as the load draws current, or stay static (nominal load like a light bulb), if the contact is a loose contact which isn't making a good contact, the voltage will start being erratic and effectively be doing an arc, but not with any significant current—so therefore traditional arc fault current testing won't detect it. However, the electrical device in example embodiments will detect the series arc fault because it will detect the squishing of the voltage.

The electrical device in example embodiments not only looks at the instantaneous difference in the black and the white but also look at the waveform of that different as well to see if there are additional conclusions from it. When arcing happens the electrical device in example embodiments can see the FFT signature of the difference.

The electrical device in example embodiments can analyse the variations in the differential(s) across time indicating any reliable detection of the occurrence of an arc.

The electrical device in example embodiments brings in the black to voltage and current sensors; and the white to voltage and current sensors. The electrical device in example embodiments then is doing processing on the data as well as measuring voltages and other parameters from the wires.

Another embodiment for testing GFCI addresses achieving better resolution in the circuitry. To address having the large dynamic range, in order to achieve better sensitivity and improved resolution on the current imbalance to detect Ground Faults, an analog circuit is added to do current processing after the current sensors, prior to providing the information to the computer.

An example embodiment is an electrical device or receptacle comprising of: voltage and current sensors (input going into an analog sensor), ADC (digitizer) is between the sensor and CPU, microprocessor, taking current and voltage measurements in real time. The power is controlled and delivered on a real time basis. The power is controlled and delivered by turning on the switch every single cycle. This can be referred to as controlling the delivery of power.

An example embodiment is an electrical device and process enabling information to be extracted from the processor to a higher level decision-making control means/process step, for any purpose, whether for safety or power switching. The electrical device includes an API to extract information from the electrical device. The API is used to extract information and to provide high level control to the electrical device. The API can be used without a physical communication interface in some examples.

Another embodiment of the electrical device is for testing GFCI addresses achieving better resolution in the circuitry To address having the large dynamic range, in order to achieve better sensitivity and improved resolution on the current imbalance to detect Ground Faults, an analog circuit is added to do current processing after the current sensors, prior to providing the information to the computer.

The lack of resolution was not the processor's limitation. Having added the analog circuit is actually increasing the amount of information we have to process. Ultimately it is the analog signal that is being digitized and using it to do calculations. Using two analog signals, namely the black and the white, would not result in the resolution being good enough.

Example embodiments of the electrical device use an analog circuit to measure the differential current between two of the power lines, from hot to ground, allowing the electrical device to do the GFI to required resolution; and allows the electrical device to magnify the differential current.

Traditional industry uses mainly with GFCI in the analog domain, using current transformers. In traditional industry, the device passes the black and neutral on the opposite sides of the transformer and they cancel each other out, and any residual current will tell the device how much differential current there is, and proportional to that you can trip the breaker or receptacle device. The traditional industry device uses the differential itself to drive the tripping circuit.

In example embodiments of the electrical device, the subtraction is done in the analog domain, however that signal is taken in following ADC to do further analysis by the microprocessor which will apply its logic to the digital data.

Instead of measuring the absolute value of the current differences, example embodiments of the electrical device subtracts one current from the other, and measures the subtracted current—rather than measuring the absolute current directly. Therefore, example embodiments of the electrical device are measuring both the absolute current as well as the subtracted value of the current as well.

Example embodiments of the electrical device can detect GFI current as well as leakage current using this analog differential circuit. We have to have an external measurement of the leakage current done separately.

Example embodiments of the electrical device measures differentials, but is measuring using an analog circuit making it immune to magnetic interferences. Example embodiments of the electrical device are measuring the differential in the current between black and white, using the analog sensor which instantaneously tracks the difference between black and white along the AC cycle—so example embodiments of the electrical device are not looking at the difference in RMS (average) values—but looking at instantaneous differences as well, and measuring them using the processor—and are going to be looking at the wave forms of the differences as well.

Example embodiments of the electrical device looks directly at the waveform, and is far more sensitive to the variations that traditional industry may miss as those are looking just at the average values using RMS.

Now, example embodiments of the electrical device are going to be looking at the graph of the differential. If the external circuit is correct, then the differential graph should be steady regardless of how much we change the load. As the electrical device is tracking the differential, if there is an arc there may be a change in the differential; e.g. because of the arc, does the voltage and current go out of phase. For different loads, appliances will likely have different identifiable signatures.

Example embodiments of the electrical device are configured for identifying signatures of different appliances/devices/loads based on analyzing/comparing the differentials. And it doesn't have to be arcs. The differentials is current; voltage has to remain constant (fluctuations happen on the upstream, not at the load).

The differential is the current that the load is returning back. Normally should be equal to that coming in. If not the case, then either the load is taking the current in, or it's feeding the current into the circuit from somewhere.

Definitely the differentials will tell the electrical device of the characteristics of the load. The differential (current) is the difference between the current going in to the load and the current coming out. Normally they should be equal.

Example embodiments of the electrical device are looking at differential values using a huge range in measurement (e.g. using 14,000 counts to measure the difference). Previously we were measuring the complete absolute value using the 14,000 counts (high dynamic range); Example embodiments of the electrical device can measure the difference using the 14,000 counts, thereby effectively having magnified the small difference to such a huge range. Example embodiments of the electrical device look at this value, and because it is magnified, now has control over deciding at what point to trip.

Example embodiments of the electrical device are measuring using our analog measurement engine, and are able to not only measure the difference, but measure the waveform of the difference as well. Example embodiments of the electrical device can look at instantaneous variation in the difference.

The differential circuit can be used by the electrical device for GFCI; e.g. difference between black and the white. The differential circuit can be used by the electrical device for to parallel AFCI between hot and ground. As we are dealing with arcing between the black and the ground, there will be a differential and the electrical device will be able to detect it. It will be applicable to parallel arcing between live and ground because there will be a leakage.

Example embodiments can sample at relatively lower frequency sampling rate, such as 60 Hz up to 1.9 kHz. In order to do FFT at 100 kHz, need to collect samples at 200 kHz range, which means we would need to do almost 100,000 samples in one AC cycle. The electrical device may not have processor speed, nor memory to store that many samples. The smaller sampling rates enables the electrical device to do FFT and therefore analyze the data from a different perspective. The electrical device can operate from sampling rate of e.g. sixty Hz to 1.9 kHz. This has the advantage of having the ability to look at and do the analysis of all the data in the full spectrum in deciding if there is an arc or not. Having in low frequency sampling rate of 60 Hz to 1.9 kHz, collection of data for whole spectrum, Frequency analysis (e.g. FFT), and analysis of that data in the microprocessor; e.g. weighted sum of all the frequencies detected (or area under the curve).

In example embodiments the electrical device is in a low range as it is using the digitized version for frequency detection; e.g. digital converted signal (64 samples) so the max frequency we can detect is up to 1.9 kHz; we detect between 60 Hz to 1920 Hz. When arcing occurs we have seen activity in this range. We cannot go higher than our 1920 Hz because of our FFT.

In an example, the electrical device collects 64 samples of the RMS values per cycle, and then run standard deviation across them; looking at 64 cycles, storing data for 200 milliseconds time frame; if see standard deviation shows some are high peak and others low peak, then it is an arc. If no arcing, then the change in standard deviation will be close to zero. All of them will have the same waveform. The RMS value for each cycle will not change.

In case of arcing, the standard deviation will vary a great deal. Example embodiments of the electrical device notice the standard deviation goes beyond a certain value, e.g. an arcing threshold.

Example embodiments of the electrical device use statistical tools, such as standard deviation, as indicator of variations. Changes in the voltage will be represented by a higher standard deviation in the waveform. Example embodiments of the electrical device are configured for detecting erratic variation of voltage based on standard deviation of the RMS.

Traditional industry devices cannot incorporate the 5 mA differential (which is a GFCI specification) in their AFCI breaker as GFCI requires higher resolution.

Example embodiments of the electrical device can distinguish between 5 mA differential or less. By our incorporating AFCI and GFCI, and tripping at 5 mA, the electrical device is safer than existing traditional industry manufacturers' devices that incorporate 30 mA ground fault interruption.

By having the analog subtraction, example embodiments of the electrical device can trip as low as 5 mA differential, and do not need to digitally subtract subtracting black and white in the microcomputer.

Example embodiments of the electrical device can detect AFCI and GFI faults in the load or extension cord that is downstream or plugged into the electrical device. Traditional industry AFCI breakers cannot detect if an arc event is taking place in an electrical cord of an appliance/device plugged into receptacles. Example embodiments of the electrical device can be an AFCI breaker and detect an arc in a load or cord plugged into the receptacle because there is GFI built in. In Example embodiments of the electrical device, which incorporate GFCI, can detect an arc occurring in a cord plugged into the receptacle.

Example embodiments of the electrical device have high resolution. Traditional AFCI breakers put the ground fault tripping at 30 mA because they are not able to handle a high resolution. Example embodiments of the electrical device incorporate GFI, due to having separated in an analog circuit, the subtraction process rather than the microprocessor doing the subtraction, and being able to deal with high resolution and detecting the leakage current with high resolution.

An example embodiment is an electrical device including: a first contact for configured for electrical connection to a hot power line; a first sensor configured to provide a first analog signal indicative of current of the hot power line; a second contact for configured for electrical connection to a neutral power line; a second sensor configured to provide a second analog signal indicative of current of the neutral power line; a solid state switch for electrical connection to the hot power line and configured to be activated or deactivated; an analog-to-digital convertor (ADC) configured to receive the analog and output a digital signal, and a processor configured to detect a ground fault condition of the hot power line by determining a current imbalance between the hot power line and the neutral power line based on the digital signal from the ADC, for the deactivation of the solid state switch.

An example embodiment is a ground fault circuit interrupter including: power line conductor; a first sensor configured to provide a first analog signal indicative of current of the power line conductor; a neutral line conductor; a second sensor configured to provide a second analog signal indicative of current of the neutral line conductor; a solid state switch for electrical connection to the power line conductor and configured to be activated or deactivated; a ground fault trip circuit cooperating with said operating mechanism, said ground fault trip circuit being configured to deactivate said solid state switch responsive to detection of a ground fault condition associated with current imbalance between said hot conductor and said neutral conductor, wherein said ground fault trip circuit includes: an analog comparator circuit configured to receive the first analog signal and the second analog signal and output an analog signal indicative of a difference between the first analog signal and the second analog signal, an analog-to-digital convertor (ADC) configured to receive the analog signal from the analog comparator circuit and output a digital signal, and a processor configured to perform determining of the current imbalance for the detection of the ground fault condition based on the digital signal from the ADC, for the deactivation of the solid state switch.

In an example of the ground fault circuit interrupter, the solid state switch for electrical connection to the power line conductor may be used with a Triac. Once the Triac is triggered, the solid state switch may be de-activated as the voltage drop to or below zero at zero crossing point. The solid state switch may keep activated if there is no fault condition. In the example where the solid state switch for electrical connection to the power line conductor is IGBTs, the IGBTs may be activated at the top of the cycle, and may be de-activated after a duration, such as a few nanoseconds.

In an example of the ground fault circuit interrupter, the analog comparator circuit comprises a differential amplifier. In an example of the ground fault circuit interrupter, the detection of the ground fault condition by processor includes determining that the current imbalance exceeds a threshold current imbalance and/or that the current imbalance has lasted for more than a threshold time.

In an example of the ground fault circuit interrupter, the detection of the ground fault condition by processor includes determining that the current imbalance exceeds a threshold current imbalance. In an example, the threshold current imbalance is 5 mA or less. In an example, the threshold current imbalance is less than 30 mA.

In an example of the ground fault circuit interrupter, the detection of the ground fault condition by processor includes determining that the current imbalance has lasted for more than a threshold time.

In another example, the electrical device is configured to detect another kind of electrical fault. The electrical device may detect any current and or excessive voltage occurring on or passing to the safety ground. The safety Ground Imbalance Detector (GID) may monitor both the voltage level and any current flowing on the safety ground wire/circuit.

There is a need to detect electric faults, whereby the human body's susceptibility to electric current and voltage can result in individuals experiencing serious electrical shock due to uncontrolled flow of electric current over the earth. Electrical services to residences, commercial establishments and industries need to protect occupants from potentially hazardous electrical shocks. It is extremely dangerous to short the neutral to the ground in a load center, electrical breaker panel and/or distribution box. This can result in hazards current occurring between safety ground and the neutral. Current can fly to the safety ground even if there is no direct connection.

The moment that the load is switched, not all current flows through the neutral. The Safety Ground can pick up current as it has the least resistance.

Breaker panels and distribution boxes (including but not limited to junction boxes), and receptacle devices can be a source location where black and white wiring initially originating from the breaker panel. When wiring is spliced, often wire-nuts or marrettes are used to connect and insulate the splices, which are used for the distribution of power to different loads. It is possible that somewhere on the circuit a marrette joining the white wires can become a glowing or open contact. Once the current cannot flow back through the white, if there is a safety ground connected on or near that line, then the current will travel down that path of least resistance; the white will raise in voltage potential and can dangerously short someone.

Electric shock may be caused by “stray current”. And when there is a GFI issue, the current can be significant. If someone shorts the neutral and the ground in a junction box, the whole box can become “hot”/live. Someone touching it would get a shock because the current starts flowing through the ground wire rather than the white. If they short it and/or if somehow the ground wire is disconnected, the whole circuit will be hazardous.

An example embodiment is an electrical device that is a safety ground imbalance detector which detects for any potential hazardous voltage occurring between the safety ground and the white neutral ground, and/or any current that may be flowing. The ground imbalance sensor may include a current sensor and a voltage sensor as a combo sensor. The ground imbalance sensor may also include only one current sensor or voltage sensor to detect safety ground fault.

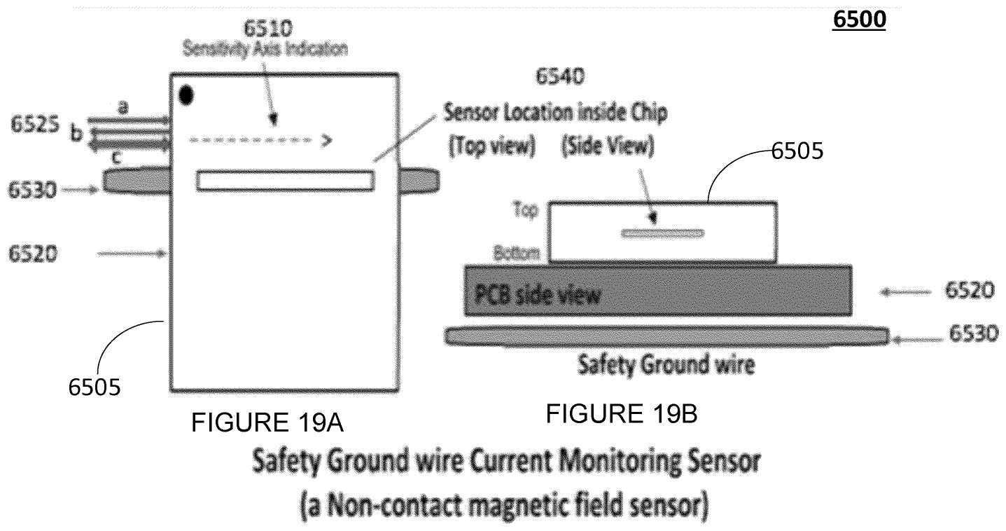

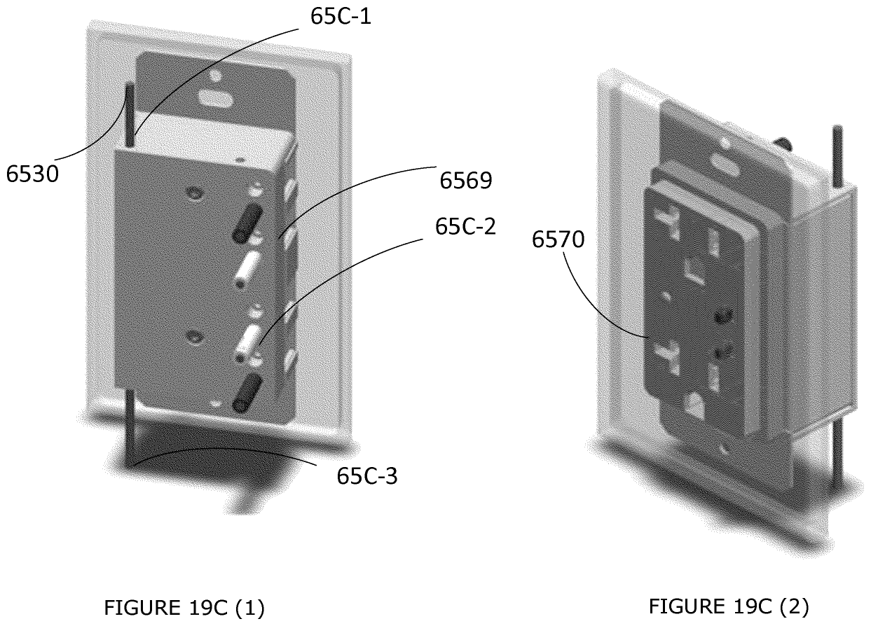

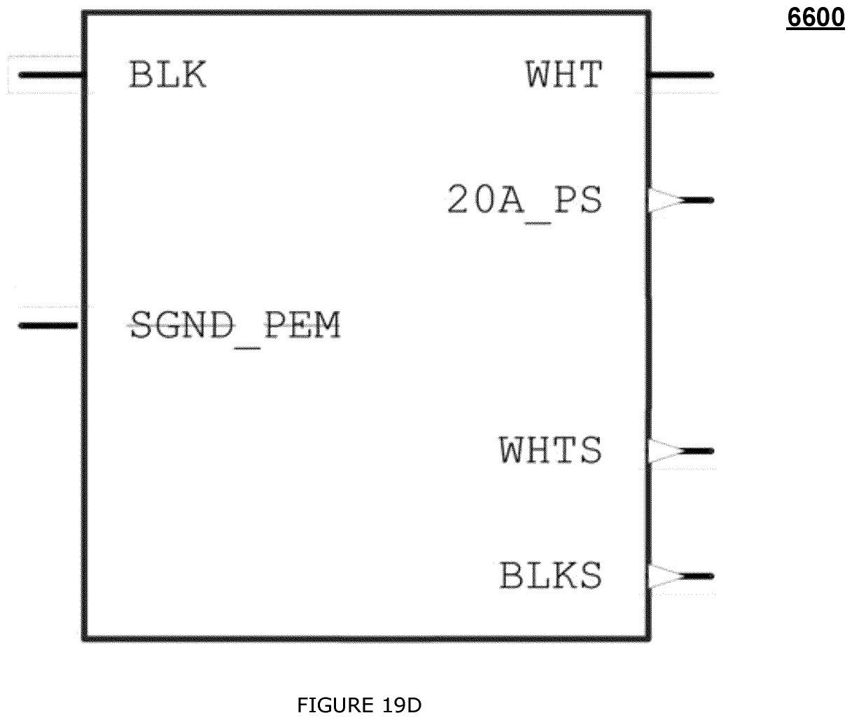

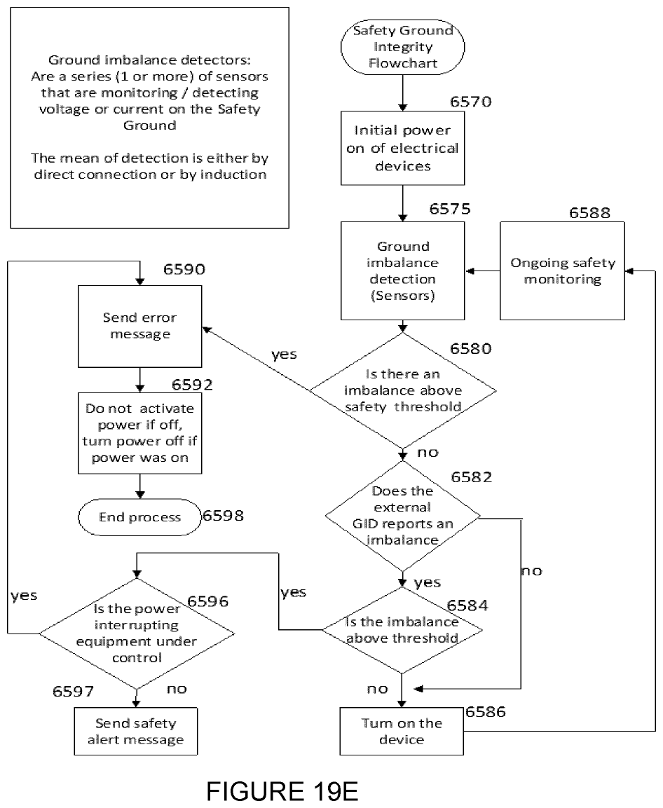

The current sensor (FIGS. 19A, B and C(1) and C(2)) may use induction from the safety ground wire to be described; the voltage sensor is illustrated in FIG. 19D.

The combo sensor detects both voltage and current with respect to the neutral line using the voltage sensor and current flowing on the safety ground using the current sensor. The combo sensor therefore provides greater certainty for detecting a safety ground fault rather than using only one current senor or a voltage sensor. The electrical device is detecting an imbalance between neutral and ground using a voltage and current sensing circuit in conjunction with a special analysis software program.

The voltage and the current may be monitored. A processor may determine whether the voltage level measurements received from the voltage sensor has reached a potentially hazardous level to the user, and if so, take action accordingly.

The electrical device is a ground imbalance detector which detects voltage differences between the safety ground and the neutral. In addition to the current and voltage sensors and sensing already disclosed, such sensors are used as a ground sensor. The electrical device is configured to detect and indicate that the safety ground has been compromised and to shut off the power.

The safety Ground Imbalance Detector (GID) device, as illustrated in FIGS. 19A-19E to be described below, may be mounted internally on a main board of the device or externally on the Printed Circuit Board (PCB). The PCB may be connected to the device via a signal cable, such as a communication cable or voltage cable. When mounted externally, the GID and other sensors, including but not limited to water sensor(s), may be monitored by sending the measurement results of these sensors to a processor. The processor may determine whether a measurement result has reached a threshold. Traditionally, the industry AFCIs or GFCIs do not detect if there are any problems occurring on the safety ground. Existing equipment typically does not detect any current or voltage leakage or short circuit, between the white neutral line and the safety ground. Special safety equipment, but not branch circuit breakers and receptacle devices, may be used for this purpose in special electrical environment.

For example, when a 3-prong plug is used to supply power to a metal appliance, the metal of the appliance is traditionally connected to the safety ground which in turn connects to the safety ground in the plug. When voltage leaks to the safety ground to 30 volts or more, this creates a safety hazard.

The industry only deals with stray current leakage from the black, not from other conductors, such as a black and/or red, which may be in opposite phase and which is not going to a GFI. When there is current leakage to the safety ground, the leakage may not be indicated in a normal breaker.

The sensors may measure current of 15 amp or the 20 amp and may be used as safety ground current sensors in a GID. The sensors may also measure current of other amperages based on international standards, or a specified amperage of a specific application. A separate safety ground voltage sensor may also be included in the GID. The GID or a PCB incorporating the GID may include one or more pins or PEMs. A PEM is a type of self-clinching surface mount or stud for providing a reusable mounting point on a thin metal sheet and a PCB. In some examples, the safety ground may be mounted to a PEM, and the PEM may indicate “safety ground”.

FIGS. 19A and 19B illustrate an exemplary safety group wire current monitoring sensor 6500. The Safety Ground Wire 6530 in FIGS. 19A and 19B is placed beneath the PCB 6520 for the sensor 6500 to detect stray current. The Safety Ground Wire 6530 may also be placed above the PCB 6520, provided that the distance and sensor sensitivity requirements are met and in a controlled position in relation to the sensor 6500. The distance and sensor sensitivity requirements are determined by sensor manufacturer specifications as well as the level of the current.

Block 6510 on the surface of the chip 6505 is a reference line, and illustrates the sensitivity axis which relates to the position for the wire to pick up the magnetic field(s) generated by the current. Since the sensor detects the magnetic field induced by current circulating in the wire, the position of the sensor is important for accurate readings,

Block 6520 is the printed circuit board (PCB) placed over the wire 6530. The PCB 6520 incorporates the current sensor chip 6505. The PCB 6520 may carry voltage and signals. This will indicate the level of current or voltage detected. The voltages are read by the processor which performs the analysis.

Block 6525 represents three signal paths directed to the PCB Block 6520, to power the chip 6505 via the path 6525a, and to transmit measurement results from the chip 6505 via the path 6525b.

The voltage provided on the PCB 6520 may be a low voltage such as 3 volts, or 5 volts. The voltage value may depend on factors including but not limited to sensitivity of the sensor type and the type of conductors used (e.g. bus bars, wires etc.). If long distances are desired, a wire connecting the sensor may not directly connect to a CPU or a processor, but may connect to a local adjacent processor incorporated on the GID circuit. A communications line or channel may be used to connect the sensor with the local adjacent processor for transmitting the measurement results from the sensor to the local adjacent processor. The PCB 6520 in this example may output an analog voltage from path 6525a and output a communication signal or measurement data from path 6525b to the processor or CPU.

In some examples, Block 6520b may output of analog or digital signal from the PCB 6520 to the processor. If the output signal is an analog signal, and ADC may be used to covert the analog signal to digital signal for the processor to process. The strength of the signal may be proportional to the value of the current. The signal may be the magnetic field.

Path Block 6525c may connect to the white neutral line. The white neutral inside the circuit ground may be bi-directional as current input and output from the circuit on the PCB 6520. The path 6525c may be an internal ground of the sensor 6500 and may be different from the safety ground 6530. Path 6525c feeds voltage of the PCB 6520 back to the processor (not shown). The processor may be incorporated on the same PCB 6520.

Block 6530 is the bare safety ground wire beneath the PCB 6520. The other two wires in the three conductor cable (black, white) is not illustrated (e.g. a romex cable).

Block 6540 is an example of a possible location of the current sensor inside the magnetic field sensor chip 6505 which is located on the PCB 6520. The GID sensor has indicators for the placement location related to the conductors.

A plastic clip(s) can be attached to the PCB 6520 so it can snap on to the bare safety ground wire 6530. Alternatively, tie wraps or any suitable attachment means could be used.

In an example embodiment illustrated in FIGS. 19C(1) and 19C(2), the current safety ground wire 6530 is in an enclosure 6569 housing the safety ground current fault sensor module 6500. In the example of FIGS. 19C(1) and 19C(2), the current safety ground wire 6530 passes through and is incorporated within a channel or tunnel in the box enclosure 6569, at a distance enabling sensing from the chip 6505 on the PCB 6520. The distance is determined by the expected current flow and the conductor type.

The Safety Ground Wire (“SGW”) 6530 may be a bare wire with a length, such as 4″ to 6″. Safety Ground Wire (“SGW”) 6530 may be securely fastened in the housing, for example through a tunnel or channel in the housing 6569. The safety ground bare wire 6530 may be inserted through the input hole area 65C-1 and the white wire is inserted in 65C-2. The bare wire is passes through 65C-1 out through the other end 65C-3, and the bare wire 6530 may be attached to a screw. As 6530 is contained securely inside the box in FIGS. 19C(1) and 19C(2), when the screw is tightened, the bare wire 6530 electrically connects the safety ground of the PCB 6520. The ground is still separated and not directly contacted with the PCB 6520. This method facilitate installation as it ensures maintaining a secure fastening of the SGW 6530 in an exact position in relation to the ground sensor chip 6505. Furthermore, during installation, when the two screws for the box are tightened, the GSW is already in its proper place. There are separate openings on the cover of the enclosure 6569 for the screws. The SGW 6530 does not electrically connect with the screws, and this provides electrical safety and electrical insulation/isolation.

The sensor 6500 may monitor multiple downstream grounds, and the conductors originating at the breaker panel. In an example embodiment, the sensors are in the connection point in the breaker panel and may indicate that a conductor(s) brings in the signal.

When the SGW 6530 is connected in the enclosure 6569, for example in a receptacle device, the enclosure 6569 is placed over the SGW 6530 for sensing current flowing through the SGW 6530 without interrupting the current.

The neutral wire is an internal ground; the circuitry on the PCB 6520 may use the neutral as ground. SGW 6530 is the safety ground which connects to the electrical enclosure 6569 by fasteners, such as screws. In this case, the current flowing through the safety ground wire 6530 is physically continuous without interruption.

FIG. 19D illustrates an example of a Safety Ground Voltage Sensor 6600. The voltage sensor 6600 may include pins of BLK, WHT, 20A_PS, WHTS (white line sensor), BLKS (black line sensor), and SGND_PEM. The PEM (PEM stud, metal pipe-shaped) is the metal from which the voltage for SGND is provided. The PEM is an example of the means for providing safety ground voltage to the voltage sensor. The Safety Ground Sensor 6600 senses the pin SGND_PEM for voltage. Safety Ground (SGND) is not a separate clip, but is a PEM which holds the PCB board, coming from a plate.

The flowchart in FIG. 19E illustrates logic in which the GID of an electrical device, such as an appliance, is configured to detect and optionally indicate, such as on a screen, whether the safety ground has been compromised. If the safety ground has been compromised, the GID of an electrical device may not turn on the device or not deliver power to the appliance from the next half AC cycle. The detection that the safety ground has been compromised may be achieved by directly connecting to relevant wire(s) or by induction without directly connecting to the wire(s).

At step 6570, power is turned on an electrical device. At step 6575, one or more sensors of the GID may be used for detecting ground imbalance, for example, for current, voltage, or both current and voltage. The processor of the GID may read or receives input from the sensors 6500 and/or 6600. At step 6580, the processor may determine whether there is a sufficient imbalance and if so, whether the imbalance is above a predetermined safety threshold level. If the imbalance is above a predetermined safety threshold level, such as to a hazardous level to human being, the processor at step 6590 may send an error message for display on a screen of the GID device. The error may also be indicated by sound, alert LED light. At step 6592, the processor may further determine where the electrical device is powered on. If the power is not on, the power may not be delivered to the device. If the power is already on, the delivery of the power to the device may be discontinued and the user may investigate the cause of the error. The process is then ended at step 6598.

If the processor determines that imbalance is below a predetermined safety level, the imbalance is deemed not to be hazardous. At step 6582, safety ground fault inputs from external sensors are considered. The safety ground fault inputs may be transmitted to the processor via an external GID link. If the external GID is local to the processor, the sensor may directly detect voltage and communicate with the processor via the external GID link. If the external GID link is remote from the processor, the external GID link may connect to a separate processor for communicating the safety ground fault inputs to the separate processor. The separate processor may then communicate the received safety ground fault inputs to the processor. If processor determines that the external sensors indicate an imbalance above a predetermined threshold at step 6584, and that the power interrupting device is under control at step 6596, and in the circumstance where there may be no possibility of direct control of the external GID, an indication that there is an electrical hazard may be desired, the processor may generate and send a signal and/or alert event at step 6590 to alert external safety ground fault event and perform the operation at step 6592 as described above. External safety ground faults may include, but is not limited to, a breaker panel becoming live, in which case emergency warnings would indicate that only professional electricians or emergency personnel should disable the delivery of power at the breakers. For example, the professional electricians or emergency personnel may need to wear suitable protective clothing, rubber boots, and prover gloves, the professional electricians or emergency personnel may also trip manually the plastic breakers until the source of the safety ground fault is identified.

If the processor determines that the external sensors indicate an imbalance is not above a predetermined threshold at step 6584, the processor may turn on the electrical device at step 6586 and keep monitoring the imbalance at step 6588 and detecting ground imbalance at step 6575.

If the processor determines that the power interrupting device is not under control at step 6596, the processor may send a safety alter message on a screen of the GID device to indicate that the power interrupting device is not under control.

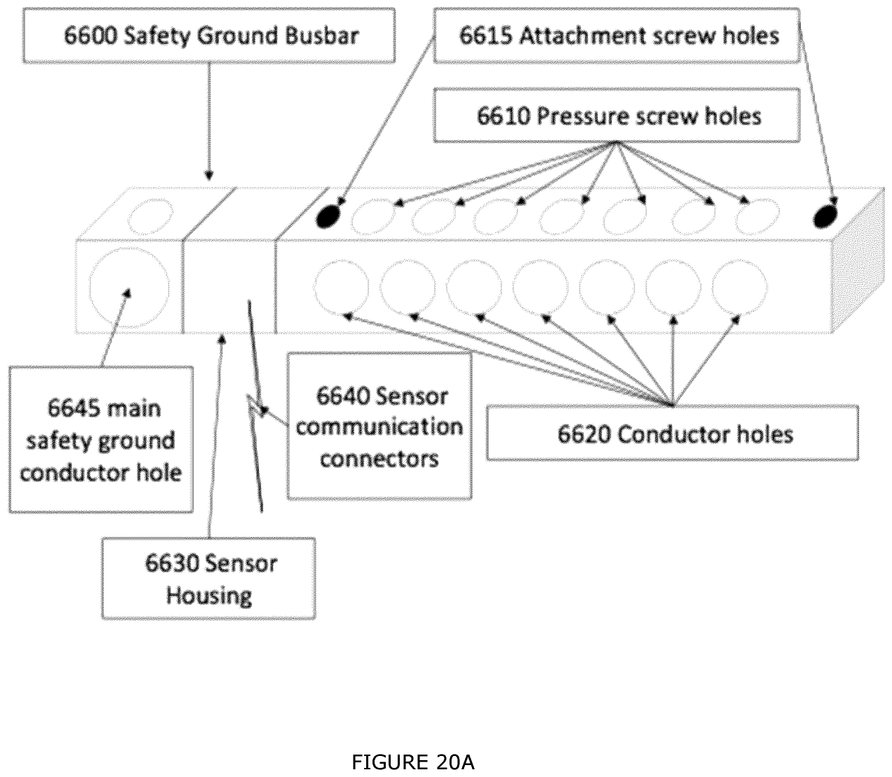

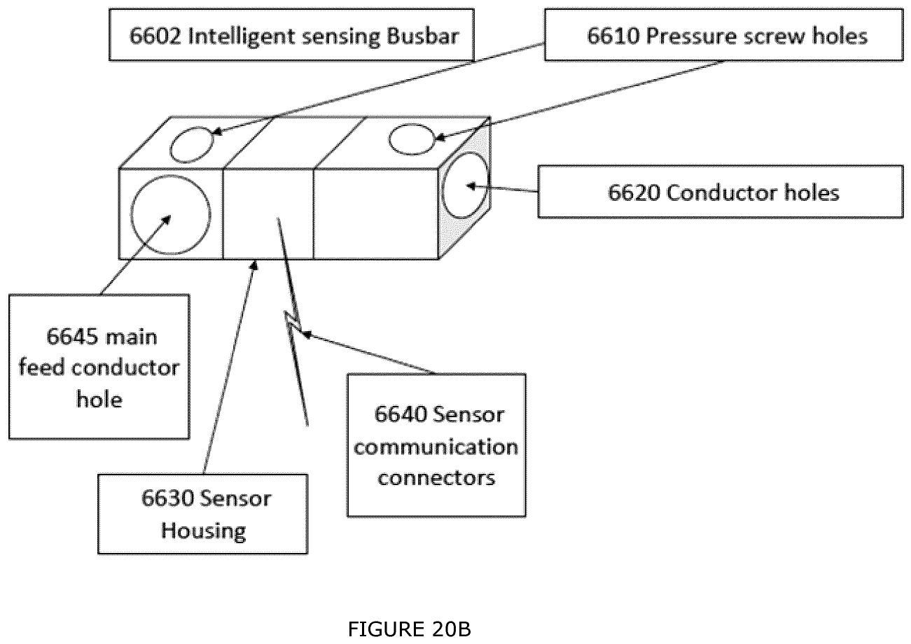

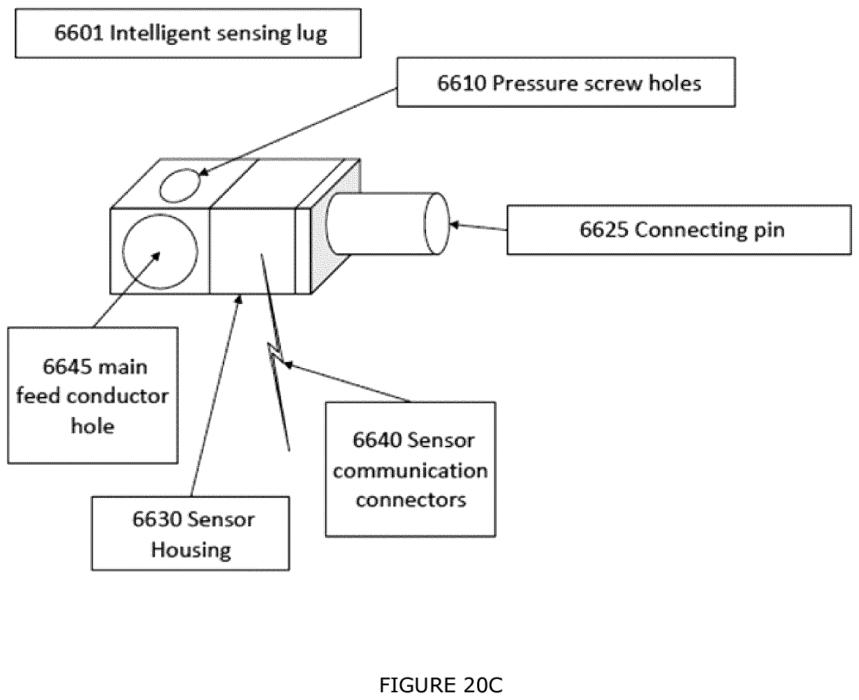

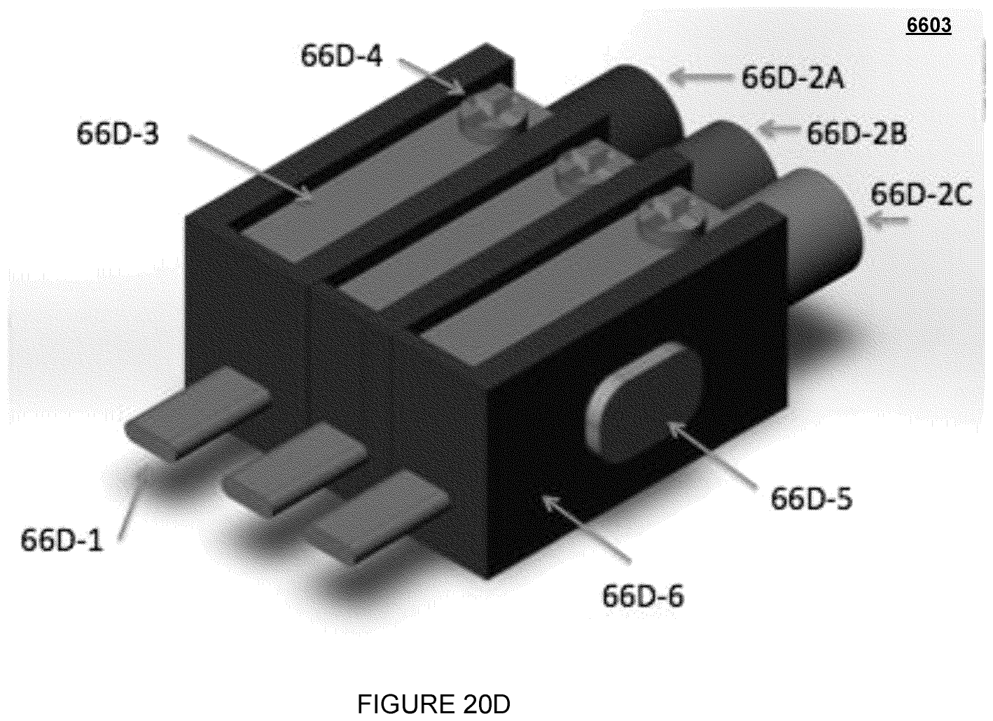

FIG. 20A illustrates an example of a safety ground bus bar 6600. The bus bar 6600 may be a self-contained external GID bus bar. The bus bar 6600 may be a rectangular bar.

The bus bar 6600 may include a plurality of screw holes 6610, each for receiving a screw. In some examples, the square bar may have a length of ½″, and the screw may be #20 screw. The bus bar 6600 may also include a plurality of conductor through holes 6620, each for receiving a power line or wire. The screw holes 6610 may be perpendicular to the conductor through holes 6620. In use, a power line may be inserted into the bus bar 6600 from one side of the bus bar 6600 and extended out from the other opposite side of the bus bar 6600. The screw may, via a screw hole 6610, secure a wire placed in the conductor holes 6620. In some examples, the safety ground conductors get connected via the connector holes 6620 and the wires are secured via the pressure screws inserted into the pressure screw holes 6610. The bus bar 6600 may also include one or more attachment screw holes 6615 for mounting the bus bar 6600 to an object, such as a panel, a wall, or a cabinet.

A sensor housing 6630 may be formed at an end at the body of the bus bar 6600, and one or more sensors may be housed at a sensor housing 6630. The sensor housing 6630 is a space defined at the body of the bus bar 6600 for securely retaining the sensors or a sensor assembly having one or more sensors. In some examples, the sensor housing 6630 may retain a Ground Imbalance Detection sensor unit, as described above. From the sensor housing 6630, a connector 6640, such as a cable, may be extended out from the sensor housing 6630 for communicating the measurement results of the sensors or sensor assembly to or processing module, for example, a processor. The sensor may be a current sensor, a voltage sensor, or both current and voltage sensors. The measurement results includes the measurement results of voltage and/or current flowing in the bus bar 6600 in relation to the safety ground. The sensor may be used in any equipment with common safety ground connection. The current and voltage sensors in sensor housing 6630 on the safety ground bus bar 6600 are the safest way to detect any current leakage. The monitoring equipment may be programmed to determine safety leakage levels. The monitoring equipment may use the sensor leads 6640 for monitoring the leakage level. The Monitoring equipment may receive a signal indicating the level of current or voltage present. In some examples, the sensor leads 6640 may be replaced with a cable and connector 6650. The monitoring equipment interact with the cable and connector 6650 by receiving at the monitoring equipment a signal indicating the level of current or voltage present.

The bus bar may also include a safety ground conductor hole 6645 for inserting of a conductor to the ground post, such as the cold metal water pipe located before the water meter. The conductor typically is a large braided bare or multi-strand number 8 wire (or larger) which carries any leaking current from the safety ground wire(s) from the respective connections and or devices, into this ground. As leakage current flows, the energy indicated (by the magnetic flux) is compared to a threshold and accordingly an alert may be sent as required.

It is a good wiring practice that when conductors are connected inside a breaker panel, the strain relief that prevents ripping of the wire may be insulated, and the ground wire may contact with the bus bar 6600. In some examples, the connectors may be loose in the breaker panel. Leaving the wires loose may create a short to the enclosure. The safety ground bus bar 6600 is phase independent, and may protect any kind of electrical panel with any current or voltage. As described above, a GID may determine whether a potential hazard is present, and thus protect a user from such hazard.

The bus bar 6600 may replace conventional ground bus bars used in conventional breaker panels, for detecting faults occurring at a premises, such as a residential house or building or a commercial building. A GID described above may be housed inside the bus bar 6600.

The bus bar 6600 may be attached to an object, such as a wall or a cabinet, using the attachment holes 6615. The bus bar 6600 may be directly connected to a safety ground. In some examples, the ground bus bar 6600 may be connected to a breaker panel housing. When the bus bar 6600 is installed, the bare safety ground from the field to the breaker panel may not electrically connected to the breaker panel housing. By insulating the ground bus bar 6600 from the breaker panel cabinet, the cabinet is not part of the electrical circuit. Therefore in a GFI event, a user would not be shocked by touching the panel housing. As such, the safety of an individual is improved.

In some examples, the bus bar 6600 and sensors contained in the sensor housing 6630 may be used on the white power lines. Using GID, the bus bar 6600, or both the GID and bus bar 6600 on a white wire may include an indicator for any ground imbalance. For example, bus bar 6600, or both the GID and bus bar 6600 may be used on the white power line combined with a separate power line, such as a black power line or other power lines, to indicate that there is leakages present. In some examples, the bus bar 6600, or both the GID and bus bar 6600 may be used on the black and red power lines. The bus bar 6600 may monitor a single phase or be used for a single circuit distribution method.

The bus bar 6600 may be used in any equipment with common safety ground connection, or other equipment where there is a common return point for conductors flowing to a single point/return. The bus bar 6600 may effectively be a data collection device for current and voltage by using the sensors or a sensor assembly.

In another example embodiment, a second sensing bus bar 6600 for the white (neutral) conductor may be used for replacing the existing bus bar. In another example embodiment, a bus bar may be used on the white(s)/neutral, the bus bar 6600 may be used as a second sensing bus bar, but for the white/neutral wires, resulting in having an indication of any ground imbalance.

In an exemplary embodiment, a current sensor may be used on the white(s) power line, and a separate sensor may be used on each of the hot phase(s) (Black, Red, etc.). A separate processing module or a processor may be used to receive measurement results from the sensors. A ground fault may be detected, in a similar manner as a GFCI breaker or a GFCI receptacle device, based on predetermined thresholds, or thresholds provided in real time. This embodiment may or may not provide control of the delivery of power, but may send an alarm indicating the presence of leakages. The bus bar 6600 may be used to detect ground fault leakages, and/or power imbalances between the black/red (hot, live power) and white (neutral) for one or more circuits connected to the bus bar 6600. The bus bar 6600 may allow detection of arcs, included but not limited to series arcs, by incorporating voltage measurement results generated by the sensors, i.e. the bus bar and/or lugs with sensors may provide an effective electrical fault detection means; and combined with the processor, power delivery control.

In another example embodiment, the sensors of the bus bar 6600 may be mounted on the red and black live phase wires to monitor the measurement results of both wires, or mounted on red, black and white live phase wires to monitor the measurement results of all three wires.

The bus bar 6600 therefore may provide complete data analysis on existing breaker panels by using the safety ground bus bar 6600 with the existing breaker panels, a white neutral busbar(s) and one or more wire-mounted sensors for hot (live) phases. All of the sensors may be connected to one or more monitoring devices.

FIG. 20B is an example of an Intelligent Sensing Bus Bar 6602. The intelligent sensing bus bar 6602 may incorporate receiving a wire through a main feed conductor hole 6645, and providing an exit path for the conducting wire through the conductor hole 6620. A jumper cable may be used between the conductor hole 6620 and an existing bus bar.

FIG. 20C illustrates an intelligent sensing lug 6601 that has a protruding pin 6625. In the example of FIG. 20C, the pin 6625 takes the place of the wire in the example of FIG. 20B, and may be installed perpendicular to the bus bar. In FIG. 20B, the wire may be installed parallel to the bus bar or side-by-side to the busbar. For other embodiments, the hole 6645 alternatively may be located at the other end of the sensing bus bar, for example, directly facing opposite the connecting holes 6620.

A feed wire may goes into main feed conductor hole 6645, secured by the pressure screw 6610 and is conductively connected to the pin 6625. Connecting pin 6625 may be inserted into the original hole of the power distribution bus bar, from which the power supply wire was removed.

In other embodiments, the hole 6645 alternatively may be located directly facing opposite the connecting pin 6625.

The connecting pin 6625 may be attached by being tightened by the housing screw, to a traditional bus bar or to a terminal connector assembly.

The intelligent sensing bus bars and lug(s) disclosed herein may be used with hot, neutral and/or ground power lines. The intelligent sensing bus bars and lug(s) may also be configured as one in one out. One per hot phase and one per breaker.

In another embodiment, a unit may be constructed such that a single bus bar may have a single sensor for current and/or voltage coming in and going out, for one or more conductors. A protocol such as Modbus in a serial communication environment such as RS485 and multi-drop RS485 environment in another embodiment configuration may be used to accommodate multiple conductors.

In another embodiment the intelligent lugs 6601 may be used to monitor each circuit coming from the field allowing for circuit independent detection and analysis.

One, two and three phase environments may be dealt with at the intelligent bus bar level rather than the power processing modules herein disclosed. Three of these bus bar modules may be used on each of the three phases, providing advanced energy data monitoring for any and/or all phases.

FIG. 20D illustrates an example of a joint three-phase intelligent current and/or voltage Sensing/Monitoring Module 6603, which may be used to handle 3-phase power applications, to provide both current, voltage and power synchronization and related waveform information to a power control processor. The module 6603 may be self-contained embodied as the power input portion of a 3-phase power bus bar. Another example embodiment may incorporate lugs.

Block 66D-1 may be power output terminals which may be used to provide the monitored power to either a 3-phase breaker, and/or as an AC contactor power input contacts.

The power output terminals may have holes in which screws may be used to attach the related power output to the each bus bar or simply they slide into the compression screw terminals of a contractor or breaker etc.

Blocks 66D-2A, 66D-2B and 66-2C are incoming power wires, i.e. the black (Phase 1), red (Phase 2) and blue (Phase 3) wires, respectively. Each wire may be secured by a screw 66D-4.

Block 66D-3 is the metal body of the respective power delivery/sensor module 6603. The modules 66D-3 are insulated from each other by an insulating body/casing 66D-6 (the material surrounding each of the modules 66D-3.

Block 66D-5 is the encapsulated electronics of the power delivery/sensor module 6603, the electronic circuitry are encapsulated inside the metal body, where electronic circuitry senses the various currents and voltages flowing through the respective power delivery/sensor module(s). The electronic circuitry is encapsulated to prevent them from being damaged and to ensure the various sensors are maintained in the correct position relative to the respective conductor(s) and sensors. This also ensures the timing and voltage relationship for the internal sensing elements.

Although a three-phase embodiment is illustrated in FIG. 20D, other embodiments may be for single to an n-phase module, which provides a single intelligent current and/or voltage Sensing/Monitoring Module 6603.

In the example of FIG. 20D, the respective power delivery/sensor module 6603 includes three metal bodies 66D-3. Another embodiment may contain 4 Sensing/Monitoring Modules. Where 2 modules are the connected to the incoming 2-phase 110/220 AC power, another to the White/Neutral, and the fourth being the Safety the ground. The respective modules output may be connected to a bus bar/connector strip etc.

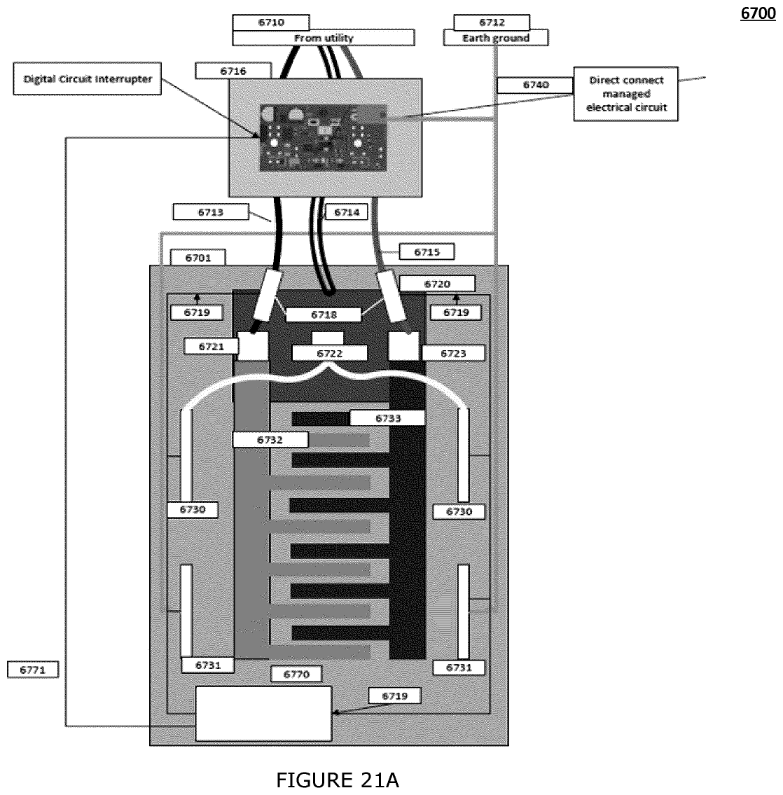

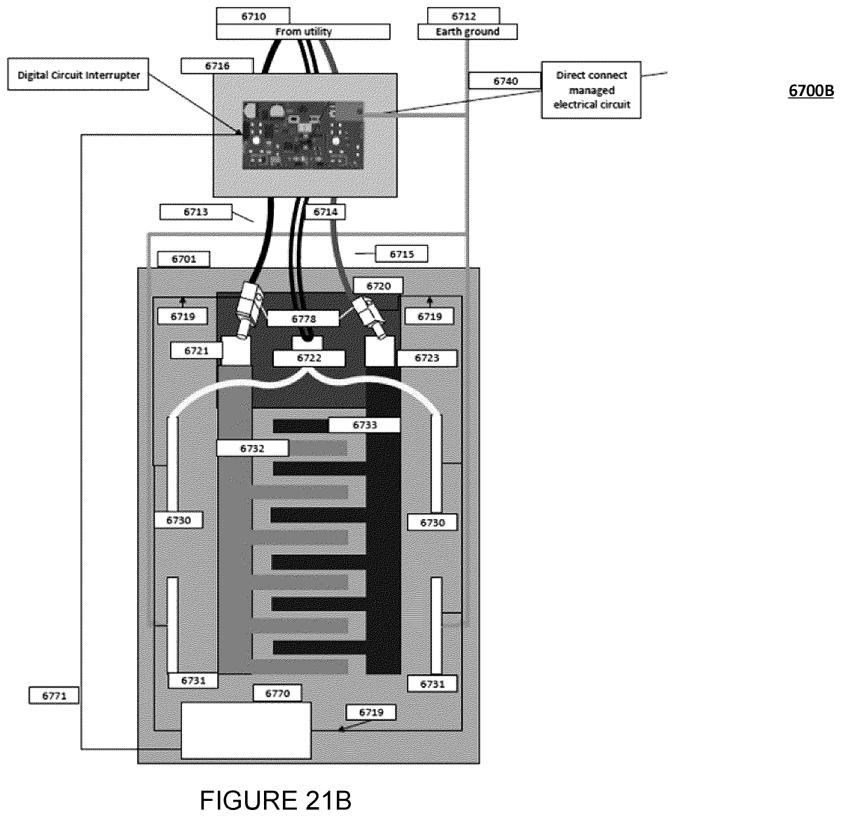

FIG. 21A is one embodiment of an existing analog breaker panel that may be enhanced with sensors that would allow the characterization of the electric profile to maximize safety detection, including but not limited to Arc faults, Ground Faults and other All Safe detection capabilities. The disclosed system and method could be used in both AC and DC environments. FIG. 21A illustrates a digital master breaker circuit interrupter electrical safety protection system 6700, embodied in a two-phase environment.

The digital master breaker circuit interrupter electrical safety protection system 6700 may include a breaker panel 6701 and a digital circuit interrupter 6716. The breaker panel 6701 may include one or more sensing bus bars 6730 for sensing white/neutral distribution wires, and one or more sensing busbars 6731 for sensing safety ground distribution wires.

Block 6701 is the breaker panel. Block 6730 are sensing bus bars for white/neutral distribution wires. The example of FIG. 21A illustrates 2 bus bars 6730. In some examples, the digital master breaker circuit interrupter electrical safety protection system 6700 may include one or more bus bar 6730.

Block 6731 are sensing busbars for safety ground distribution wires. The example of FIG. 21A illustrates 2 bus bars 6731. In some examples, the digital master breaker circuit interrupter electrical safety protection system 6700 may include one or more bus bar 6731.

Block 6720 is the insulator backplane support surface that supports all the connections from the main breaker; 6721, 6722 and 6723 are connection posts for connecting the hot phases or neutral wires coming from the transformer and/or other panels to the digital master breaker circuit interrupter electrical safety protection system 6700. Block 6732 and 6733 represent the hot distribution busbars for the 2 hot phases powering the local breakers.

Blocks 6719 are the sensor data connectors, such as cables for transmitting measurement data from the sensors to the circuit interrupter 6716. Block 6718 shows two sensors monitoring hot phase(s) 6713 and 6715. In this embodiment, Block 6716 replaces the master analog breaker and acts as the master circuit interrupter protecting the breaker panel 6701. In another embodiment, the master circuit interrupter 6716 may be placed before or after (from an electrical standpoint) the traditional master breaker and be located in the immediate vicinity.

In the example of FIG. 21A, the digital master breaker 6716 is outside the breaker panel 6701. The digital master breaker 6716 may or may not replace the master analog circuit breaker. In another example embodiment, a legacy analog main breaker may be used instead of being replaced by a digital master breaker 6716, and sensor connectors 6719 may be connected to a separate monitoring unit.

In this specific embodiment, the digital master breaker 6716 is a digital circuit interrupter which may directly manage and optionally directly monitor, protect and control one or more emergency circuits 6740 that may not trip if the breaker panel is disconnected in case of a detected fault.

In this embodiment, the entire breaker panel 6701 is monitored by one or more sensors 6718 and one or more sensing busbars 6730 and 6731. The example in FIG. 21A illustrates two sensors 6718 and two sensing busbars 6730 and 6731. This embodiment shows that the digital master breaker circuit interrupter electrical safety protection system 6700 may be used in a two-phase system. The digital master breaker circuit interrupter electrical safety protection system 6700 may also be used in 1 to 3 hot phases, and even more phases.

The information transmitted to the digital master breaker 6716 by the different sensors allows the digital circuit interrupter 6716 to protect the environment as a whole, rendering this legacy analog breaker panel as safe as a modern unit.

This digital master breaker circuit interrupter system 6700 may also provide system wide statistics, including but not limited to the electrical consumption; and if properly certified, it may be used as a utility meter—reporting directly to the utility.

Block 6770 may be an encased sensor communication module for receiving and aggregating information from all the sensors 6718 via a communication path 6719. Although in the example of FIG. 21A, the sensor communication module 6770 is located inside the breaker panel 6701, in another example embodiment, the sensor communication module 6770 may be located outside the breaker panel 6701. A digital master breaker 6716 may note be required; sensor communication module 6770 may optionally transmit command(s) and/or data signal(s) from a processor for possible actions that result from sensor information received. If digital circuit interrupter 6716 is present, the digital circuit interrupter 6716 may decide whether or not to trip or power a circuit based on the signal information received from 6770. Alternatively, intelligent sensing lugs may be installed on each hot wire coming from the field, therefore providing circuit specific information.

Block 6771 may be a communication link between the sensor communications module 6770 and the intelligent circuit breaker 6716.

Additional electrical safety functionality may be incorporated for example on the housing of the circuit interrupter, including but not limited to: on/off buttons, test/reset buttons, status LEDs and a display screen to show the status of the system and/or system statistics.

The sensor connectors may use other means of connections including but not limited ribbon cables, wireless connections, fiber optics. If an imbalance is detected by the module 6670 due to the presence of current or voltage that should not be present, the module 6670 may either inform the user by sending a present message/alarm or if an intelligent circuit interrupter is present, the module 6670 may determine, for example by consulting a pre-set table of values, the action to be taken: for example, from sending an alarm message to cutting power to the entire breaker panel.

FIG. 21B illustrates an example of a breaker panel 6700B incorporating intelligent voltage and/or current sensing lugs as described above in FIG. 20C. Wire may extend into the sensing lug described above which may extend into an existing connector. The breaker panel 6700B may be used on any or all the distributed power wires, including neutral if desired. The sensing lugs may be part of the sensor communication module 6770 described above.

In the example of FIG. 21B, Blocks 6778 are two lugs that are connected to at the point where the black and red used to be connected. Similarly, the same lugs may be incorporated in Blocks 6730 and 6731. As well, rather than changing the bus bar, the white wire connection may be replace with 6778 lug, as described above in FIG. 20C.

Blocks 6778, 6770 and 6719 (sensor wires) may be incorporated in a single “pre-assembled” module, or assembly. The digital circuit interrupter 6716 may or may not be incorporated as part of a pre-assembled assembly unit. The digital circuit interrupter 6716 acting as an intelligent master breaker, may be used in conjunction with an analog master breaker, whereby the analog master breaker is primarily used for protection against external fault events rather than inside events.

In another embodiment, the sensor data collection module Block 6770 may be external to the breaker panel 6701.

In another example embodiment, intelligent sensing lugs 6601 may be installed on multiple hot wires and breaker connections in FIG. 21B for black wires going into each of the breakers, thereby providing individual circuit information. For example, multiple intelligent sensing lugs may replace a traditional bus bar. Multiple configurations are possible, including but not limited to for example, 4 large size lugs connected into the module and 48 small lugs to monitor black wires.

The wire coming from the master breaker may be fed into an intelligent sensing lug 6601 first (albeit larger than in the other embodiment 6721 and 6723), and the lug 6601 may be connected to the terminal of the breaker panel 6701.

Same intelligent sensing lug(s) 6701 may be used to feed into a breaker, or for the main connection into the breaker panel.

Example embodiments of the electrical device can detect non-continuous arcing. Traditional industry devices require a continuous arc because they are looking only at the current. As traditional industry devices are looking only at the current, they have to have a steady arcing current so that they will be able to trip through their arcing mechanism. Loose connections are always non-continuous.

Example embodiments of the electrical device can detect non-continuous arcing quite easily as the electrical device is looking at erratic variations in the voltage, and a non-continuous arc will produce erratic variation in the voltage, rather than just dropping in the voltage.

Example embodiments of the electrical device are looking at erratic variations of the voltage RMS values; and would detect right away non-continuous arcing. The discontinuous nature of the series arc will give rise to erratic changes in the voltage and these will be detected by the electrical device and will trip based on the detection. Detection and tripping of a series arc based on examination of erratic changes in the voltage, which results from the non-continuous nature of the series arc.

If arcing were continuous, it would drop and stay at the lower levels. If voltage stays at the lower level, there is no variation again. The whole RMS goes down, but the standard deviation goes to zero because the whole thing is down now. Whereas if it is non-continuous it will go up and down, up and down. Example embodiments of the electrical device are looking at voltage to determine if an arc, and looking at current to make detection more reliable and avoid false tripping because of erroneous data.

In example embodiments, the electrical device uses solid state switches such as IGBTs and Triacs to continually deliver power within a cycle. An active power distribution device operates for every cycle.

“Fig.” and “Figure” are used interchangeably herein in the present disclosure.

While some of the present embodiments are described in terms of methods, a person of ordinary skill in the art will understand that present embodiments are also directed to various apparatus such as processors, circuitry, and controllers including components for performing at least some of the aspects and features of the described methods, be it by way of hardware components, software or any combination of the two, or in any other manner, as applicable.

In the Figures, as applicable, at least some or all of the illustrated subsystems or blocks may include or be controlled by a processor, which executes instructions stored in a memory or computer readable medium. Variations may be made to some example embodiments, which may include combinations and sub-combinations of any of the above. The various embodiments presented above are merely examples and are in no way meant to limit the scope of this disclosure. Variations of the innovations described herein will be apparent to persons of ordinary skill in the art having the benefit of the example embodiments, such variations being within the intended scope of the present disclosure. In particular, features from one or more of the above-described embodiments may be selected to create alternative embodiments comprised of a sub-combination of features, which may not be explicitly described above. In addition, features from one or more of the above-described embodiments may be selected and combined to create alternative embodiments comprised of a combination of features which may not be explicitly described above. Features suitable for such combinations and sub-combinations would be readily apparent to persons skilled in the art upon review of the present disclosure as a whole. The subject matter described herein intends to cover and embrace all suitable changes in technology.

Certain adaptations and modifications of the described embodiments can be made. Therefore, the above discussed embodiments are considered to be illustrative and not restrictive.

1. An electrical device comprising:
a contact configured for electrical connection to a power line;
at least one sensor to detect at least voltage signals indicative of the power line; and
a processor configured to determine from the detected voltage signals that a series arc fault has occurred.

2. An electrical device as recited in claim 1, further comprising a solid state switch for in-series electrical connection with the power line, the processor further configured to, in response to said determining that the series arc fault has occurred on the power line, deactivating the solid state switch.

3. An electrical device as recited in claim 2, wherein the solid state switch is a TRIAC.

4. An electrical device as recited in claim 1, wherein the contact is configured for electrical connection to a downstream power line or an electrical outlet.

5. An electrical device as recited in claim 4, wherein said determining comprises the processor determining that the series arc fault has occurred on the downstream power line or a load plugged into the electrical outlet.

6. An electrical device as recited in claim 1, wherein said determining comprises the processor determining that the series arc fault has occurred on the power line.

7. An electrical device as recited in claim 1, further comprising a communication subsystem, wherein the processor is configured to, in response to said determining that the series arc fault has occurred, sending a communication that the series arc fault has occurred.

8. An electrical device as recited in claim 1, wherein the at least one sensor further includes at least one current sensor to detect current signals indicative of the power line, wherein the determining is further based on the detected current signals in addition to the detected voltage signals.

9. An electrical device as recited in claim 1, wherein the determining is that there is little or no variance in the detected voltage signals, and is below a specified voltage threshold.

10. An electrical device as recited in claim 8, wherein the determining is that there is variance in the detected current signals, for a load that experiences current above a threshold.

11. An electrical device as recited in claim 1, wherein the power line comprises a hot power line, or a neutral power line.

12. An electrical device as recited in claim 1, wherein the series arc fault is between a hot power line and a second hot power line, or a neutral power line and a second neutral power line, or a ground power line and a second ground power line.

13. An electrical device as recited in claim 1, wherein the series arc fault is between the power line and the contact or a second contact.

14. An electrical device as recited in claim 1, wherein the determining from the detected voltage signals that the series arc fault has occurred comprises: computing a frequency analysis of the detected voltage signals, determining that the series arc fault has occurred from the frequency analysis by determining that there is little or no deviation of the frequency analysis.

15. An electrical device as recited in claim 14, wherein the frequency analysis comprises calculating a Fourier transform a Fast Fourier Transform (FFT) of the detected voltage signals, and analyzing higher order frequency signals of the Fourier transform or the Fast Fourier Transform (FFT) that are higher than fundamental frequency of the power line.

16. An electrical device as recited in claim 14, wherein the frequency analysis comprises analyzing higher order frequency signals that are higher than fundamental frequency of the power line.

17. An electrical device as recited in claim 1, wherein the determining from the detected voltage signals that the series arc fault has occurred comprises calculating a mean square or root mean square of the detected voltage signals and determining that the mean square or the root mean square deviates from previous mean square or root mean square of previously detected voltage signals.

18. An electrical device as recited in claim 17, wherein the determining from the detected voltage signals that the series arc fault has occurred comprises determining that that the mean square or the root mean square deviation has occurred for more than a threshold number of cycles of the detected voltage signals within a certain time window.

19. An electrical device as recited in claim 17, wherein the processor is configured to, when the mean square or the root mean square deviation has occurred for less than a threshold number of cycles of the detected voltage signals within a certain time window, determine that no series arc fault has yet occurred to avoid false trips.

20. An electrical device as recited in claim 9, wherein the variance is a decrease in the mean square or the root mean square of the detected voltage signals.

21. An electrical device as recited in claim 1, wherein the determining from the detected voltage signals that the series arc fault has occurred comprises calculating a mean square or root mean square of individual cycles of the detected voltage signals and determining that there are at least two consecutive cycles of decreases in the mean square or the root mean square of the detected voltage signals.

22. An electrical device as recited in claim 1, wherein the determining from the detected voltage signals that the series arc fault has occurred comprises determining whether there is a voltage variance for individual cycles of the detected voltage signals, and determining that the voltage variance has occurred for more than a threshold number of cycles of the detected voltage signals within a certain time window.

23. An electrical device as recited in claim 1, wherein the processor is configured to determine whether there is a voltage variance for individual cycles of the detected voltage signals, and determine that no series arc fault has yet occurred to avoid false trips when the voltage variance has occurred for less than a threshold number of cycles of the detected voltage signals within a certain time window.

24. An electrical device as recited in claim 1, further comprising at least one analog-to-digital convertor (ADC) internal or external to the processor configured to receive a respective analog signal from the at least one sensor and output a respective digital signal for processing by the processor for the determining from the detected voltage signals that the series arc fault has occurred.

25. An electrical device as recited in claim 1, wherein the at least one sensor is for in-series electrical connection with the power line.

26. An electrical device as recited in claim 1, wherein the series arc fault is a non-continuous arc fault.

27. An arc fault circuit interrupter comprising:
a power line conductor;
a solid state switch for electrical connection to the power line conductor and configured to be activated or deactivated; and
an arc fault trip circuit cooperating with said solid state switch, said arc fault trip circuit being configured to deactivate said solid state switch responsive to detection of a series arc fault condition associated with voltage conditions of the power line conductor.

28. An arc fault circuit interrupter as recited in claim 27, wherein the power line conductor comprises a hot conductor, a neutral conductor, or a ground conductor.

29. An arc fault circuit interrupter as recited in claim 27, wherein the solid state switch is a TRIAC.

30. An electrical device comprising:
a contact configured for electrical connection to a power line;
at least one sensor configured to detect voltage signals indicative of the power line; and
a processor configured to sample a plurality of the detected voltage signals within individual cycles of the detected voltage signals, and calculate mean square or root mean square values of the sampled voltage signals for the respective individual cycle of the detected voltage signals.

31. An electrical device as recited in claim 30, wherein sixty four samples are sampled from the respective individual cycle of the detected voltage signals.

32. An electrical device as recited in claim 30, further comprising an analog-to-digital convertor (ADC) configured to receive analog signals from the at least one sensor indicative of the detected voltage signals and output digital signals to the processor for the sampling.

33. An electrical device as recited in claim 30, further comprising a solid state switch for in-series electrical connection with the power line, the processor further configured to, in response to determining that a series arc fault has occurred from the calculated mean square or root mean square values of the sampled voltage signals, deactivate the solid state switch.

34. An electrical device as recited in claim 33, wherein said determining comprises the processor determining that the series arc fault has occurred on the power line.

35. An electrical device as recited in claim 30, further comprising a communication subsystem, wherein the processor is configured to, in response to said determining that a series arc fault has occurred from the calculated mean square or root mean square values of the sampled voltage signals, send a communication that the series arc fault has occurred.

36. An electrical circuit interruption device comprising:
a contact configured for electrical connection to a power line;
a solid state switch for in-series electrical connection with the power line;
at least one sensor to detect voltage signals indicative of the power line and provide analog signals indicative of the detected voltage signals;
an analog-to-digital convertor (ADC) configured to receive the analog signals from the at least one sensor and output digital signals; and
a processor configured to determine from the digital signals that an arc fault has occurred, and in response deactivating the solid state switch.

37. An electrical circuit interruption device as recited in claim 36, wherein the determining from the detected voltage signals that the arc fault has occurred comprises: computing a frequency analysis of the detected voltage signals, wherein the arc fault is determined to be a parallel arc fault from the frequency analysis.

38. An electrical circuit interruption device as recited in claim 37, wherein the frequency analysis comprises calculating a Fourier transform or a Fast Fourier Transform (FFT) of the detected voltage signals, and analyzing higher order frequency signals of the Fourier transform or the Fast Fourier Transform (FFT) that are higher than fundamental frequency of the power line.

39. An electrical circuit interruption device as recited in claim 38, wherein the calculating of the Fourier transform or the FFT of the detected voltage signals is performed on individual cycles of the detected voltage signals, and wherein the arc fault is determined to be a parallel arc fault based on the higher order frequency signals over a plurality of cycles.

40. An electrical circuit interruption device as recited in claim 37, wherein the frequency analysis comprises analyzing higher order frequency signals that are higher than fundamental frequency of the power line.

41. An electrical circuit interruption device as recited in claim 37, wherein the frequency analysis of the detected voltage signals comprises performing the frequency analysis on individual cycles of the detected voltage signals and wherein the arc fault is determined to be a series arc fault when there is little or no deviation of the frequency analysis over a plurality of cycles.

42. An electrical circuit interruption device as recited in claim 36, wherein the determining from the detected voltage signals that the arc fault has occurred comprises calculating a mean square or root mean square of the detected voltage signals and determining that the mean square or the root mean square deviates from previous mean square or root mean square of previously detected voltage signals.

43. An electrical circuit interruption device as recited in claim 36, wherein the determining from the detected voltage signals that the arc fault has occurred comprises calculating a variance of the detected voltage signals and determining that the variance deviates from previous variance of previously detected voltage signals, wherein the variance is a decrease in the mean square or the root mean square of the detected voltage signals.

44. An electrical circuit interruption device as recited in claim 36, wherein the determining from the detected voltage signals that the arc fault has occurred comprises calculating a variance of the detected voltage signals and determining that the variance deviates from previous variance of previously detected voltage signals, wherein the variance is a decrease in a peak voltage of at least one cycle of the detected voltage signals.

45. An electrical circuit interruption device as recited in claim 36, wherein the arc fault is determined to be a series arc fault, wherein the determining from the detected voltage signals that the arc fault has occurred comprises calculating a mean square or root mean square of individual cycles of the detected voltage signals and determining that a variance of the mean square or the root mean square has occurred over a plurality of cycles.

46. An electrical circuit interruption device as recited in claim 36, wherein the arc fault is determined to be a series arc fault, wherein the determining from the detected voltage signals that the arc fault has occurred comprises determining whether there is a voltage variance for individual cycles of the detected voltage signals, and determining that the voltage variance has occurred for more than a threshold number of cycles of the detected voltage signals within a certain time window.

47. An electrical circuit interruption device as recited in claim 36, wherein the at least one sensor is for in-series electrical connection with the power line.

48. An electrical circuit interruption device as recited in claim 36, wherein the processor is configured to decide, for each cycle of the detected voltage signals, whether to activate or de-activate the solid state switch.

49. An electrical circuit interruption device as recited in claim 36, wherein the processor is configured for active power distribution of the power line within each cycle of the detected voltage signals by activating or deactivating the solid state switch.

50. An electrical circuit interruption device as recited in claim 36, wherein the arc fault is a glowing contact arc fault between the contact and the power line.

51. An arc fault circuit interrupter comprising:
a hot conductor;
a solid state switch for electrical connection to the hot conductor and configured to be activated or deactivated; and
an arc fault trip circuit cooperating with said solid state switch, said arc fault trip circuit being configured to deactivate said solid state switch responsive to detection of an arc fault condition between the hot conductor and a neutral power line associated with detected current variation of the hot conductor and neutral power line.

52. An electrical circuit interruption device as recited in claim 51, wherein the arc fault condition is determined based on frequency analysis of the hot conductor and neutral power line.

53. An electrical device comprising:
a contact configured for electrical connection to a hot power line;
at least one sensor to detect at least current signals indicative of the hot power line; and
a processor configured to determine from the detected current signals that an arc fault has occurred between the hot power line and a neutral power line or between hot power line and ground power line.

54. An electrical device as recited in claim 53, wherein the determining from the detected current signals that the arc fault has occurred comprises: computing a frequency analysis of the detected current signals of the hot power line.

55. An electrical device as recited in claim 54, wherein the frequency analysis comprises calculating a Fourier transform or a Fast Fourier Transform (FFT) of the detected current signals, and analyzing higher order frequency signals of the Fourier transform or the Fast Fourier Transform (FFT) that are higher than fundamental frequency of the hot power line.

56. An electrical device as recited in claim 55, wherein the calculating of the Fourier transform or the FFT of the detected current signals is performed on individual cycles of the detected current signals, and wherein the arc fault is determined to be a parallel arc fault based on the higher order frequency signals over a plurality of cycles.

57. An electrical device as recited in claim 53, wherein the determining from the detected current signals that the arc fault has occurred comprises: determining a variation over a plurality of cycles of the detected current signals.

58. An electrical device as recited in claim 53, further comprising an analog-to-digital convertor (ADC) configured to receive analog signals from the at least one sensor indicative of the detected current signals and output digital signals to the processor for the determining.

59. An electrical device as recited in claim 53, further comprising a solid state switch for in-series electrical connection with the hot power line, wherein the processor is further configured to, in response to determining that the that arc fault has occurred, deactivating the solid state switch.

60. An electrical device as recited in claim 59, wherein the solid state switch is deactivated prior to current overload of the hot power line.

61. An electrical device as recited in claim 59, wherein the solid state switch is deactivated when there is no leakage to ground or another conductor.

62. An electrical device as recited in claim 53, wherein the at least one sensor is for in-series electrical connection with the hot power line.

63. An electrical device as recited in claim 53, wherein the determining from the detected current signals that the arc fault has occurred comprises: computing a frequency analysis of the detected current signals, wherein the arc fault is determined to be a parallel arc fault from the frequency analysis.

64. An electrical device comprising:
a sensor to detect voltage signals indicative of a hot power line; and
a processor configured to determine from the detected voltage signals that an arc fault has occurred, and differentiate the arc fault as being a series arc fault versus a parallel arc fault.

65. An electrical device comprising:
a contact configured for electrical connection to a power line;
a solid state switch for in-series electrical connection with the power line;
a sensor to detect voltage signals indicative of the power line; and
a processor configured to determine from the detected voltage signals that an arc fault has occurred, and in response deactivating the solid state switch without false tripping of the solid state switch.

66. An electrical circuit interruption device comprising:
a contact configured for electrical connection to a power line;
a solid state switch for in-series electrical connection with the power line;
a sensor to detect current signals indicative of the power line; and
a processor configured to: set a settable current threshold value, and deactivate the solid state switch in response to the detect current signals of the power line exceeding the settable current threshold value.

67. An electrical circuit interruption device as recited in claim 66, wherein the settable current threshold value is a standard current threshold value.

68. An electrical circuit interruption device as recited in claim 67, wherein the standard current threshold value is 15 A/20 A, 16 A/32 A, 50 A, 100 A, 200 A, or a value higher than 200 A.

69. An electrical circuit interruption device as recited in claim 66, wherein the settable current threshold value is non-standard current threshold value.

70. An electrical circuit interruption device as recited in claim 66, wherein the setting is performed by the processor based on the detected current signals.

71. An electrical circuit interruption device as recited in claim 66, wherein the setting is performed by the processor based on a database stored in a memory accessible by the processor.

72. An electrical circuit interruption device as recited in claim 66, wherein the settable current threshold value for the setting is received by the processor by way of received input.

73. An electrical circuit interruption device as recited in claim 72, wherein the received input is received from an Application Program Interface, a user input device, a second electrical receptacle device, or a computer device.

74. An electrical device comprising:
a contact configured for electrical connection to a power line;
a voltage sensor for in-series connection to the power line to detect voltage signals indicative of the power line and provide analog signals indicative of the detected voltage signals;
a current sensor for to detect current signals indicative of the power line and provide analog signals indicative of the detected current signals;
an analog-to-digital convertor (ADC) configured to receive analog signals from the voltage sensor and output digital signals; and
a processor configured to sample the digital signals in real time.

75. An electrical device as recited in claim 74, wherein the processor is a microprocessor.

76. An electrical device as recited in claim 74, wherein sixty four samples are sampled from the respective individual cycle of the detected voltage signals and the detected current signals.

77. An electrical device as recited in claim 74, wherein the processor is configured to determine that an arc fault has occurred from at least some of the sampled digital signals.

78. An electrical device as recited in claim 77, wherein the processor is configured to determine that the arc fault is a series arc fault from a calculated mean square or root mean square values of the sampled voltage signals, and that there is little or no deviation in the detected current signals.

79. An electrical device as recited in claim 77, wherein the processor is further configured to compute a frequency analysis of the detected voltage signals, and determine that the arc fault is a parallel arc fault based on the frequency analysis.

80. An electrical device as recited in claim 79, wherein the frequency analysis comprises calculating a Fourier transform or a Fast Fourier Transform (FFT) of the detected voltage signals, and analyzing higher order frequency signals of the Fourier transform or the FFT that are higher than fundamental frequency of the power line.

81. An electrical device as recited in claim 80, wherein the calculating of the Fourier transform, or the FFT of the detected voltage signals is performed on individual cycles of the detected voltage signals, and wherein the arc fault is determined to be a parallel arc fault when based on the higher order frequency signals over a plurality of cycles.

82. An electrical device as recited in claim 80, wherein the frequency analysis comprises analyzing higher order frequency signals of the Fourier transform or the FFT that are higher than fundamental frequency of the power line.

83. An electrical device as recited in claim 79, wherein the power line is a hot power line, wherein when the parallel arc fault has occurred over the hot power line to a neutral power line, there is little or no deviation in the detected current signals.

84. An electrical device as recited in claim 74, wherein the processor is configured to decide, for each cycle of the detected current and/or voltage signals, whether to activate or de-activate a solid state switch.

85. An electrical device as recited in claim 74, wherein the processor is configured for active power distribution of the power line within each cycle of the detected current and/or voltage signals by activating or deactivating a solid state switch.

86. An oscilloscope electrical device comprising:
a contact configured for electrical connection to a power line;
a sensor for in circuit electrical connection to the power line to detect signals indicative of the power line; and
a processor configured to sample the detected signals in real time, and provide oscilloscope information indicative of the sampled signals.

87. An oscilloscope electrical device as recited in claim 86, wherein the electrical connection to the power line is in series electrical connection for current.

88. An oscilloscope electrical device as recited in claim 86, wherein the electrical connection to the power line is in parallel electrical connection for voltage.

89. An oscilloscope electrical device as recited in claim 86, wherein the oscilloscope information includes a waveform of the detected signals, further comprising a display screen for the providing of the waveform in real time.

90. An oscilloscope electrical device as recited in claim 86, wherein the processor is configured to analyze the sampled signals in real time.

91. An oscilloscope electrical device as recited in claim 90, wherein the analyzing includes calculating a mean square or a root mean square of the sampled signals.

92. An oscilloscope electrical device as recited in claim 90, wherein the analyzing includes performing frequency analysis of the detected signals.

93. An oscilloscope electrical device as recited in claim 92, wherein the frequency analysis is a Fourier transform or a Fast Fourier Transform (FFT) of the detected signals.

94. An oscilloscope electrical device as recited in claim 90, wherein the oscilloscope information includes information of the analyzed sampled signals.

95. An oscilloscope electrical device as recited in claim 86, further comprising a communication subsystem for the providing of the oscilloscope information by transmitting to another device.

96. An oscilloscope electrical device as recited in claim 86, further comprising at least one analog-to-digital convertor (ADC) configured to receive a respective analog signal from the at least one sensor and output a respective digital signal for processing by the processor for the providing of the oscilloscope information.

97. An oscilloscope electrical device as recited in claim 86, wherein the processor is configured to execute an application program interface (API).

98. An oscilloscope electrical device as recited in claim 97, wherein the API includes commands for instructing what mode of the oscilloscope information is to be provided by the processor.

99. An oscilloscope electrical device as recited in claim 97, further comprising a solid state switch for in-series electrical connection with the power line, wherein the API includes control commands for manual or automatic power distribution or safety of the power line by activating or deactivating the solid state switch.

100. An oscilloscope electrical device as recited in claim 86, wherein sixty four samples are sampled from the respective individual cycle of the detected signals.

101. An electrical device comprising:
a contact configured for electrical connection to a power line;
at least one sensor to detect signals indicative of the power line and provide analog signals indicative of the detected signals;
an analog-to-digital convertor (ADC) configured to receive analog signals from the at least one sensor and output digital signals; and
a processor configured to calibrate the electrical device by:
applying a first known electrical signal to the sensor and receiving a first digital signal value,
applying a second known electrical signal to the sensor and receiving a second digital signal value,
performing linear interpolation or extrapolation using the first digital signal value and the second digital signal value for the calibrating of the electrical device.

102. An electrical device as recited in claim 101, further comprising more than two digital signal values for calibrating non-linear sensor characteristics using a piece-wise linear approximation.

103. An electrical device as recited in claim 101, further comprising a solid state switch for in-series electrical connection with the power line, the processor further configured to determine that a series arc fault has occurred, and in response deactivating the solid state switch.

104. An electrical device as recited in claim 103, wherein the solid state switch is a TRIAC.

105. An electrical device as recited in claim 101, wherein the contact is configured for downstream electrical connection to a downstream power line.

106. An electrical device as recited in claim 101, wherein the contact is configured for electrical connection through an electrical outlet.

107. An electrical device as recited in claim 101, wherein the processor is a microprocessor.

108. An electrical device comprising:
a first contact for configured for electrical connection to a hot power line;
a first sensor configured to provide a first analog signal indicative of current of the hot power line;
a second contact for configured for electrical connection to a neutral power line;
a second sensor configured to provide a second analog signal indicative of current of the neutral power line;
a solid state switch for electrical connection to the hot power line and configured to be activated or deactivated;
an analog-to-digital convertor (ADC) configured to receive the analog and output a digital signal; and
a processor configured to detect a ground fault condition of the hot power line by determining a current imbalance between the hot power line and the neutral power line based on the digital signal from the ADC, for the deactivation of the solid state switch.

109. A ground fault circuit interrupter comprising:
a power line conductor;
a first sensor configured to provide a first analog signal indicative of current of the power line conductor;
a neutral line conductor;
a second sensor configured to provide a second analog signal indicative of current of the neutral line conductor;
a solid state switch for electrical connection to the power line conductor and configured to be activated or deactivated; and
a ground fault trip circuit cooperating with said solid state switch, said ground fault trip circuit being configured to deactivate said solid state switch responsive to detection of a ground fault condition associated with current imbalance between said hot power line conductor and said neutral conductor,
wherein said ground fault trip circuit includes:
an analog comparator circuit configured to receive the first analog signal and the second analog signal and output an analog signal indicative of a difference between the first analog signal and the second analog signal,
an analog-to-digital convertor (ADC) configured to receive the analog signal from the analog comparator circuit and output a digital signal, and
a processor configured to perform determining of the current imbalance for the detection of the ground fault condition based on the digital signal from the ADC, for the deactivation of the solid state switch.

110. A ground fault circuit interrupter as recited in claim 109, wherein the analog comparator circuit comprises a differential amplifier.

111. A ground fault circuit interrupter as recited in claim 110, wherein the differential amplifier is unaffected by magnetic field effects.

112. A ground fault circuit interrupter as recited in claim 109, wherein the detection of the ground fault condition by processor includes determining that the current imbalance exceeds a threshold current imbalance and/or that the current imbalance has lasted for more than a threshold time.

113. A ground fault circuit interrupter as recited in claim 109, wherein the detection of the ground fault condition by processor includes determining that the current imbalance exceeds a threshold current imbalance.

114. A ground fault circuit interrupter as recited in claim 109, wherein the detection of the ground fault condition by processor includes determining that the current imbalance has lasted for more than a threshold time.

115. A ground fault circuit interrupter as recited in claim 109, wherein the first sensor and the second sensor are unaffected by magnetic field effects.

116. An electrical device comprising:
a conductive housing defining a first channel for receiving a power line, and a second channel; and
a fastener through the second channel for tightening the power line to the first channel, a head of the fastener engaging the power line and the conductive housing when tightened.

117. An electrical device as claimed in claim 116, wherein the head is nested within an exterior of the conductive housing when tightened.

118. An electrical device as claimed in claim 116, wherein the fastener contacts the conductive housing without contacting the power line.

119. An electrical device as claimed in claim 116, wherein the conductive housing includes a first conductive part and a second conductive part that collectively define the first channel.

120. An electrical device as claimed in claim 116, wherein the first channel includes one or more ribs for crimping contact with the power line.

121. An electrical device as claimed in claim 116, wherein the fastener is a screw and the head is a screw head.

122. An electrical device as claimed in claim 121, wherein the power line does not wrap around the screw.

123. An electrical device as claimed in claim 116, further comprising a conductive element conductively connected to the conductive housing for electrical connection to an electrical outlet or for downstream connection.

124. An electrical device as claimed in claim 123, further comprising a circuit board that comprises the conductive element.

125. An electrical device as claimed in claim 124, wherein the circuit board includes an opening for receiving direct connection to the power line, the opening being accessible through the first channel.

126. An electrical device as claimed in claim 125, wherein the opening is axially offset from the first channel.

127. An electrical device as claimed in claim 125, wherein the opening and the first channel collectively define a guiding tunnel for the power line.

128. An electrical device as claimed in claim 116, wherein the power line does not wrap around the fastener.

129. An electrical device as claimed in claim 116, for preventing of glowing contact between the power line and the conductive housing.

130. An electrical device as claimed in claim 116, wherein the fastener and the head are conductive.

131. An electrical device as claimed in claim 116, wherein the first channel is generally perpendicular to the second channel.

132. A device as recited in claim 1, wherein the device is an in-wall receptacle, a multiple-outlet power adapter, a power strip, an in-line power receptacle, an extension cord, a circuit breaker, a circuit breaker panel, a junction box, or a load center.

133. An electrical device comprising:
a ground contact configured for electrical connection to ground;
a first voltage sensor to detect voltage signals indicative of the ground contact;
a first current sensor to detect current signals indicative of the ground contact;
a neutral contact configured for electrical connection to a neutral power line;
a second voltage sensor to detect voltage signals indicative of the neutral power line;
a second current sensor to detect current signals indicative of the neutral power line; and
a processor configured to determine from the detected voltage signals and/or the current signals that a ground imbalance has occurred between the neutral power line and the ground.

134. An electrical device as recited in claim 133, further comprising a solid state switch for in-series electrical connection with a power line, the processor further configured to, in response to said determining that the ground imbalance has occurred on the power line, deactivating the solid state switch.

135. An electrical device as recited in claim 134, wherein the solid state switch is a TRIAC.

136. An electrical device as recited in claim 133, wherein said determining comprises the processor determining that the ground imbalance has occurred upstream of the electrical device.

137. An electrical device as recited in claim 133, further comprising a communication subsystem, wherein the processor is configured to, in response to said determining that the ground imbalance fault has occurred, sending a communication that the ground imbalance has occurred.

138. An electrical device as recited in claim 133, wherein the ground contact is for electrical connection to the ground by way of a ground power line.

139. An electrical device as recited in claim 133, further comprising at least one analog-to-digital convertor (ADC) configured to receive a respective analog signal from the first voltage sensor and output a respective digital signal for processing by the processor for the determining from the detected voltage signals that the ground imbalance has occurred.

140. An electrical device as recited in claim 133, wherein the first voltage sensor is for in-series electrical connection with the ground.

141. An electrical device as recited in claim 133, wherein the first current sensor includes a magnetic field sensor for the detecting of the current signals of the ground.

142. An electrical device as recited in claim 133, further comprising a ground plate for connecting the ground contact to the ground.

143. An electrical device as recited in claim 142, wherein the ground plate is a heat sink of the electrical device.

144. An electrical device as recited in claim 142, wherein the ground plate is a face plate of the electrical device.

145. An electrical device comprising:
a ground contact configured for electrical connection to ground;
a voltage sensor for in-series connection to a power line to detect voltage signals indicative of the ground contact line and provide analog signals indicative of the detected voltage signals;
a current sensor for in-series connection to the power line to detect current signals indicative of the ground contact line and provide analog signals indicative of the detected current signals;
an analog-to-digital convertor (ADC) configured to receive analog signals from the voltage sensor and output digital signals; and
a processor configured to sample the digital signals in real time.

146. An electrical device as recited in claim 145, wherein the voltage sensor is for in-series electrical connection with the ground.

147. An electrical device as recited in claim 145, wherein the current sensor includes a magnetic field sensor for the detecting of the current signals of the ground.

148. An electrical device as recited in claim 145, further comprising a ground plate for connecting the ground contact to the ground.

149. An electrical device as recited in claim 148, wherein the ground plate is a heat sink of the electrical device.

150. An electrical device as recited in claim 148, wherein the ground plate is a face plate of the electrical device.

151. An electrical device comprising:
a processor; and
a sensor assembly electrically coupled to the processor for detecting a current leakage, a voltage between two power lines, or both the current leakage and the voltage between the two power lines.

152. The electrical device as recited in claim 151, wherein the sensor assembly comprises a current sensor.

153. The electrical device as recited in claim 151, wherein the sensor assembly comprises a voltage sensor.

154. The electrical device as recited in claim 151, wherein the sensor assembly comprises both a current sensor and a voltage sensor.

155. The electrical device as recited in claim 152, wherein current sensor detects current leakage on a safety ground wire.

156. The electrical device as recited in claim 155, wherein current sensor detects a magnetic field generated by the leakage current on the safety ground wire.

157. (canceled)

158. The electrical device as recited in claim 151, further comprising a communications line for connecting the sensor assembly with the processor for transmitting measurement results from the sensor assembly to the processor.

159. A method for detecting ground imbalance on an electrical device, comprising:
receiving, from a senor assembly, current, voltage, or both current and voltage measurement results;
determine whether a ground imbalance is above a predetermined safety threshold level; and
sending an error message indicating the ground imbalance.

160. The method as recited in claim 159, further comprising, in response to the determining that the ground imbalance is above the predetermined safety threshold level, discontinuing delivery of power to the electrical device.

161. The method as recited in claim 159, further comprising, if a second ground imbalance indicated by an external sensors above a predetermined threshold, alerting an external safety ground fault.

162. (canceled)

163. The method as recited in claim 161, further comprising discontinuing delivery of power to the electrical device.

164. An electrical device comprising:
a dielectric body,
a plurality of through holes formed on the dielectric body, each through hole for receiving a power line; and
a housing at an end of the body for housing a current sensor for sensing a current of the power line, a voltage sensor for sensing the voltage of the power line, or both a current sensor for sensing a current of the power line and a voltage sensor for sensing a voltage of the power line.

165. The electrical device of claim 164, further comprising a plurality of screw holes, each hole for receiving a screw for securing the power line in a through hole.

166. The electrical device of claim 165, further comprising a plurality of attachment screw holes for securing the electric device to an object.

167. The electrical device of claim 164, further comprising a plurality of sensor leads, each for indicating a status of a sensor in the housing.

168. The electrical device of claim 164, further comprising a conductor or a cable for transmitting measurement results to a processor.

169. The electrical device of claim 164, wherein the electrical device is an insulated bus bar mounted on a breaker panel housing.

170. The electrical device of claim 164, wherein the electrical device detects fault on current and/or voltage.

171. The electrical device of claim 164, wherein the electrical device is configured to receive a wire through a main feed conductor hole, and to provide an exit path for the wire through a second conductor hole.

172. The electrical device of claim 171, wherein the electrical device further comprising a jumper cable for use between the second conductor hole and a bus bar.

173. An electrical device comprising:
a dielectric body,
a through holes formed on a first side of the dielectric body for receiving an end of a power line; and
a housing at an end of the body for housing a current sensor for sensing a current of the power line, a voltage sensor for sensing the voltage of the power line, or both a current for sensing a current of the power line and a voltage sensor for sensing a voltage of the power line; and
a conductive pin on a second side of the dielectric body for conducting current or voltage to or from the power line.

174. The electrical device of claim 173, wherein the conductive pin is mounted perpendicularly to the second side of the dielectric body.

175. An electrical device comprising:
a plurality of power output terminals for supplying power;
a plurality of power supply terminals for receiving power supply from a power source;
a plurality of insulated power delivery modules, each module electrically connected to a respective power supply terminal and a power output terminal for conducting power; and
a sensor unit for sensing current and voltage flowing through each of the power delivery module.

176. The electrical device of claim 175, wherein the sensor unit is encapsulated in the electrical device.
